(19) United States
(12) Patent Application Publication
(10) Pub. No.: US 2010/0122730 A1
(43) Pub. Date: May 20, 2010

(54) POWER-LOSS-INHIBITING CURRENT-COLLECTOR

(76) Inventors: Jason S. CORNEILLE, Santa Clara, CA (US); Joseph Laia, Morgan Hill, CA (US); Magdalena M. Parker, Santa Cruz, CA (US); Brett A. Hinze, San Jose, CA (US); Todd A. Krajewski, Mountain View, CA (US); Adam B.P. Froimovitch, San Francisco, CA (US); Steven T. Croft, Menlo Park, CA (US); Bruce Hachtmann, San Martin, CA (US); Darin S. Birtwhistle, San Francisco, CA (US)

Correspondence Address: Weaver Austin Villeneuve & Sampson LLP, P.O. BOX 70250, OAKLAND, CA, 94612-0250, US

(21) Appl. No.: 12/272,600

(22) Filed: Nov. 17, 2008

(51) Int. Cl. H01L 31/00

(52) U.S. Cl. 136/259

(57) ABSTRACT

A power-loss-inhibiting current-collector. The power-loss-inhibiting current-collector includes a trace for collecting current from a solar cell. The power-loss-inhibiting current-collector further includes a current-limiting portion of the power-loss-inhibiting current-collector. The current-limiting portion of the power-loss-inhibiting current-collector is coupled to the trace. The current-limiting portion of the power-loss-inhibiting current-collector is configured to regulate current flow through the power-loss-inhibiting current-collector.

### TECHNICAL FIELD

Embodiments of the present invention relate generally to the field of photovoltaic technology.

### BACKGROUND

In the quest for renewable sources of energy, photovoltaic technology has assumed a preeminent position as a cheap renewable source of clean energy. In particular, solar cells based on the compound semiconductor copper indium gallium diselenide (CIGS) used as an absorber layer offer great promise for thin-film solar cells having high efficiency and low cost. Of comparable importance to the technology used to fabricate thin-film solar cells themselves, is the technology used to collect current from solar cells, solar-cell modules and solar-cell arrays, and to collect current from these without power loss.

Solar-cells are impacted by shunt defects. A significant challenge is the development of solar-cell current-collection and interconnection schemes that minimize the effects of power losses that can occur if such shunt defects are present. Reliability and efficiency of solar-cells protected from shading effects in the presence of adventitious shunt defects determines the useful life and performance of solar-cells, and the solar-cell modules and solar-cell arrays that depend upon them.

### SUMMARY

Embodiments of the present invention include a power-loss-inhibiting current-collector. The power-loss-inhibiting current-collector includes a trace for collecting current from a solar cell. The power-loss-inhibiting current-collector further includes a current-limiting portion of the power-loss-inhibiting current-collector. The current-limiting portion of the power-loss-inhibiting current-collector is coupled to the trace. The current-limiting portion of the power-loss-inhibiting current-collector is configured to regulate current flow through the power-loss-inhibiting current-collector.

### DESCRIPTION OF THE DRAWINGS

The accompanying drawings, which are incorporated in and form a part of this specification, illustrate embodiments of the invention and, together with the description, serve to explain the embodiments of the invention:

FIG. 1A is a cross-sectional elevation view of a layer structure of a solar cell, in accordance with an embodiment of the present invention.

FIG. 1B is a schematic diagram of a model circuit of a solar cell, electrically connected to a load, in accordance with an embodiment of the present invention.

FIG. 2 is a schematic diagram of a model circuit of a solar-cell module, electrically connected to a load, that shows the interconnection of solar cells in the solar-cell module, in accordance with an embodiment of the present invention.

FIG. 3 is a schematic diagram of a model circuit of a solar-cell module, electrically connected to a load, that details model circuits of interconnect assemblies, in accordance with an embodiment of the present invention.

FIG. 4A is a schematic diagram of a model circuit of an interconnect assembly for connecting two solar cells of a solar-cell module, in accordance with an embodiment of the present invention.

FIG. 4B is a plan view of the interconnect assembly of FIG. 4A that shows the physical interconnection of two solar cells in the solar-cell module, in accordance with an embodiment of the present invention.

FIG. 4C is a cross-sectional, elevation view of the interconnect assembly of FIG. 4B that shows the physical interconnection of two solar cells in the solar-cell module, in accordance with an embodiment of the present invention.

FIG. 4D is a cross-sectional, elevation view of an alternative interconnect assembly for FIG. 4B that shows an edge-conforming interconnect assembly for the physical interconnection of two solar cells in the solar-cell module, in accordance with an embodiment of the present invention.

FIG. 4E is a cross-sectional, elevation view of an alternative interconnect assembly for FIG. 4B that shows a shingled-solar-cell arrangement for the physical interconnection of two solar cells in the solar-cell module, in accordance with an embodiment of the present invention.

FIG. 4F is a plan view of an alternative interconnect assembly for FIG. 4A that shows the physical interconnection of two solar cells in the solar-cell module, in accordance with an embodiment of the present invention.

FIG. 5A is a plan view of the combined applicable carrier film, interconnect assembly that shows the physical arrangement of a trace with respect to a top carrier film and a bottom carrier film in the combined applicable carrier film, interconnect assembly, in accordance with an embodiment of the present invention.

FIG. 5B is a cross-sectional, elevation view of the combined applicable carrier film, interconnect assembly of FIG. 5A that shows the physical arrangement of a trace with respect to a top carrier film in the combined applicable carrier film, interconnect assembly prior to disposition on a solar cell, in accordance with an embodiment of the present invention.

FIG. 5C is a cross-sectional, elevation view of the interconnect assembly of FIG. 5B that shows the physical arrangement of a trace with respect to a top carrier film in the combined applicable carrier film, interconnect assembly after disposition on a solar cell, in accordance with an embodiment of the present invention.

FIG. 6A is a plan view of an integrated busbar-solar-cell-current collector that shows the physical interconnection of a terminating solar cell with a terminating busbar in the integrated busbar-solar-cell-current collector, in accordance with an embodiment of the present invention.

FIG. 6B is a cross-sectional, elevation view of the integrated busbar-solar-cell-current collector of FIG. 6A that shows the physical interconnection of the terminating solar cell with the terminating busbar in the integrated busbar-solar-cell-current collector, in accordance with an embodiment of the present invention.

FIG. 7A is a combined cross-sectional elevation and perspective view of a roll-to-roll, interconnect-assembly fabricator for fabricating the interconnect assembly from a first roll of top carrier film and from a dispenser of conductive-trace material, in accordance with an embodiment of the present invention.

FIG. 7B is a combined cross-sectional elevation and perspective view of a roll-to-roll, laminated-interconnect-assembly fabricator for fabricating a laminated-interconnect assembly from the first roll of top carrier film, from a second roll of bottom carrier film and from the dispenser of conductive-trace material, in accordance with an embodiment of the present invention.

FIG. 8 is flow chart illustrating a method for roll-to-roll fabrication of an interconnect assembly, in accordance with an embodiment of the present invention.

FIG. 9 is flow chart illustrating a method for interconnecting two solar cells, in accordance with an embodiment of the present invention.

FIG. 10 is a plan view of a solar-cell module combined with external-connection mechanism mounted to respective edge regions and in-laminate-diode assembly, in accordance with an embodiment of the present invention.

FIG. 11A is a schematic diagram of a diode used to by-pass current around a solar cell and electrically coupled in parallel with the solar cell, in accordance with an embodiment of the present invention.

FIG. 11B is a schematic diagram of a diode used to by-pass current around a plurality of solar cells and electrically coupled in parallel with the plurality of solar cells that are electrically coupled in parallel, in accordance with an embodiment of the present invention.

FIG. 11C is a schematic diagram of a diode used to by-pass current around a plurality of solar cells and electrically coupled in parallel with the plurality of solar cells that are electrically coupled in series, in accordance with an embodiment of the present invention.

FIG. 11D is a schematic diagram of a diode used to by-pass current around a plurality of solar cells and electrically coupled in parallel with the plurality of solar cells that are electrically coupled in series and in parallel, in accordance with an embodiment of the present invention.

FIG. 12A is a plan view of a solar-cell array including a plurality of solar-cell modules combined with centrally-mounted junction boxes and in-laminate-diode assemblies, in accordance with an embodiment of the present invention.

FIG. 12B is a plan view of a solar-cell array including a plurality of solar-cell modules combined with external-connection mechanism mounted to respective edge regions and in-laminate-diode assemblies, in accordance with an embodiment of the present invention.

FIG. 13 is a combined perspective-plan and expanded view of in-laminate-diode sub-assemblies showing an arrangement of a diode therein, in accordance with an embodiment of the present invention.

FIG. 14 is a combined plan and perspective view of a lead at a cut corner of a back glass of a solar-cell module, in accordance with an embodiment of the present invention.

FIG. 15A is a plan view of a first junction box of a first solar-cell module with a female receptacle and a second junction box of a second solar-cell module with a male connector configured to allow interconnection with the first solar-cell module, in accordance with an embodiment of the present invention.

FIG. 15B is a plan view of an interconnector with a male connector integrally attached to the second junction box of the second solar-cell module and configured to allow interconnection with the first junction box with the female receptacle of the first solar-cell module, in accordance with an embodiment of the present invention.

FIG. 15C is a plan view of an interconnector with a female receptacle integrally attached to the first junction box of the first solar-cell module, and of the interconnector with the male connector integrally attached to the second junction box of the second solar-cell module and configured to allow interconnection with the first junction box, in accordance with an embodiment of the present invention.

FIG. 16 is a first cross-sectional elevation view of a combined solar-cell, power-loss-inhibiting current-collector that shows the physical arrangement of a power-loss-inhibiting current-collector, including a trace and current-limiting portion of the power-loss-inhibiting current-collector, which includes an example positive-temperature-coefficient-of-electrical-resistance (PTCR) structure, in a low-electrical-resistance state under normal operating conditions, on a light-facing side of the solar cell, in accordance with an embodiment of the present invention.

FIG. 17 is a second cross-sectional elevation view of a combined solar-cell, power-loss-inhibiting current-collector that shows the physical arrangement of a power-loss-inhibiting current-collector, including a trace and current-limiting portion of the power-loss-inhibiting current-collector, which includes the example PTCR structure, in a high-electrical-resistance state that develops with occurrence of a shunt defect in the solar cell in proximity to a contact between a segment of the power-loss-inhibiting current-collector and the solar cell, on a light-facing side of the solar cell, in accordance with an embodiment of the present invention.

FIG. 18A is a cross-sectional, elevation view of a first example of a power-loss-inhibiting current-collector that shows the physical structure of the trace, including an electrically conductive core, and the PTCR structure in the current-limiting portion of the power-loss-inhibiting current-collector, including a low-conductivity matrix portion and a plurality of high-conductivity portions dispersed in the matrix portion, in accordance with an embodiment of the present invention.

FIG. 18B is a cross-sectional, elevation view of a second example of a power-loss-inhibiting current-collector that shows the physical structure of the trace, including an electrically conductive core and at least one overlying layer, and the PTCR structure in the current-limiting portion of the power-loss-inhibiting current-collector, including a low-conductivity matrix portion and a plurality of high-conductivity portions dispersed in the matrix portion, in accordance with an embodiment of the present invention.

FIG. 18C is a cross-sectional, elevation view of a third example of a power-loss-inhibiting current-collector that shows the physical structure of power-loss-inhibiting current-collector for a current-limiting portion of the power-loss-inhibiting current-collector integrated with the trace, in accordance with an embodiment of the present invention.

FIG. 18D is a cross-sectional, elevation view of a fourth example of a power-loss-inhibiting current-collector that shows the physical structure of the trace, including an electrically conductive core, and the current-limiting portion of the power-loss-inhibiting current-collector, in accordance with an embodiment of the present invention.

FIG. 18E is a cross-sectional, elevation view of a fifth example of a power-loss-inhibiting current-collector that shows the physical structure of the trace, including an electrically conductive core and at least one overlying layer, and the current-limiting portion of the power-loss-inhibiting current-collector, in accordance with an embodiment of the present invention.

The drawings referred to in this description should not be understood as being drawn to scale except if specifically noted.

### DESCRIPTION OF EMBODIMENTS

Reference will now be made in detail to the various embodiments of the present invention. While the invention will be described in conjunction with the various embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following description of embodiments of the present invention, numerous specific details are set forth in order to provide a thorough understanding of the present invention. However, it should be appreciated that embodiments of the present invention may be practiced without these specific details. In other instances, well known methods, procedures, and components have not been described in detail as not to unnecessarily obscure embodiments of the present invention.

### Overview

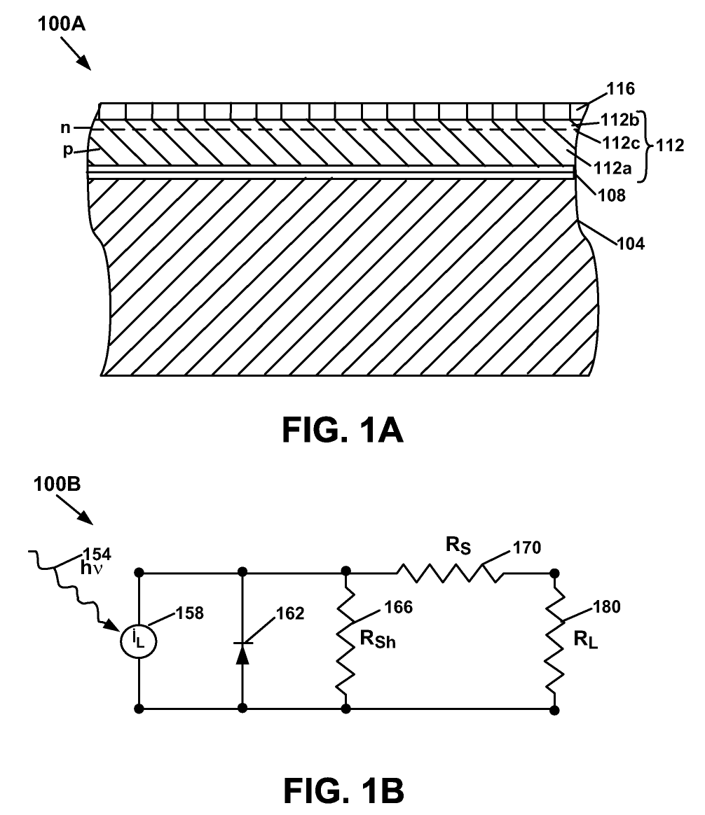

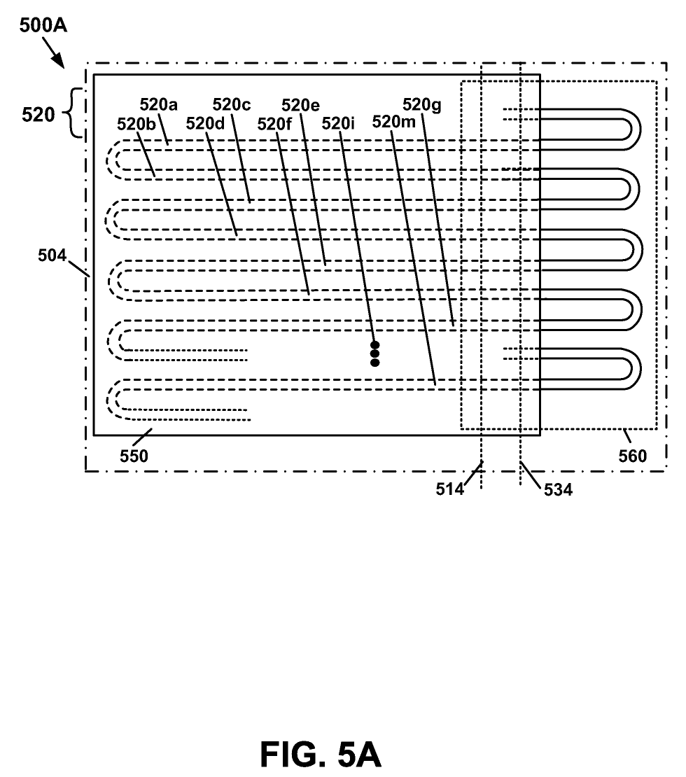

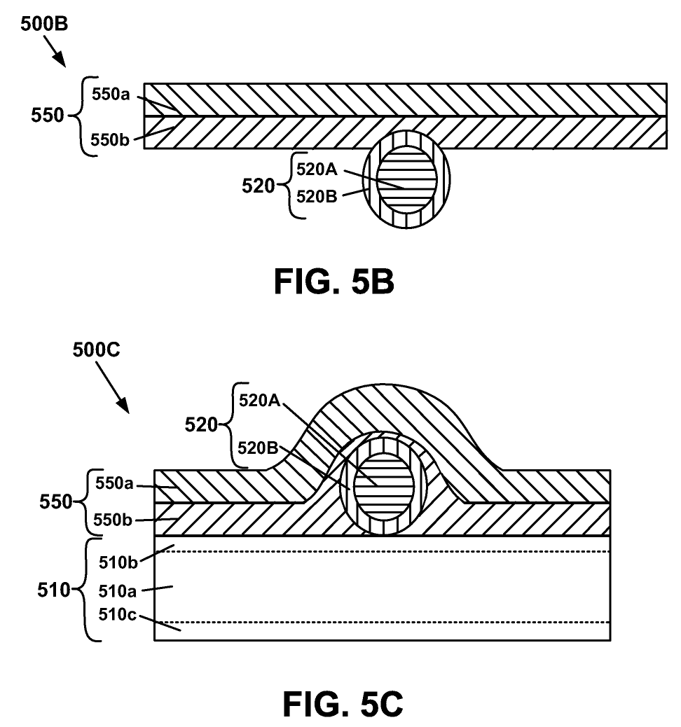

Section I describes in detail various embodiments of the present invention for an interconnect assembly (Sub-Section A), methods of fabricating the same (Sub-Section B), methods of interconnecting solar-cells (Sub-Section C), as well as a trace used in solar cells (Sub-Section D), that are incorporated as elements of a solar cell and a solar-cell module combined with a power-loss-inhibiting current-collector. FIGS. 1 through 9 illustrate specific embodiments of the present invention for the interconnect assembly so incorporated as an element of the solar-cell module combined with a power-loss-inhibiting current-collector. In particular, FIGS. 5A through 5C illustrate specific embodiments of the present invention for the collection of current from a solar cell and solar cells in the solar-cell module that may be combined with a power-loss-inhibiting current-collector.

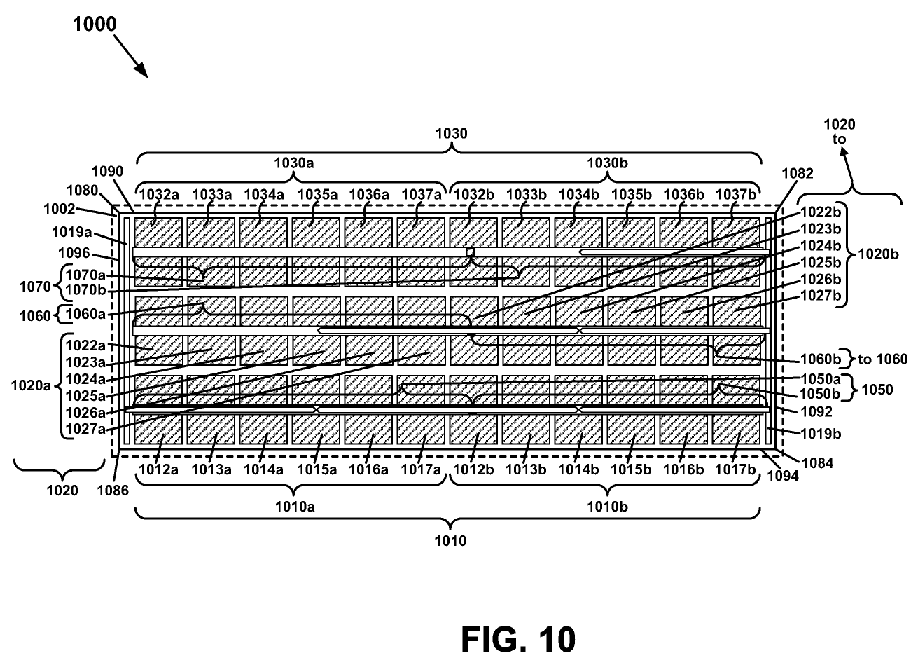

Section II provides a detailed description of various embodiments of the present invention for the solar-cell module combined with in-laminate diodes and external-connection mechanisms mounted to respective edge regions that are incorporated as elements of a solar-cell module and a solar-cell array combined with a power-loss-inhibiting current-collector. FIGS. 10 through 15 illustrate detailed arrangements of element combinations for the solar-cell module combined with in-laminate diodes and external-connection mechanisms mounted to respective edge regions that are incorporated as elements of a solar-cell module and a solar-cell array that may be combined with a power-loss-inhibiting current-collector, in accordance with embodiments of the present invention.

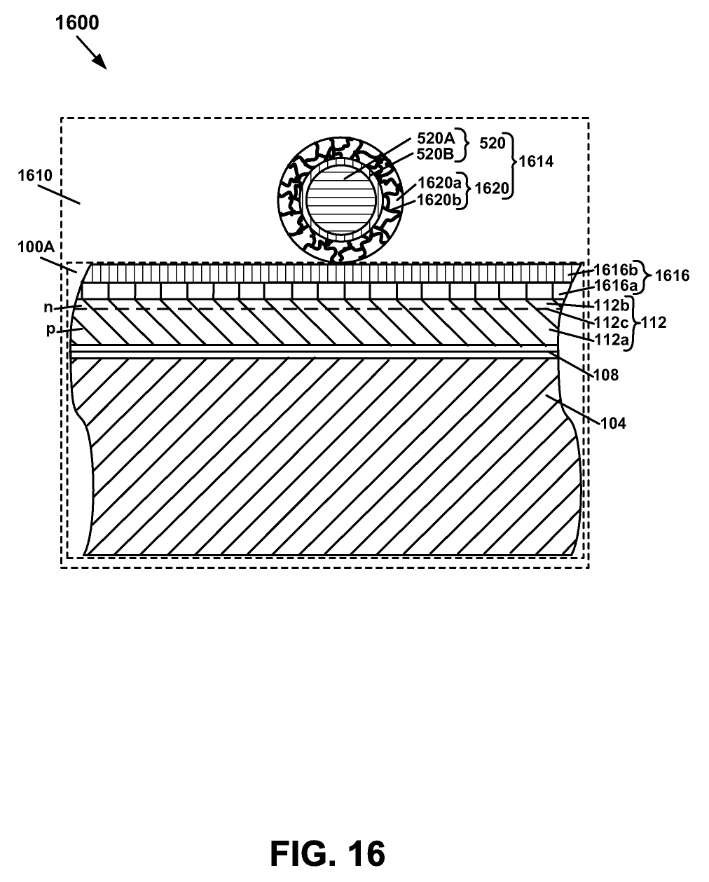

Section III provides a detailed description of various embodiments of the present invention for the power-loss-inhibiting current-collector and the combined solar-cell, power-loss-inhibiting current-collector. FIGS. 16, 17 and 18A through 18E illustrate detailed arrangements of element combinations for the power-loss-inhibiting current-collector and the combined solar-cell, power-loss-inhibiting current-collector, in accordance with embodiments of the present invention.

### Section I:

### Sub-Section A: Physical Description of Embodiments of the Present Invention for an Interconnect Assembly

With reference to FIG. 1A, in accordance with an embodiment of the present invention, a cross-sectional elevation view of a layer structure of a solar cell 100A is shown. The solar cell 100A includes a metallic substrate 104. In accordance with an embodiment of the present invention, an absorber layer 112 is disposed on the metallic substrate 104; the absorber layer 112 may include a layer of the material copper indium gallium diselenide (CIGS) having the chemical formula Cu(In₁₋ₓGaₓ)Se₂, where x may be a decimal less than one but greater than zero that determines the relative amounts of the constituents, indium, In, and gallium, Ga. Alternatively, semiconductors having the chalcopyrite crystal structure, for example, chemically homologous compounds with the compound CIGS having the chalcopyrite crystal structure, in which alternative elemental constituents are substituted for Cu, In, Ga, and/or Se, may be used as the absorber layer 112. Moreover, in embodiments of the present invention, it should be noted that semiconductors, such as silicon and cadmium telluride, as well as other semiconductors, may be used as the absorber layer 112.

As shown, the absorber layer 112 includes a p-type portion 112a and an n-type portion 112b. As a result, a pn homojunction 112c is produced in the absorber layer 112 that serves to separate charge carriers that are created by light incident on the absorber layer 112. To facilitate the efficient conversion of light energy to charge carriers in the absorber layer 112, the composition of the p-type portion 112a of the absorber layer 112 may vary with depth to produce a graded band gap of the absorber layer 112. Alternatively, the absorber layer 112 may include only a p-type chalcopyrite semiconductor layer, such as a CIGS material layer, and a pn heterojunction may be produced between the absorber layer 112 and an n-type layer, such as a metal oxide, metal sulfide or metal selenide, disposed on its top surface in place of the n-type portion 112b shown in FIG. 1A. However, embodiments of the present invention are not limited to pn junctions fabricated in the manner described above, but rather a generic pn junction produced either as a homojunction in a single semiconductor material, or alternatively a heterojunction between two different semiconductor materials, is within the spirit and scope of embodiments of the present invention. Moreover, in embodiments of the present invention, it should be noted that semiconductors, such as silicon and cadmium telluride, as well as other semiconductors, may be used as the absorber layer 112.

In accordance with an embodiment of the present invention, on the surface of the n-type portion 112b of the absorber layer 112, one or more transparent electrically conductive oxide (TCO) layers 116 are disposed, for example, to provide a means for collection of current from the absorber layer 112 for conduction to an external load. As used herein, it should be noted that the phrase “collection of current” refers to collecting current carriers of either sign, whether they be positively charged holes or negatively charged electrons; for the structure shown in FIG. 1A in which the TCO layer is disposed on the n-type portion 112b, the current carriers collected under normal operating conditions are negatively charged electrons; but, embodiments of the present invention apply, without limitation thereto, to solar cell configurations where a p-type layer is disposed on an n-type absorber layer, in which case the current carriers collected may be positively charged holes. The TCO layer 116 may include zinc oxide, ZnO, or alternatively a doped conductive oxide, such as aluminum zinc oxide (AZO), AlₓZn₁₋ₓO_{y}, and indium tin oxide (ITO), InₓSn₁₋ₓO_{y}, where the subscripts x and y indicate that the relative amount of the constituents may be varied. Alternatively, the TCO layer 116 may be composed of a plurality of conductive oxide layers. These TCO layer materials may be sputtered directly from an oxide target, or alternatively the TCO layer may be reactively sputtered in an oxygen atmosphere from a metallic target, such as zinc, Zn, Al—Zn alloy, or In—Sn alloy targets. For example, the zinc oxide may be deposited on the absorber layer 112 by sputtering from a zinc-oxide-containing target; alternatively, the zinc oxide may be deposited from a zinc-containing target in a reactive oxygen atmosphere in a reactive-sputtering process. The reactive-sputtering process may provide a means for doping the absorber layer 112 with an n-type dopant, such as zinc, Zn, or indium, In, to create a thin n-type portion 112b, if the partial pressure of oxygen is initially reduced during the initial stages of sputtering a metallic target, such as zinc, Zn, or indium, In, and the layer structure of the solar cell 100A is subsequently annealed to allow interdiffusion of the zinc, Zn, or indium, In, with CIGS material used as the absorber layer 112. Alternatively, sputtering a compound target, such as a metal oxide, metal sulfide or metal selenide, may also be used to provide the n-type layer, as described above, on the p-type portion 112a of the absorber layer 112.

With further reference to FIG. 1A, in accordance with the embodiment of the present invention, a conductive backing layer 108 may be disposed between the absorber layer 112 and the metallic substrate 104 to provide a diffusion barrier between the absorber layer 112 and the metallic substrate 104. The conductive backing layer 108 may include molybdenum, Mo, or other suitable metallic layer having a low propensity for interdiffusion with an absorber layer 112, such as one composed of CIGS material, as well as a low diffusion coefficient for constituents of the substrate. Moreover, the conductive backing layer 108 may provide other functions in addition to, or independent of, the diffusion-barrier function, for example, a light-reflecting function, for example, as a light-reflecting layer, to enhance the efficiency of the solar cell, as well as other functions. The embodiments recited above for the conductive backing layer 108 should not be construed as limiting the function of the conductive backing layer 108 to only those recited, as other functions of the conductive backing layer 108 are within the spirit and scope of embodiments of the present invention, as well.

With reference now to FIG. 1B, in accordance with an embodiment of the present invention, a schematic diagram of a model circuit 100B of a solar cell that is electrically connected to a load is shown. The model circuit 100B of the solar cell includes a current source 158 that generates a photocurrent, i_{L}. As shown in FIG. 1A, the current source 158 is such as to produce counterclockwise electrical current, or equivalently an clockwise electron-flow, flowing around each of the loops of the circuit shown; embodiments of the present invention also apply, without limitation thereto, to solar-cell circuits in which the electrical current flows in a clockwise direction, or equivalently electrons flow in a counterclockwise direction. The photocurrent, i_{L}, is produced when a plurality of incident photons, light particles, of which one example photon 154 with energy, hv, is shown, produce electron-hole pairs in the absorber layer 112 and these electron-hole pairs are separated by the pn homojunction 112c, or in the alternative, by a pn heterojunction as described above. It should be appreciated that the energy, hv, of each incident photon of the plurality of photons should exceed the band-gap energy, E_{g}, that separates the valence band from the conduction band of the absorber layer 112 to produce such electron-hole pairs, which result in the photocurrent, i_{L}.

The model circuit 100B of the solar cell further includes a diode 162, which corresponds to recombination currents, primarily at the pn homojunction 112c, that are shunted away from the connected load. As shown in FIG. 1B, the diode is shown having a polarity consistent with electrical current flowing counterclockwise, or equivalently electron-flow clockwise, around the loops of the circuit shown; embodiments of the present invention apply, without limitation thereto, to a solar cell in which the diode of the model circuit has the opposite polarity in which electrical current flows clockwise, or equivalently electron-flow flows counterclockwise, around the loops of the circuit shown. In addition, the model circuit 100B of the solar cell includes two parasitic resistances corresponding to a shunt resistor 166 with shunt resistance, R_{Sh}, and to a series resistor 170 with series resistance, R_{S}. The solar cell may be connected to a load represented by a load resistor 180 with load resistance, R_{L}. Thus, the circuit elements of the solar cell include the current source 158, the diode 162 and the shunt resistor 166 connected across the current source 158, and the series resistor 170 connected in series with the load resistor 180 across the current source 158, as shown. As the shunt resistor 166, like the diode 162, are connected across the current source 158, these two circuit elements are associated with internal electrical currents within the solar cell shunted away from useful application to the load. As the series resistor 170 connected in series with the load resistor 180 are connected across the current source 158, the series resistor 170 is associated with internal resistance of the solar cell that limits the electrical current to the load.

With further reference to FIG. 1 B, it should be recognized that the shunt resistance may be associated with surface leakage currents that follow paths at free surfaces that cross the pn homojunction 112c; free surfaces are usually found at the edges of the solar cell along the side walls of the device that define its lateral dimensions; such free surfaces may also be found at discontinuities in the absorber layer 112 that extend past the pn homojunction 112c. The shunt resistance may also be associated with shunt defects which may be present that shunt electrical current away from the load. A small value of the shunt resistance, R_{Sh}, is undesirable as it lowers the open circuit voltage, V_{OC}, of the solar cell, which directly affects the efficiency of the solar cell. Moreover, it should also be recognized that the series resistance, R_{S}, is associated with: the contact resistance between the p-type portion 112a and the conductive backing layer 108, the bulk resistance of the p-type portion 112a, the bulk resistance of the n-type portion 112b, the contact resistance between the n-type portion 112b and TCO layer 116, and other components, such as conductive leads, and connections in series with the load. These latter sources of series resistance, conductive leads, and connections in series with the load, are germane to embodiments of the present invention as interconnect assemblies, which is subsequently described. A large value of the series resistance, R_{S}, is undesirable as it lowers the short circuit current, I_{SC}, of the solar cell, which also directly affects the efficiency of the solar cell.

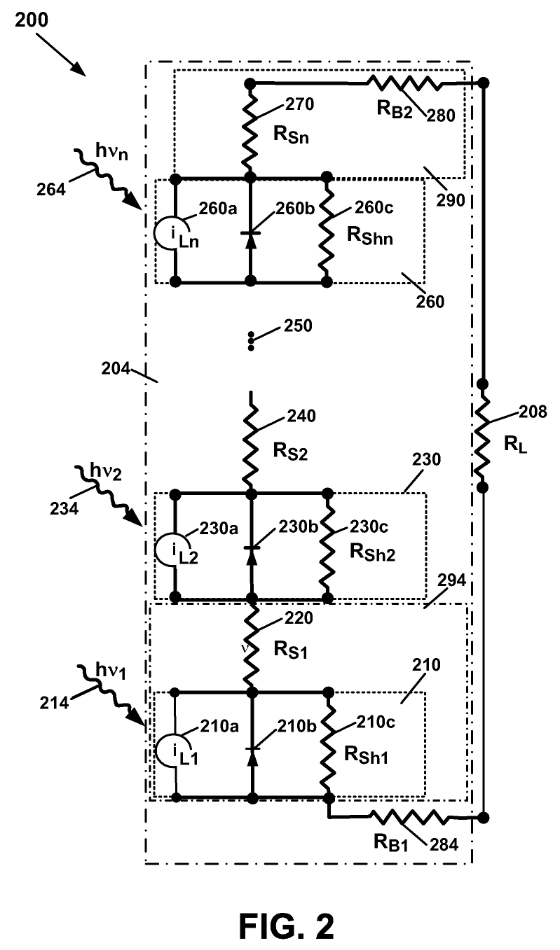

With reference now to FIG. 2, in accordance with an embodiment of the present invention, a schematic diagram of a model circuit 200 of a solar-cell module 204 that is coupled to a load is shown. The load is represented by a load resistor 208 with load resistance, R_{L}, as shown. The solar-cell module 204 of the model circuit 200 includes a plurality of solar cells: a first solar cell 210 including a current source 210a that generates a photocurrent, i_{L1}, produced by example photon 214 with energy, hv₁, a diode 210b and a shunt resistor 210c with shunt resistance, R_{Sh1}; a second solar cell 230 including a current source 230a that generates a photocurrent, i_{L2}, produced by example photon 234 with energy, hv₂, a diode 230b and a shunt resistor 230c with shunt resistance, R_{Sh2}; and, a terminating solar cell 260 including a current source 260a that generates a photocurrent, i_{L3}, produced by example photon 264 with energy, hvₙ, a diode 260b and a shunt resistor 260c with shunt resistance, R_{Shn}. Parasitic series internal resistances of the respective solar cells 210, 230 and 260 have been omitted from the schematic diagram to simplify the discussion. Instead, series resistors with series resistances, R_{S1}, R_{S2} and R_{Sn} are shown disposed in the solar-cell module 204 of the model circuit 200 connected in series with the solar cells 210, 230 and 260 and the load resistor 208.

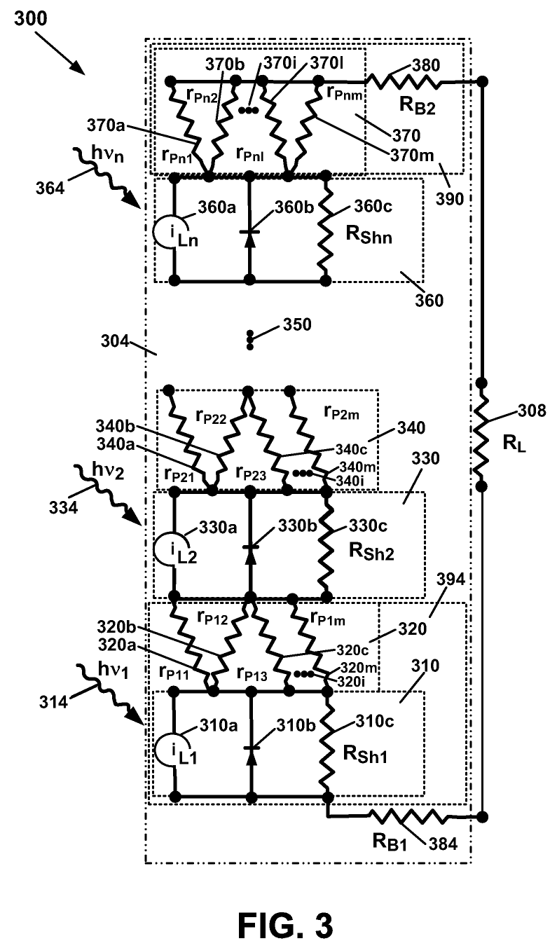

As shown in FIGS. 2 and 3, the current sources are such as to produce counterclockwise electrical current, or equivalently an clockwise electron-flow, flowing around each of the loops of the circuit shown; embodiments of the present invention also apply, without limitation thereto, to solar-cell circuits in which the electrical current flows in a clockwise direction, or equivalently electrons flow in a counterclockwise direction. Similarly, as shown in FIGS. 2 and 3, the diode is shown having a polarity consistent with electrical current flowing counterclockwise, or equivalently electron-flow clockwise, around the loops of the circuit shown; embodiments of the present invention apply, without limitation thereto, to a solar cell in which the diode of the model circuit has the opposite polarity in which electrical current flows clockwise, or equivalently electron-flow flows counterclockwise, around the loops of the circuit shown.

With further reference to FIG. 2, in accordance with an embodiment of the present invention, the series resistors with series resistances R_{S1} and R_{S2} correspond to interconnect assemblies 220 and 240, respectively. Series resistor with series resistance, R_{S1}, corresponding to interconnect assembly 220 is shown configured both to collect current from the first solar cell 210 and to interconnect electrically to the second solar cell 230. Series resistor with series resistance, R_{Sn}, corresponds to an integrated solar-cell, current collector 270. The ellipsis 250 indicates additional solar cells and interconnect assemblies (not shown) coupled in alternating pairs in series in model circuit 200 that make up the solar-cell module 204. Also, in series with the solar cells 210, 230 and 260 are a first busbar 284 and a terminating busbar 280 with series resistances R_{B1} and R_{B2}, respectively, that carry the electrical current generated by solar-cell module 204 to the load resistor 208. The series resistor with resistance R_{Sn}, corresponding to the integrated solar-cell, current collector 270, and R_{B2}, corresponding to the terminating busbar 280, in combination correspond to a integrated busbar-solar-cell-current collector 290 coupling the terminating solar cell 260 with the load resistor 208. In addition, series resistor with resistance R_{S1}, corresponding to interconnect assembly 220, and first solar cell 210 in combination correspond to a combined solar-cell, interconnect assembly 294.

As shown in FIG. 2 and as used herein, it should be noted that the phrases “to collect current,” “collecting current” and “current collector” refer to collecting, transferring, and/or transmitting current carriers of either sign, whether they be positively charged holes or negatively charged electrons; for the structures shown in FIGS. 1A-B, 2, 3, 4A-F, 5A-C and 6A-B, in which an interconnect assembly is disposed above and electrically coupled to an n-type portion of the solar cell, the current carriers collected under normal operating conditions are negatively charged electrons. Moreover, embodiments of the present invention apply, without limitation thereto, to solar cell configurations where a p-type layer is disposed on an n-type absorber layer, in which case the current carriers collected may be positively charged holes, as would be the case for solar cells modeled by diodes and current sources of opposite polarity to those of FIGS. 1A-B, 2, 3, 4A-F, 5A-C and 6A-B. Therefore, in accordance with embodiments of the present invention, a current collector and associated interconnect assembly that collects current may, without limitation thereto, collect, transfer, and/or transmit charges associated with an electrical current, and/or charges associated with an electron-flow, as for either polarity of the diodes and current sources described herein, and thus for either configuration of a solar cell with an n-type layer disposed on and electrically coupled to a p-type absorber layer or a p-type layer disposed on and electrically coupled to an n-type absorber layer, as well as other solar cell configurations.

With further reference to FIG. 2, in accordance with an embodiment of the present invention, the series resistances of the interconnect assemblies 220 and 240, integrated solar-cell, current collector 270, and the interconnect assemblies included in ellipsis 250 can have a substantial net series resistance in the model circuit 200 of the solar-cell module 204, unless the series resistances of the interconnect assemblies 220 and 240, integrated solar-cell, current collector 270, and the interconnect assemblies included in ellipsis 250 are made small. If a large plurality of solar cells are connected in series, the short circuit current of the solar-cell module, I_{SCM}, may be reduced, which also directly affects the solar-cell-module efficiency analogous to the manner in which solar-cell efficiency is reduced by a parasitic series resistance, R_{S}, as described above with reference to FIG. 1. Embodiments of the present invention provide for diminishing the series resistances of the interconnect assemblies 220 and 240, integrated solar-cell, current collector 270, and the interconnect assemblies included in ellipsis 250.

With reference now to FIG. 3, in accordance with embodiments of the present invention, a schematic diagram of a model circuit 300 of a solar-cell module 304 is shown that illustrates embodiments of the present invention such that the series resistances of the interconnect assemblies 320 and 340, integrated solar-cell, current collector 370, and the interconnect assemblies included in ellipsis 350 are made small. The solar-cell module 304 is coupled to a load represented by a load resistor 308 with load resistance, R_{L}, as shown. The solar-cell module 304 of the model circuit 300 includes a plurality of solar cells: a first solar cell 310 including a current source 310a that generates a photocurrent, i_{L1}, produced by example photon 314 with energy, hv₁, a diode 310b and a shunt resistor 310c with shunt resistance, R_{Sh1}; a second solar cell 330 including a current source 330a that generates a photocurrent, i_{L2}, produced by example photon 334 with energy, hv₂, a diode 330b and a shunt resistor 330c with shunt resistance, R_{Sh2}; and, a terminating solar cell 360 including a current source 360a that generates a photocurrent, i_{L3}, produced by example photon 364 with energy, hvₙ, a diode 360b and a shunt resistor 360c with shunt resistance, R_{Shn}.

With further reference to FIG. 3, in accordance with an embodiment of the present invention, the interconnect assemblies 320 and 340 and the integrated solar-cell, current collector 370, with respective equivalent series resistances R_{S1}, R_{S2} and R_{Sn} are shown disposed in the solar-cell module 304 of the model circuit 300 connected in series with the solar cells 310, 330 and 360 and the load resistor 308. The ellipsis 350 indicates additional solar cells and interconnect assemblies (not shown) coupled in alternating pairs in series in model circuit 300 that make up the solar-cell module 304. Also, in series with the solar cells 310, 330 and 360 are a first busbar 384 and a terminating busbar 380 with series resistances R_{B1} and R_{B2}, respectively, that carry the electrical current generated by solar-cell module 304 to the load resistor 308. The integrated solar-cell, current collector 370 with resistance R_{Sn}, and the series resistor with series resistance R_{B2}, corresponding to the terminating busbar 380, in combination correspond to an integrated busbar-solar-cell-current collector 390 coupling the terminating solar cell 360 with the load resistor 308. In addition, interconnect assembly 320 with resistance, R_{S2}, and solar cell 310 in combination correspond to a combined solar-cell, interconnect assembly 394.

With further reference to FIG. 3, in accordance with embodiments of the present invention, the interconnect assembly 320 includes a trace including a plurality of electrically conductive portions, identified with resistors 320a, 320b, 320c, and 320m with respective resistances, r_{P11}, r_{P12}, r_{P13} and r_{P1m}, and the ellipsis 320i indicating additional resistors (not shown). It should be noted that although the plurality of electrically conductive portions of the trace are modeled here as discrete resistors the interconnection with solar cell 330 is considerably more complicated involving the distributed resistance in the TCO layer of the solar cell, which has been omitted for the sake of elucidating functional features of embodiments of the present invention. Therefore, it should be understood that embodiments of the present invention may also include, without limitation thereto, the effects of such distributed resistances on the trace. The plurality of electrically conductive portions, without limitation thereto, identified with resistors 320a, 320b, 320c, 320i, and 320m, are configured both to collect current from the first solar cell 310 and to interconnect electrically to the second solar cell 330. The plurality of electrically conductive portions, identified with resistors 320a, 320b, 320c, 320i, and 320m, are configured such that upon interconnecting the first solar cell 310 and the second solar cell 330 the plurality of electrically conductive portions are connected electrically in parallel between the first solar cell 310 and the second solar cell 330.

Thus, in accordance with embodiments of the present invention, the plurality of electrically conductive portions is configured such that equivalent series resistance, R_{S1}, of the interconnect assembly 320 including the parallel network of resistors 320a, 320b, 320c, 320i, and 320m, is less than the resistance of any one resistor in the parallel network. Therefore, upon interconnecting the first solar cell 310 with the second solar cell 330, the equivalent series resistance, R_{S1}, of the interconnect assembly 320, is given approximately, omitting the effects of distributed resistances at the interconnects with the first and second solar cells 310 and 330, by the formula for a plurality of resistors connected electrically in parallel, viz. R_{S1}=1/[Σ(1/r_{P1i})], where r_{P1i} is the resistance of the ith resistor in the parallel-resistor network, and the sum, Σ, is taken over all of the resistors in the network from i=1 to m. Hence, by connecting the first solar cell 310 to the second solar cell 330, with the interconnect assembly 320, the series resistance, R_{S1}, of the interconnect assembly 320 can be reduced lowering the effective series resistance between solar cells in the solar-cell module 304 improving the solar-cell-module efficiency.

Moreover, in accordance with embodiments of the present invention, the configuration of the plurality of electrically conductive portions due to this parallel arrangement of electrically conductive portions between the first solar cell 310 and the second solar cell 330 provides a redundancy of electrical current carrying capacity between interconnected solar cells should one of the plurality of electrically conductive portions become damaged, or its reliability become impaired. Thus, embodiments of the present invention provide that the plurality of electrically conductive portions is configured such that solar-cell efficiency is substantially undiminished in an event that any one of the plurality of electrically conductive portions is conductively impaired, because the loss of electrical current through any one electrically conductive portion will be compensated for by the plurality of other parallel electrically conductive portions coupling the first solar cell 310 with the second solar cell 330. It should be noted that as used herein the phrase, “substantially undiminished,” with respect to solar-cell efficiency means that the solar-cell efficiency is not reduced below an acceptable level of productive performance.

With further reference to FIG. 3, in accordance with embodiments of the present invention, the interconnect assembly 340 includes a trace including a plurality of electrically conductive portions identified with resistors 340a, 340b, 340c, and 340m with respective resistances, r_{P2}1, r_{P22} , r_{P23} and r_{P2m}, and the ellipsis 340i indicating additional resistors (not shown). The plurality of electrically conductive portions, without limitation thereto, identified with resistors 340a, 340b, 340c, 340i, and 340m, are configured both to collect current from a first solar cell 330 and to interconnect electrically to a second solar cell, in this case a next adjacent one of the plurality of solar cells represented by ellipsis 350. From this example, it should be clear that for embodiments of the present invention a first solar cell and a second solar cell refer, without limitation thereto, to just two adjacent solar cells configured in series in the solar-cell module, and need not be limited to a solar cell located first in line of a series of solar cells in a solar-cell module, nor a solar cell located second in line of a series of solar cells in a solar-cell module. The resistors 340a, 340b, 340c, 340i, and 340m, are configured such that upon interconnecting the first solar cell 330 and the second solar cell, in this case the next adjacent solar cell of the plurality of solar cells represented by ellipsis 350, the resistors 340a, 340b, 340c, 340i, and 340m, are coupled electrically in parallel between the first solar cell 330 and the second solar cell, the next adjacent solar cell of the plurality of solar cells represented by ellipsis 350.

Thus, in accordance with embodiments of the present invention, the plurality of electrically conductive portions is configured such that series resistance, R_{S2}, of the interconnect assembly 340 including the parallel network of resistors 340a, 340b, 340c, 340i, and 340m, is less than the resistance of any one resistor in the network. Hence, the series resistance, R_{S2}, of the interconnect assembly 340 can be reduced lowering the effective series resistance between solar cells in the solar-cell module improving the solar-cell-module efficiency of the solar-cell module 304. Moreover, the plurality of electrically conductive portions, identified with resistors 340a, 340b, 340c, 340i, and 340m, may be configured such that solar-cell efficiency is substantially undiminished in an event that any one of the plurality of electrically conductive portions is conductively impaired.

With further reference to FIG. 3, in accordance with embodiments of the present invention, the combined solar-cell, interconnect assembly 394 includes the first solar cell 310 and the interconnect assembly 320; the interconnect assembly 320 includes a trace disposed above a light-facing side of the first solar cell 310, the trace further including a plurality of electrically conductive portions, identified with resistors 320a, 320b, 320c, and 320m with respective resistances, r_{P21}, r_{P22}, r_{P23} and r_{P2m}, and the ellipsis 320i indicating additional resistors (not shown). All electrically conductive portions of the plurality of electrically conductive portions, without limitation thereto, identified with resistors 320a, 320b, 320c, 320i, and 320m, are configured to collect current from the first solar cell 310 and to interconnect electrically to the second solar cell 330. In addition, the plurality of electrically conductive portions, identified with resistors 320a, 320b, 320c, 320i, and 320m, may be configured such that solar-cell efficiency is substantially undiminished in an event that any one of the plurality of electrically conductive portions is conductively impaired. Also, any of the plurality of electrically conductive portions, identified with resistors 320a, 320b, 320c, 320i, and 320m, may be configured to interconnect electrically to the second solar cell 330.

With further reference to FIG. 3, in accordance with embodiments of the present invention, the integrated busbar-solar-cell-current collector 390 includes the terminating busbar 380 and the integrated solar-cell, current collector 370. The integrated solar-cell, current collector 370 includes a trace including a plurality of electrically conductive portions, identified with resistors 370a, 370b, 370l, and 370m with respective resistances, r_{Pn1}, r_{Pn2}, r_{Pnl} and r_{Pnm}, and the ellipsis 370i indicating additional resistors (not shown). The plurality of electrically conductive portions, without limitation thereto, identified with resistors 370a, 370b, 370i, 370ₗ and 370m, are configured both to collect current from the first solar cell 310 and to interconnect electrically to the terminating busbar 380. The resistors 370a, 370b, 370i, 370ₗ and 370m, are coupled electrically in parallel between the terminating solar cell 360 and the terminating busbar 380 series resistor with series resistance, R_{B2}. Thus, the plurality of electrically conductive portions is configured such that series resistance, R_{Sn}, of the interconnect assembly 340 including the parallel network of resistors 370a, 370b, 370i, 370ₗ and 370m, is less than the resistance of any one resistor in the network.

In accordance with embodiments of the present invention, the integrated solar-cell, current collector 370 includes a plurality of integrated pairs of electrically conductive, electrically parallel trace portions. Resistors 370a, 370b, 370ₗ and 370m with respective resistances, r_{Pn1}, r_{Pn2}, r_{Pnl} and r_{Pnm}, and the ellipsis 370i indicating additional resistors (not shown) form such a plurality of integrated pairs of electrically conductive, electrically parallel trace portions when suitably paired as adjacent pair units connected electrically together as an integral unit over the terminating solar cell 360. For example, one such pair of the plurality of integrated pairs of electrically conductive, electrically parallel trace portions is pair of resistors 370a and 370b connected electrically together as an integral unit over the terminating solar cell 360, as shown. The plurality of integrated pairs of electrically conductive, electrically parallel trace portions are configured both to collect current from the terminating solar cell 360 and to interconnect electrically to the terminating busbar 380. Moreover, the plurality of integrated pairs of electrically conductive, electrically parallel trace portions is configured such that solar-cell efficiency is substantially undiminished in an event that any one electrically conductive, electrically parallel trace portion, for example, either one, but not both, of the resistors 370a and 370b of the integral pair, of the plurality of integrated pairs of electrically conductive, electrically parallel trace portions is conductively impaired.

With further reference to FIG. 3, in accordance with embodiments of the present invention, the solar-cell module 304 includes the first solar cell 310, at least the second solar cell 330 and the interconnect assembly 320 disposed above a light-facing side of an absorber layer of the first solar cell 310. The interconnect assembly 320 includes a trace including a plurality of electrically conductive portions, identified with resistors 320a, 320b, 320c, and 320m with respective resistances, r_{P11}, r_{P12} , r_{P13} and r_{P1m}, and the ellipsis 320i indicating additional resistors (not shown). The plurality of electrically conductive portions is configured both to collect current from the first solar cell 310 and to interconnect electrically to the second solar cell 330. The plurality of electrically conductive portions is configured such that solar-cell efficiency is substantially undiminished in an event that any one of the plurality of electrically conductive portions is conductively impaired.

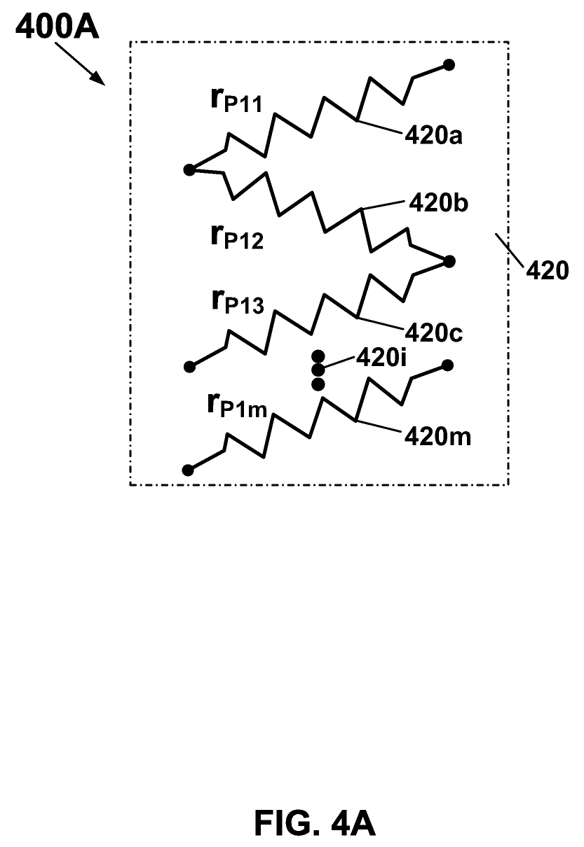

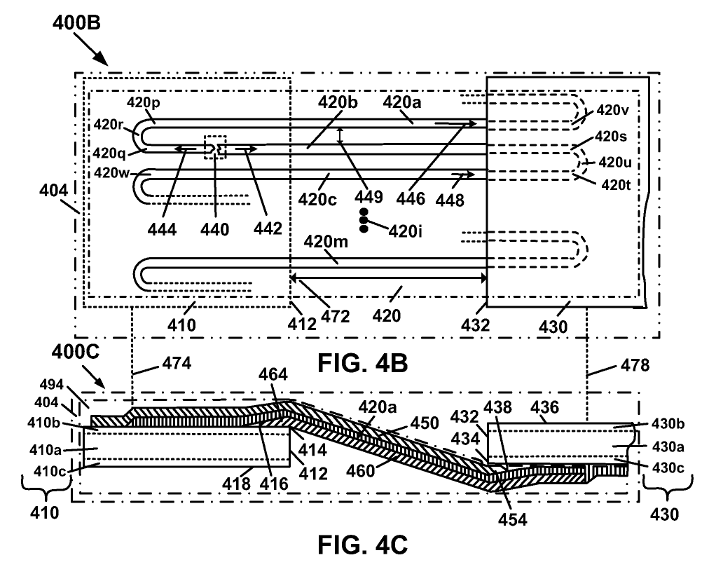

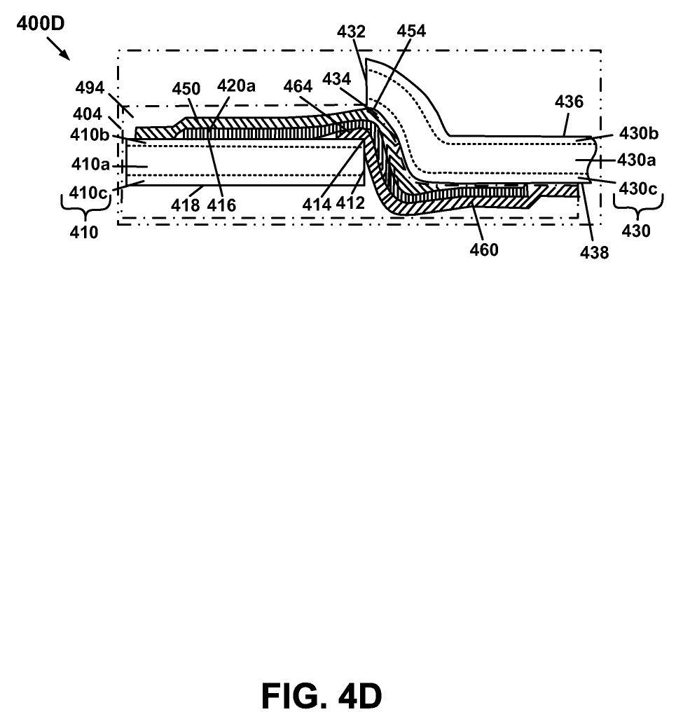

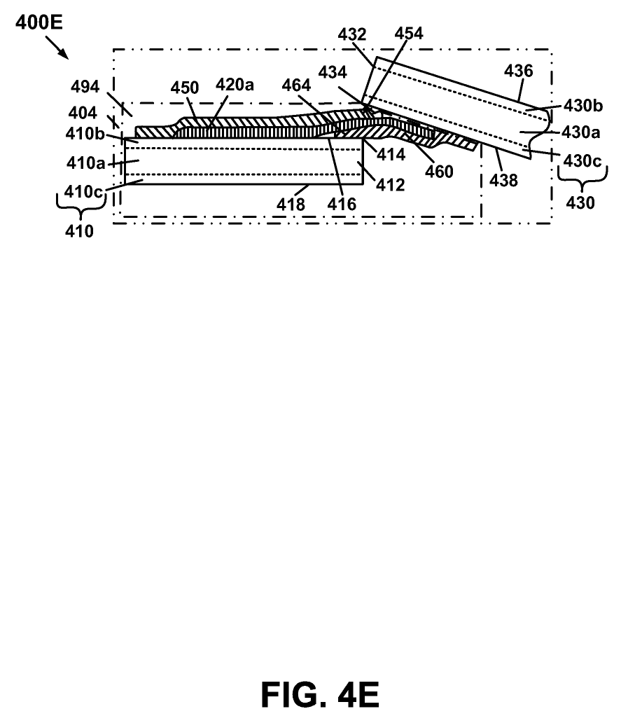

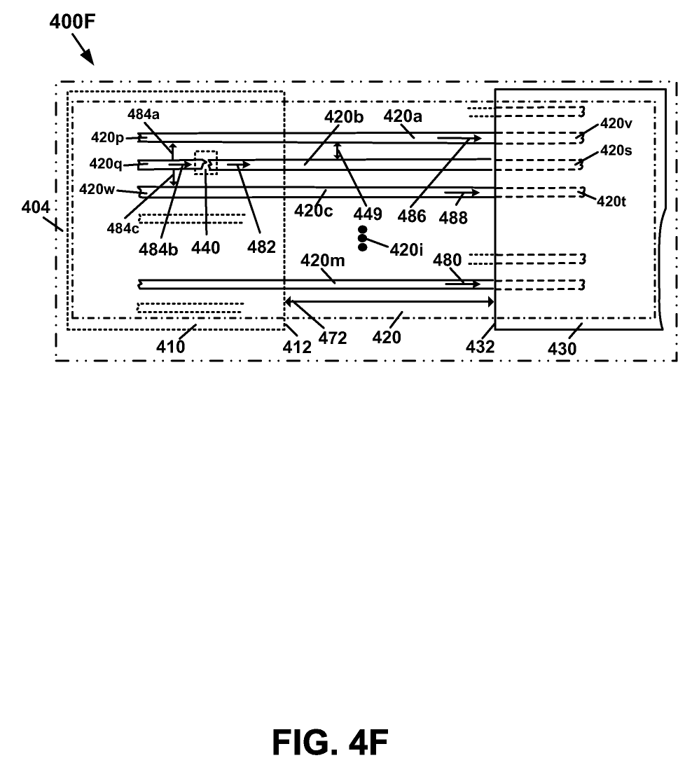

With reference now to FIGS. 4A, 4B and 4C, in accordance with embodiments of the present invention, a schematic diagram of a model circuit 400A of an interconnect assembly 420 connecting a first solar cell 410 to a second solar cell 430 of a solar-cell module 404 is shown. The interconnect assembly 420 includes a trace including a plurality of electrically conductive portions, identified with resistors 420a, 420b, 420c, and 420m with respective resistances, r_{P11}, r_{P12} , r_{P13} and r_{P1m}, and the ellipsis 420i indicating additional resistors (not shown). The plurality of electrically conductive portions, without limitation thereto, identified with resistors 420a, 420b, 420c, 420i, and 420m, are configured both to collect current from the first solar cell 410 and to interconnect electrically to the second solar cell 430. The plurality of electrically conductive portions, identified with resistors 420a, 420b, 420c, 420i, and 420m, are configured such that, upon interconnecting the first solar cell 410 and the second solar cell 430, the plurality of electrically conductive portions are connected electrically in parallel between the first solar cell 410 and the second solar cell 430. The plurality of electrically conductive portions is configured such that equivalent series resistance, R_{S1}, of the interconnect assembly 420 including the parallel network of resistors 420a, 420b, 420c, 420i, and 420m, is less than the resistance of any one resistor in the parallel network. Therefore, by connecting the first solar cell 410 to the second solar cell 430, with the interconnect assembly 420, the series resistance, R_{S1}, of the interconnect assembly 420 can be reduced lowering the effective series resistance between solar cells in the solar-cell module 404 improving the solar-cell-module efficiency.

Moreover, in accordance with embodiments of the present invention, the configuration of the plurality of electrically conductive portions due to this parallel arrangement of electrically conductive portions between the first solar cell 410 and the second solar cell 430 provides a redundancy of electrical current carrying capacity between interconnected solar cells should any one of the plurality of electrically conductive portions become damaged, or its reliability become impaired. Thus, embodiments of the present invention provide that the plurality of electrically conductive portions is configured such that solar-cell efficiency is substantially undiminished in an event that any one of the plurality of electrically conductive portions is conductively impaired, because the loss of electrical current through any one electrically conductive portion will be compensated for by the plurality of the unimpaired parallel electrically conductive portions coupling the first solar cell 410 with the second solar cell 430. It should be noted that as used herein the phrase, “substantially undiminished,” with respect to solar-cell efficiency means that the solar-cell efficiency is not reduced below an acceptable level of productive performance. In addition, in accordance with embodiments of the present invention, the plurality of electrically conductive portions may be configured in pairs of electrically conductive portions, for example, identified with resistors 420a and 420b. Thus, the plurality of electrically conductive portions may be configured such that solar-cell efficiency is substantially undiminished even in an event that, in every pair of electrically conductive portions of the plurality of electrically conductive portions, one electrically conductive portion of the pair is conductively impaired. In accordance with embodiments of the present invention, each member of a pair of electrically conductive portions may be electrically equivalent to the other member of the pair, but need not be electrically equivalent to the other member of the pair, it only being necessary that in an event one member, a first member, of the pair becomes conductively impaired the other member, a second member, is configured such that solar-cell efficiency is substantially undiminished.

With further reference to FIGS. 4B and 4C, in accordance with embodiments of the present invention, a plan view 400B of the interconnect assembly 420 of FIG. 4A is shown that details the physical interconnection of two solar cells 410 and 430 in the solar-cell module 404. The solar-cell module 404 includes the first solar cell 410, at least the second solar cell 430 and the interconnect assembly 420 disposed above a light-facing side 416 of the absorber layer of the first solar cell 410. The interconnect assembly 420 includes a trace including a plurality of electrically conductive portions 420a, 420b, 420c, 420i and 420m, previously identified herein with the resistors 420a, 420b, 420c, 420i and 420m described in FIG. 400A, where the ellipsis of 420i indicates additional electrically conductive portions (not shown). The plurality of electrically conductive portions 420a, 420b, 420c, 420i and 420m is configured both to collect current from the first solar cell 410 and to interconnect electrically to the second solar cell 430. The plurality of electrically conductive portions 420a, 420b, 420c, 420i and 420m is configured such that solar-cell efficiency is substantially undiminished in an event that any one of the plurality of electrically conductive portions 420a, 420b, 420c, 420i and 420m is conductively impaired.

With further reference to FIG. 4B, in accordance with embodiments of the present invention, the detailed configuration of the plurality of electrically conductive portions 420a, 420b, 420c, 420i and 420m is shown. The plurality of electrically conductive portions 420a, 420b, 420c, 420i and 420m further includes a first portion 420a of the plurality of electrically conductive portions 420a, 420b, 420c, 420i and 420m configured both to collect current from the first solar cell 410 and to interconnect electrically to the second solar cell 430 and a second portion 420b of the plurality of electrically conductive portions 420a, 420b, 420c, 420i and 420m configured both to collect current from the first solar cell 410 and to interconnect electrically to the second solar cell 430. The first portion 420a includes a first end 420p distal from the second solar cell 430. Also, the second portion 420b includes a second end 420q distal from the second solar cell 430. The second portion 420b is disposed proximately to the first portion 420a and electrically connected to the first portion 420a such that the first distal end 420p is electrically connected to the second distal end 420q, for example, at first junction 420r, or by a linking portion, such that the second portion 420b is configured electrically in parallel to the first portion 420a when configured to interconnect to the second solar cell 430.

With further reference to FIG. 4B, in accordance with embodiments of the present invention, the plurality of electrically conductive portions 420a, 420b, 420c, 420i and 420m may further include the second portion 420b including a third end 420s distal from the first solar cell 410 and a third portion 420c of the plurality of electrically conductive portions 420a, 420b, 420c, 420i and 420m configured both to collect current from the first solar cell 410 and to interconnect electrically to the second solar cell 430. The third portion 420c includes a fourth end 420t distal from the first solar cell 410. The third portion 420c is disposed proximately to the second portion 420b and electrically connected to the second portion 420b such that the third distal end 420s is electrically connected to the fourth distal end 420t, for example, at second junction 420u, or by a linking portion, such that the third portion 420c is configured electrically in parallel to the second portion 420b when configured to interconnect with the first solar cell 430.

With further reference to FIGS. 4B and 4C, in accordance with embodiments of the present invention, it should be noted that the nature of the parallel connection between electrically conductive portions interconnecting a first solar cell and a second solar cell is such that, for distal ends of electrically conductive portions not directly joined together, without limitation thereto, the metallic substrate of a second solar cell and a TCO layer of the first solar cell may provide the necessary electrical coupling. For example, distal ends 420v and 420s are electrically coupled through a low resistance connection through a metallic substrate 430c of second solar cell 430. Similarly, for example, distal ends 420w and 420q are electrically coupled through the low resistance connection through the TCO layer 410b of first solar cell 410.

With further reference to FIG. 4B, in accordance with embodiments of the present invention, an open-circuit defect 440 is shown such that second portion 420b is conductively impaired. FIG. 4B illustrates the manner in which the plurality of electrically conductive portions 420a, 420b, 420c, 420i and 420m is configured such that solar-cell efficiency is substantially undiminished in an event that any one of the plurality of electrically conductive portions 420a, 420b, 420c, 420i and 420m is conductively impaired, for example, second portion 420b. An arrow 448 indicates the nominal electron-flow through a third portion 420c of the plurality of electrically conductive portions 420a, 420b, 420c, 420i and 420m essentially unaffected by open-circuit defect 440. In the absence of open-circuit defect 440, an electron-flow indicated by arrow 448 would normally flow through any one electrically conductive portion of the plurality of electrically conductive portions 420a, 420b, 420c, 420i and 420m, in particular, second portion 420b. However, when the open-circuit defect 440 is present, this electron-flow divides into two portions shown by arrows 442 and 444: arrow 442 corresponding to that portion of the normal electron-flow flowing to the right along the second portion 420b to the second solar cell 430, and arrow 444 corresponding to that portion of the normal electron-flow flowing to the left along the second portion 420b to the first portion 420a and then to the right along the first portion 420a to the second solar cell 430. Thus, the net electron-flow represented by arrow 446 flowing to the right along the first portion 420a is consequently larger than what would normally flow to the right along the first portion 420a to the second solar cell 430 in the absence of the open-circuit defect 440.

It should be noted that open-circuit defect 440 is for illustration purposes only and that embodiments of the present invention compensate for other types of defects in an electrically conductive portion, in general, such as, without limitation to: a delamination of an electrically conductive portion from the first solar cell 410, corrosion of an electrically conductive portion, and even complete loss of an electrically conductive portion. In accordance with embodiments of the present invention, in the event a defect completely conductively impairs an electrically conductive portion, the physical spacing between adjacent electrically conductive portions, identified with double-headed arrow 449, may be chosen such that solar-cell efficiency is substantially undiminished. Nevertheless, embodiments of the present invention embrace, without limitation thereto, other physical spacings between adjacent electrically conductive portions in the event defects are less severe than those causing a complete loss of one of the electrically conductive portions.

With further reference to FIG. 4B, in accordance with embodiments of the present invention, the plurality of electrically conductive portions 420a, 420b, 420c, 420i and 420m may be connected electrically in series to form a single continuous electrically conductive line. Moreover, the trace that includes the plurality of electrically conductive portions 420a, 420b, 420c, 420i and 420m may be disposed in a serpentine pattern such that the interconnect assembly 420 is configured to collect current from the first solar cell 410 and to interconnect electrically to the second solar cell 430, as shown.

With further reference to FIG. 4C, in accordance with embodiments of the present invention, a cross-sectional, elevation view 400C of the interconnect assembly 420 is shown that further details the physical interconnection of two solar cells 410 and 430 in the solar-cell module 404. Projections 474 and 478 of planes orthogonal to both of the views in FIGS. 4B and 4C, and coincident with the ends of the plurality of electrically conductive portions 420a, 420b, 420c, 420i and 420m show the correspondence between features of the plan view 400B of FIG. 4B and features in the cross-sectional, elevation view 400C of FIG. 4C. Also, it should be noted that although the solar-cell module 404 is shown with separation 472 between the first solar cell 410 and the second solar cell 430, there need not be such separation 472 between the first solar cell 410 and the second solar cell 430. As shown in FIGS. 4B and 4C, a combined solar-cell, interconnect assembly 494 includes the first solar cell 410 and the interconnect assembly 420. The interconnect assembly 420 includes the trace disposed above the light-facing side 416 of the first solar cell 410, the trace further including the plurality of electrically conductive portions 420a, 420b, 420c, 420i and 420m. All electrically conductive portions of the plurality of electrically conductive portions 420a, 420b, 420c, 420i and 420m are configured to collect current from the first solar cell 410 and to interconnect electrically to the second solar cell 430. In addition, the plurality of electrically conductive portions 420a, 420b, 420c, 420i and 420m may be configured such that solar-cell efficiency is substantially undiminished in an event that any one of the plurality of electrically conductive portions 420a, 420b, 420c, 420i and 420m is conductively impaired. Also, any of the plurality of electrically conductive portions 420a, 420b, 420c, 420i and 420m may be configured to interconnect electrically to the second solar cell 430. The first solar cell 410 of the combined solar-cell, interconnect assembly 494 may include a metallic substrate 410c and an absorber layer 410a. The absorber layer 410a of the first solar cell 410 may include copper indium gallium diselenide (CIGS). Alternatively, other semiconductors having the chalcopyrite crystal structure, for example, chemically homologous compounds with the compound CIGS having the chalcopyrite crystal structure, in which alternative elemental constituents are substituted for Cu, In, Ga, and/or Se, may be used as the absorber layer 410a. Moreover, in embodiments of the present invention, it should be noted that semiconductors, such as silicon and cadmium telluride, as well as other semiconductors, may be used as the absorber layer 410a.

With further reference to FIG. 4C, in accordance with embodiments of the present invention, the plurality of electrically conductive portions 420a, 420b, 420c, 420i and 420m of the combined solar-cell, interconnect assembly 494 further includes the first portion 420a of the plurality of electrically conductive portions 420a, 420b, 420c, 420i and 420m configured to collect current from the first solar cell 410 and the second portion 420b of the plurality of electrically conductive portions 420a, 420b, 420c, 420i and 420m configured to collect current from the first solar cell 410. The first portion 420a includes the first end 420p distal from an edge 414 of the first solar cell 410. The second portion 420b includes the second end 420q distal from the edge 414 of the first solar cell 410. The second portion 420b is disposed proximately to the first portion 420a and electrically connected to the first portion 420a such that the first distal end 420p is electrically connected to the second distal end 420q such that the second portion 420b is configured electrically in parallel to the first portion 420a when configured to interconnect to the second solar cell 430.

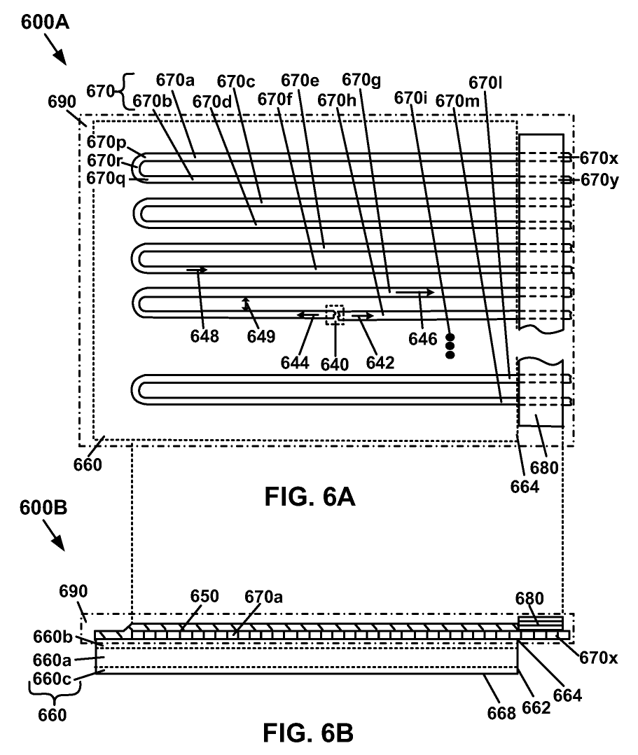

With further reference to FIG. 4C, in accordance with embodiments of the present invention, the interconnect assembly 420 further includes a top carrier film 450. The top carrier film 450 includes a first substantially transparent, electrically insulating layer coupled to the trace and disposed above a top portion of the trace. The first substantially transparent, electrically insulating layer allows for forming a short-circuit-preventing portion 454 at an edge 434 of the second solar cell 430. The first substantially transparent, electrically insulating layer allows for forming the short-circuit-preventing portion 454 at the edge 434 of the second solar cell 430 to prevent the first portion 420a from short circuiting an absorber layer 430a of the second solar cell 430 in the event that the first portion 420a buckles and rides up a side 432 of second solar cell 430. The edge 434 is located at the intersection of the side 432 of the second solar cell 430 and a back side 438 of the second solar cell 430 that couples with the plurality of electrically conductive portions 420a, 420b, 420c, 420i and 420m, for example, first portion 420a as shown. The second solar cell 430 may include the absorber layer 430a, a TCO layer 430b, and the metallic substrate 430c; a backing layer (not shown) may also be disposed between the absorber layer 430a and the metallic substrate 430c. Above a light-facing side 436 of the second solar cell 430, an integrated busbar-solar-cell-current collector (not shown in FIG. 4C, but which is shown in FIGS. 6A and 6B) may be disposed and coupled to the second solar cell 430 to provide interconnection with a load (not shown). Alternatively, above the light-facing side 436 of the second solar cell 430, another interconnect assembly (not shown) may be disposed and coupled to the second solar cell 430 to provide interconnection with additional solar-cells (not shown) in the solar-cell module 404.

With further reference to FIG. 4C, in accordance with embodiments of the present invention, the interconnect assembly 420 further includes a bottom carrier film 460. The bottom carrier film 460 may include a second electrically insulating layer coupled to the trace and disposed below a bottom portion of the trace. Alternatively, The bottom carrier film 460 may include a carrier film selected from a group consisting of a second electrically insulating layer, a structural plastic layer, and a metallic layer, and is coupled to the trace and is disposed below a bottom portion of the trace. The second electrically insulating layer allows for forming an edge-protecting portion 464 at the edge 414 of the first solar cell 410. Alternatively, a supplementary isolation strip (not shown) of a third electrically insulating layer may be disposed between the bottom carrier film 460 and the first portion 420a of the plurality of electrically conductive portions 420a, 420b, 420c, 420i and 420m, or alternatively between the bottom carrier film 460 and the edge 414, to provide additional protection at the edge 414. The supplementary isolation strip may be as wide as 5 millimeters (mm) in the direction of the double-headed arrow showing the separation 472, and may extend along the full length of a side 412 of the first solar cell 410. The edge 414 is located at the intersection of the side 412 of the first solar cell 410 and a light-facing side 416 of the first solar cell 410 that couples with the plurality of electrically conductive portions 420a, 420b, 420c, 420i and 420m, for example, first portion 420a as shown. The first solar cell 410 may include the absorber layer 410a, the TCO layer 410b, and the metallic substrate 410c; a backing layer (not shown) may also be disposed between the absorber layer 410a and the metallic substrate 410c. Below a back side 418 of the first solar cell 410, a first busbar (not shown) may be disposed and coupled to the first solar cell 410 to provide interconnection with a load (not shown). Alternatively, below the back side 418 of the first solar cell 410, another interconnect assembly (not shown) may be disposed and coupled to the first solar cell 410 to provide interconnection with additional solar-cells (not shown) in the solar-cell module 404.

With reference now to FIGS. 4D and 4E, in accordance with embodiments of the present invention, cross-sectional, elevation views 400D and 400E, respectively, of two alternative interconnect assemblies that minimize the separation 472 (see FIG. 4B) between the first solar cell 410 and the second solar cell 430 to improve the solar-cell-module efficiency of the solar-cell module 404 are shown. In both examples shown in FIGS. 4D and 4E, the side 412 of the first solar cell 410 essentially coincides with the side 432 of the second solar cell 430. It should be noted that as used herein the phrase, “essentially coincides,” with respect to the side 412 of the first solar cell 410 and the side 432 of the second solar cell 430 means that there is little or no separation 472 between the first solar cell 410 and the second solar cell 430, and little or no overlap of the first solar cell 410 with the second solar cell 430 so that there is less wasted space and open area between the solar cells 410 and 430, which improves the solar-collection efficiency of the solar-cell module 404 resulting in improved solar-cell-module efficiency. FIG. 4D shows an edge-conforming interconnect assembly for the physical interconnection of the two solar cells 410 and 430 in the solar-cell module 404. FIG. 4E shows a shingled-solar-cell arrangement for the physical interconnection of the two solar cells 410 and 430 in the solar-cell module 404. For both the edge-conforming interconnect assembly of FIG. 4D and the shingled-solar-cell arrangement of FIG. 4E, the interconnect assembly 420 further includes the bottom carrier film 460. The bottom carrier film 460 includes a second electrically insulating layer coupled to the trace and disposed below a bottom portion of the trace. Alternatively, The bottom carrier film 460 may include a carrier film selected from a group consisting of a second electrically insulating layer, a structural plastic layer, and a metallic layer, and is coupled to the trace and is disposed below a bottom portion of the trace. The second electrically insulating layer allows for forming the edge-protecting portion 464 at the edge 414 of the first solar cell 410. In the case of the edge-conforming interconnect assembly shown in FIG. 4D, the bottom carrier film 460 and the first portion 420a of the interconnect assembly 420 may be relatively flexible and compliant allowing them to wrap around the edge 414 and down the side 412 of the first solar cell 410, as shown. The edge 414 is located at the intersection of the side 412 of the first solar cell 410 and the light-facing side 416 of the first solar cell 410 that couples with the plurality of electrically conductive portions 420a, 420b, 420c, 420i and 420m, for example, first portion 420a as shown. The first solar cell 410 may include the absorber layer 410a, a TCO layer 410b, and the metallic substrate 410c; a backing layer (not shown) may also be disposed between the absorber layer 410a and the metallic substrate 410c. Below the back side 418 of the first solar cell 410, another interconnect assembly (not shown) or first busbar (not shown) may be disposed and coupled to the first solar cell 410 as described above for FIG. 4C. If an additional solar cell (not shown) is interconnected to the back side 418 of the first solar cell 410 as in the shingled-solar-cell arrangement of FIG. 4E, the first solar cell 410 would be pitched upward at its left-hand side and interconnected to another interconnect assembly similar to the manner in which the second solar cell 430 is shown interconnected with solar cell 410 at side 412 in FIG. 4E.

With further reference to FIGS. 4D and 4E, in accordance with embodiments of the present invention, the interconnect assembly 420 further includes the top carrier film 450. The top carrier film 450 includes a first substantially transparent, electrically insulating layer coupled to the trace and disposed above a top portion of the trace. The first substantially transparent, electrically insulating layer allows for forming the short-circuit-preventing portion 454 at the edge 434 of the second solar cell 430 to prevent the first portion 420a from short circuiting the absorber layer 430a of the second solar cell 430 in the event that the first portion 420a rides up the side 432 of second solar cell 430. The edge 434 is located at the intersection of the side 432 of the second solar cell 430 and the back side 438 of the second solar cell 430 that couples with the plurality of electrically conductive portions 420a, 420b, 420c, 420i and 420m, for example, first portion 420a as shown. In the case of the edge-conforming interconnect assembly shown in FIG. 4D, the top carrier film 450 may be relatively flexible and compliant allowing it to follow the conformation of the bottom carrier film 460 and the first portion 420a of the interconnect assembly 420 underlying it that wrap around the edge 414 and down the side 412 of the first solar cell 410, as shown. The second solar cell 430 may include the absorber layer 430a, the TCO layer 430b, and the metallic substrate 430c; a backing layer (not shown) may also be disposed between the absorber layer 430a and the metallic substrate 430c. Also, in the case of the edge-conforming interconnect assembly, the absorber layer 430a, TCO layer 430b, and metallic substrate 430c of the second solar cell 430 may be relatively flexible and compliant allowing them to follow the conformation of the underlying interconnect assembly 420 that wraps around the edge 414 and down the side 412 of the first solar cell 410. Above the light-facing side 436 of the second solar cell 430, an integrated busbar-solar-cell-current collector (not shown in FIG. 4C, but which is shown in FIGS. 6A and 6B), or alternatively another interconnect assembly (not shown), may be disposed on and coupled to the second solar cell 430, as described above for FIG. 4C.

With reference now to FIG. 4F, in accordance with embodiments of the present invention, a plan view 400F of an alternative interconnect assembly for the interconnect assembly 420 of FIG. 4A is shown that details the physical interconnection of two solar cells 410 and 430 in the solar-cell module 404. The solar-cell module 404 includes the first solar cell 410, at least the second solar cell 430 and the interconnect assembly 420 disposed above the light-facing side 416 of the absorber layer of the first solar cell 410. The edges 414 and 434 of the solar cells 410 and 430 may be separated by the separation 472 as shown in FIG. 4F; or alternatively, the edges 414 and 434 of the solar cells 410 and 430 may essentially coincide as discussed above for FIGS. 4D and 4E. The interconnect assembly 420 includes a trace including a plurality of electrically conductive portions 420a, 420b, 420c, 420i and 420m, previously identified herein with the resistors 420a, 420b, 420c, 420i and 420m described in FIG. 400A, where the ellipsis of 420i indicates additional electrically conductive portions (not shown). The plurality of electrically conductive portions 420a, 420b, 420c, 420i and 420m is configured both to collect current from the first solar cell 410 and to interconnect electrically to the second solar cell 430. The plurality of electrically conductive portions 420a, 420b, 420c, 420i and 420m is configured such that solar-cell efficiency is substantially undiminished in an event that any one of the plurality of electrically conductive portions 420a, 420b, 420c, 420i and 420m is conductively impaired.

With further reference to FIG. 4F, in accordance with embodiments of the present invention, the detailed configuration of the plurality of electrically conductive portions 420a, 420b, 420c, 420i and 420m is shown without electrically connecting trace portions, for example, junctions formed in the trace or linking portions of the trace. For example, in the case where electrically connecting trace portions of the trace have been cut away, removed, or are otherwise absent, from the distal ends of the plurality of electrically conductive portions 420a, 420b, 420c, 420i and 420m, as shown in FIG. 4F. The plurality of electrically conductive portions 420a, 420b, 420c, 420i and 420m may be linked together instead indirectly by the TCO layer 410b of the first solar cell 410 at distal ends of the trace disposed over the first solar cell 410, for example, first distal end 420p of first portion 420a and second distal end 420q of second portion 420b by portions of the TCO layer 410b of the first solar cell 410 that lie in between the distal ends 420p and 420q. In like fashion, the distal ends 420w and 420q are electrically coupled through the low resistance connection through the TCO layer 410b of first solar cell 410. Similarly, the plurality of electrically conductive portions 420a, 420b, 420c, 420i and 420m may be linked together instead indirectly by the metallic substrate 430c, or intervening backing layer (not shown), of the first solar cell 430 at distal ends of the trace disposed under the second solar cell 430, for example, third distal end 420s of second portion 420b and fourth distal end 420t of third portion 420c by portions of the metallic substrate 430c of the second solar cell 430 that lie in between the distal ends 420s and 420t. In like fashion, the distal ends 420v and 420s are electrically coupled through a low resistance connection through the metallic substrate 430c of second solar cell 430.

With further reference to FIG. 4F, in accordance with embodiments of the present invention, the open-circuit defect 440 is shown such that second portion 420b is conductively impaired. FIG. 4F illustrates the manner in which the plurality of electrically conductive portions 420a, 420b, 420c, 420i and 420m is configured such that solar-cell efficiency is substantially undiminished in an event that any one of the plurality of electrically conductive portions 420a, 420b, 420c, 420i and 420m is conductively impaired, for example, second portion 420b. An arrow 480 indicates the nominal electron-flow through an m-th portion 420m of the plurality of electrically conductive portions 420a, 420b, 420c, 420i and 420m essentially unaffected by open-circuit defect 440. In the absence of open-circuit defect 440, an electron-flow indicated by arrow 480 would normally flow through any one electrically conductive portion of the plurality of electrically conductive portions 420a, 420b, 420c, 420i and 420m, in particular, second portion 420b. However, when the open-circuit defect 440 is present, portions of this electron-flow are lost to adjacent electrically conductive portions 420a and 420c shown by arrows 484a and 484c; arrow 482 corresponds to that portion of the normal electron-flow flowing to the right along the second portion 420b to the second solar cell 430, and arrow 484b corresponds to that portion of the normal electron-flow that would bridge the open-circuit defect 440 by flowing through the higher resistance path of the TCO layer 410b bridging across the two portions of second portion 420b on either side of the open-circuit defect 440. Thus, the net electron-flow represented by arrow 486 flowing to the right along the first portion 420a is consequently larger than what would normally flow to the right along the first portion 420a to the second solar cell 430 in the absence of the open-circuit defect 440; and, the net electron-flow represented by arrow 488 flowing to the right along the third portion 420c is consequently larger than what would normally flow to the right along the third portion 420c to the second solar cell 430 in the absence of the open-circuit defect 440.

Moreover, in the case of the alternative interconnect assembly depicted in FIG. 4F, as stated before for the interconnect assembly depicted in FIG. 4B, it should again be noted that open-circuit defect 440 is for illustration purposes only and that embodiments of the present invention compensate for other types of defects in an electrically conductive portion, in general, such as, without limitation to: a delamination of an electrically conductive portion from the first solar cell 410, corrosion of an electrically conductive portion, and even complete loss of an electrically conductive portion. In accordance with embodiments of the present invention, in the event a defect completely conductively impairs an electrically conductive portion, the physical spacing between adjacent electrically conductive portions, identified with double-headed arrow 449, may be chosen such that solar-cell efficiency is substantially undiminished. Nevertheless, embodiments of the present invention embrace, without limitation thereto, other physical spacings between adjacent electrically conductive portions in the event defects are less severe than those causing a complete loss of one of the electrically conductive portions.

With reference now to FIG. 5A, in accordance with embodiments of the present invention, a plan view 500A of the combined applicable carrier film, interconnect assembly 504 is shown. FIG. 5A shows the physical arrangement of a trace 520 with respect to a top carrier film 550 and a bottom carrier film 560 in the combined applicable carrier film, interconnect assembly 504. The combined applicable carrier film, interconnect assembly 504 includes the top carrier film 550 and the trace 520 including a plurality of electrically conductive portions 520a, 520b, 520c, 520d, 520e, 520f, 520g, 520m and 520i, the latter corresponding to the ellipsis indicating additional electrically conductive portions (not shown). The plurality of electrically conductive portions 520a through 520m is configured both to collect current from a first solar cell 510 (shown in FIG. 5C) and to interconnect electrically to a second solar cell (not shown). As shown in FIG. 5A, the plurality of electrically conductive portions 520a through 520m run over the top of the first solar cell 510 on the left and over an edge 514 of the first solar cell 510 to the right under an edge 534 of, and underneath, the second solar cell (not shown). The top carrier film 550 includes a first substantially transparent, electrically insulating layer 550A (shown in FIG. 5B). The plurality of electrically conductive portions 520a through 520m is configured such that solar-cell efficiency is substantially undiminished in an event that any one of the plurality of electrically conductive portions 520a through 520m is conductively impaired. It should be noted that as used herein the phrase, “substantially transparent,” with respect to a substantially transparent, electrically insulating layer means that light passes through the substantially transparent, electrically insulating layer with negligible absorption. The first substantially transparent, electrically insulating layer 550a is coupled to the trace 520 and disposed above a top portion of the trace 520 (shown in FIG. 5B) as indicated by the dashed portions of the trace 520 on the left of FIG. 5A.

With reference now to FIGS. 5B and 5C, in accordance with embodiments of the present invention, a cross-sectional, elevation view of the combined applicable carrier film, interconnect assembly 504 of FIG. 5A is shown. As shown in FIGS. 5B and 5C, the cross-section of the view is taken along a cut parallel to the edge 514 of the first solar cell 510. The cross-sectional, elevation view of FIG. 5B shows the physical arrangement of the trace 520 with respect to the top carrier film 550 in the combined applicable carrier film, interconnect assembly 504 prior to disposition on the first solar cell 510. On the other hand, the cross-sectional, elevation view of FIG. 5C shows the physical arrangement of the trace 520 with respect to the top carrier film 550 and the first solar cell 510 of the combined applicable carrier film, interconnect assembly 504 after it couples with the first solar cell 510. The top carrier film 550 and the trace 520 are configured for applying to a light-facing side of the first solar cell 510 both to collect current from the first solar cell 510 and to interconnect electrically to the second solar cell (not shown). The first solar cell 510 may include an absorber layer 510a, a TCO layer 510b, and a metallic substrate 510c; the backing layer (not shown) may also be disposed between the absorber layer 510a and the metallic substrate 510c. The first substantially transparent, electrically insulating layer 550a holds the trace 520 down in contact with the first solar cell 510 and allows for forming a short-circuit-preventing portion at an edge of the second solar cell (not shown). The top carrier film 550 further includes a first substantially transparent, adhesive medium 550b coupling the trace 520 to the substantially transparent, electrically insulating layer 550a. As shown in FIG. 5B, prior to disposition on the first solar cell 510, the top carrier film 550 lies relatively flat across the top portion of the trace 520, for example, as for the conformational state of the top carrier film 550 immediately after roll-to-roll fabrication of the combined applicable carrier film, interconnect assembly 504. In contrast, after disposition on the first solar cell 510, the top carrier film 550 conforms to the top portion of the trace 520, as shown in FIG. 5B. The first substantially transparent, adhesive medium 550b allows for coupling the trace 520 to the first solar cell 510 without requiring solder. The first substantially transparent, electrically insulating layer 550a may include a structural plastic material, such as polyethylene terephthalate (PET). In accordance with embodiments of the present invention, a first substantially transparent, adhesive medium such as first substantially transparent, adhesive medium 550b may be included, without limitation thereto, in a top carrier film of: the combined applicable carrier film, interconnect assembly 504, the interconnect assembly 320, the integrated busbar-solar-cell-current collector 690 (see FIG. 6B), the combined solar-cell, interconnect assembly 494, or the interconnect assembly 420 of the solar-cell module 404.

With further reference to FIGS. 5A, 5B and 5C, in accordance with embodiments of the present invention, the combined applicable carrier film, interconnect assembly 504 further includes the bottom carrier film 560. The bottom carrier film 560 includes a second electrically insulating layer, like 550a, coupled to the trace 520 and disposed below a bottom portion of the trace 520, as indicated by the solid-line portions of the trace 520 on the right of FIG. 5A. Alternatively, the bottom carrier film 560 may include a carrier film selected from a group consisting of a second electrically insulating layer, a structural plastic layer, and a metallic layer, and is coupled to the trace 520 and is disposed below a bottom portion of the trace 520. The second electrically insulating layer, like 550a, holds the trace 520 down in contact with a back side of the second solar cell (not shown) and allows for forming an edge-protecting portion at the edge 514 of the first solar cell 510. The bottom carrier film 560 further includes a second adhesive medium, like 550b, coupling the trace to the second electrically insulating layer, like 550a. The second adhesive medium, like 550b, allows for coupling the trace 520 to the back side of the second solar cell (not shown) without requiring solder. The second electrically insulating layer, like 550a, includes a structural plastic material, such as PET. In accordance with embodiments of the present invention, a second adhesive medium, like 550b, may be included, without limitation thereto, in a bottom carrier film of: the combined applicable carrier film, interconnect assembly 504, the interconnect assembly 320, the combined solar-cell, interconnect assembly 494, or the interconnect assembly 420 of the solar-cell module 404.

With further reference to FIGS. 5A, in accordance with embodiments of the present invention, the trace 520 may be disposed in a serpentine pattern that allows for collecting current from the first solar cell 510 (shown in FIG. 5C) and electrically interconnecting to the second solar cell (not shown). It should be noted that neither the first solar cell 510 nor the second solar cell (not shown) are shown in FIG. 5A so as not to obscure the structure of the combined applicable carrier film, interconnect assembly 504. As shown in FIG. 5A, the combined applicable carrier film, interconnect assembly 504 includes the trace 520 including the plurality of electrically conductive portions 520a through 520m that may run in a serpentine pattern back and forth between the first solar cell 510 and the second solar cell (not shown). The serpentine pattern is such that adjacent electrically conductive portions of the plurality of electrically conductive portions 520a through 520m are configured in pairs of adjacent electrically conductive portions: 520a and 520b, 520c and 520d, 520e and 520f, etc. The pairs of adjacent electrically conductive portions may be configured in a regular repeating pattern of equally spaced adjacent electrically conductive portions. The trace 520 including the plurality of electrically conductive portions 520a through 520m is disposed between the top carrier film 550 disposed above a top portion of the trace 520 and the bottom carrier film 560 disposed below a bottom portion of the trace 520. The first substantially transparent, electrically insulating layer 550a of top carrier film 550 and the second electrically insulating layer, or alternatively, structural plastic layer or metallic layer, of bottom carrier film 560 are coupled to the trace 520 with a first substantially transparent, adhesive medium 550b and second adhesive medium which also serve to couple the trace 520 to the first solar cell 510, which may be located on the left, and the second solar cell, which may be located on the right. In the space between the two solar cells, between the edge 514 of the first solar cell and the edge 534 of the second solar cell, the trace is sandwiched between the two carrier films 550 and 560; the overlapping region of the two carrier films 550 and 560 extends somewhat beyond the respective edges 514 and 534 of the first and second solar cells so as to form, respectively, an edge-protecting portion at the edge 514 of the first solar cell, and a short-circuit-preventing portion at the edge 534 of the second solar cell, from the trace 520 that crosses the edges 514 and 534.

With further reference to FIGS. 5B and 5C, in accordance with embodiments of the present invention, the trace 520 may further include an electrically conductive line including a conductive core 520A with at least one overlying layer 520B. In one embodiment of the present invention, the electrically conductive line may include the conductive core 520A including a material having greater conductivity than nickel, for example, copper, with an overlying nickel layer 520B. In another embodiment of the present invention, electrically conductive line may include the conductive core 520A including nickel without the overlying layer 520B. The electrically conductive line may also be selected from a group consisting of a copper conductive core clad with a silver cladding, a copper conductive core clad with a nickel coating further clad with a silver cladding and an aluminum conductive core clad with a silver cladding.

With further reference to FIGS. 5B and 5C, in accordance with embodiments of the present invention, the trace 520 for collecting current from a solar cell, for example, the first solar cell 510, may include an electrically conductive line including the conductive core 520A, and the overlying layer 520B that limits current flow to a proximate shunt defect (not shown) in the solar cell. The proximate shunt defect may be proximately located in the vicinity of an electrical contact between the overlying layer 520B of the electrically conductive line and the TCO layer 510b of the solar cell, for example, first solar cell 510. The overlying layer 520B of the electrically conductive line of the trace 520 may further include an overlying layer 520B composed of nickel. The conductive core 520A of the electrically conductive line of the trace 520 may further include nickel. The conductive core 520A may also include a material selected from a group consisting of copper, silver, aluminum, and elemental constituents and alloys having high electrical conductivity, which may be greater than the electrical conductivity of nickel. The TCO layer 510b of the solar cell, for example, first solar cell 510, may include a conductive oxide selected from a group consisting of zinc oxide, aluminum zinc oxide and indium tin oxide. In addition, the absorber layer 510a, for example, absorber layer 112 of FIG. 1A, of the solar cell, for example, first solar cell 510, may include copper indium gallium diselenide (CIGS). Alternatively, in embodiments of the present invention, it should be noted that semiconductors, such as silicon, cadmium telluride, and chalcopyrite semiconductors, as well as other semiconductors, may be used as the absorber layer 510a. Moreover, an n-type layer, for example, n-type portion 112b of absorber layer 112 of FIG. 1A, of the solar cell, for example, first solar cell 510, may be disposed on and electrically coupled to a p-type absorber layer, for example, absorber layer 112 of FIG. 1A, of the solar cell, for example, first solar cell 510, and the n-type layer, for example, n-type portion 112b of absorber layer 112 of FIG. 1A, may be selected from a group consisting of a metal oxide, a metal sulfide and a metal selenide.

Although the trace 520 is shown as having a circular cross-section having a point-like contact with a solar cell, for example, with the TCO layer 510b, or, without limitation thereto, to a top surface, of the first solar cell 510, embodiments of the present inventions include, without limitation thereto, other cross-sectional profiles of the trace 520, such as a profile including a flattened top portion and a flattened bottom portion, so as to increase the contact area between the trace 520 and a solar cell with which it makes contact. For example, a flattened bottom portion of trace 520 increases the contact area with the light-facing side of the first solar cell 510; on the other hand, a flattened top portion of trace 520 increases the contact area with a back side of an adjacent solar cell to which the plurality of electrically conductive portions 520a through 520m of the trace 520 interconnects. In accordance with embodiments of the present invention, a trace, such as trace 520, may be included, without limitation thereto, in: the combined applicable carrier film, interconnect assembly 504, the interconnect assembly 320, the integrated busbar-solar-cell-current collector 690 (see FIG. 6B), the combined solar-cell, interconnect assembly 494, or the interconnect assembly 420 of the solar-cell module 404.

With reference now to FIG. 6A, in accordance with embodiments of the present invention, a plan view 600A of an integrated busbar-solar-cell-current collector 690 is shown. FIG. 6A shows the physical interconnection of a terminating solar cell 660 with a terminating busbar 680 of the integrated busbar-solar-cell-current collector 690. The integrated busbar-solar-cell-current collector 690 includes the terminating busbar 680 and an integrated solar-cell, current collector 670. The integrated solar-cell, current collector 670 includes a plurality of integrated pairs 670a&b, 670c&d, 670e&f, 670g&h, and 670l&m and 670i, the ellipsis indicating additional integrated pairs (not shown), of electrically conductive, electrically parallel trace portions 670a-m. Throughout the following, the respective integrated pairs: 670a and 670b, 670c and 670d, 670e and 670f, 670g and 670h, and 670l and 670m, are referred to respectively as: 670a&b, 670c&d, 670e&f, 670g&h, and 670l&m; and the electrically conductive, electrically parallel trace portions: 670a, 670b, 670c, 670d, 670e, 670f, 670g, 670h, 670l and 670m, are referred to as 670a-m. The plurality of integrated pairs 670a&b, 670c&c, 670e&f, 670g&h, 670i and 670l&m of electrically conductive, electrically parallel trace portions 670a-m is configured both to collect current from the terminating solar cell 660 and to interconnect electrically to the terminating busbar 680. The plurality of integrated pairs 670a&b, 670c&c, 670e&f, 670g&h, 670i and 670l&m of electrically conductive, electrically parallel trace portions 670a-m is configured such that solar-cell efficiency is substantially undiminished in an event that any one electrically conductive, electrically parallel trace portion, for example, 670h, of the plurality of integrated pairs 670a&b, 670c&c, 670e&f, 670g&h, 670i and 670l&m of electrically conductive, electrically parallel trace portions 670a-m is conductively impaired.

With further reference to FIGS. 6A and 6B, in accordance with embodiments of the present invention, the plurality of integrated pairs 670a&b, 670c&c, 670e&f, 670g&h, 670i and 670l&m of electrically conductive, electrically parallel trace portions 670a-m further includes a first electrically conductive, electrically parallel trace portion 670a of a first integrated pair 670a&b of the electrically conductive, electrically parallel trace portions 670a-m configured both to collect current from the terminating solar cell 660 and to interconnect electrically to the terminating busbar 680, and a second electrically conductive, electrically parallel trace portion 670b of the first integrated pair 670a&b of the electrically conductive, electrically parallel trace portions 670a-m configured both to collect current from the terminating solar cell 660 and to interconnect electrically to the terminating busbar 680. The first electrically conductive, electrically parallel trace portion 670a includes a first end 670p distal from the terminating busbar 680 located parallel to a side 662 of the terminating solar cell 660. The second electrically conductive, electrically parallel trace portion 670b includes a second end 670q distal from the terminating busbar 680. The second electrically conductive, electrically parallel trace portion 670b is disposed proximately to the first electrically conductive, electrically parallel trace portion 670a and electrically connected to the first electrically conductive, electrically parallel trace portion 670a such that the first distal end 670p is electrically connected to the second distal end 670q, for example, at first junction 670r, or by a linking portion, such that the second electrically conductive, electrically parallel trace portion 670b is configured electrically in parallel to the first electrically conductive, electrically parallel trace portion 670a when configured to interconnect to the terminating busbar 680. In addition, in accordance with embodiments of the present invention, the terminating busbar 680 may be disposed above and connected electrically to extended portions, for example, 670x and 670y, of the plurality of integrated pairs 670a&b, 670c&c, 670e&f, 670g&h, 670i and 670l&m of electrically conductive, electrically parallel trace portions 670a-m configured such that the terminating busbar 680 is configured to reduce shadowing of the terminating solar cell 660.

With further reference to FIG. 6A, in accordance with embodiments of the present invention, an open-circuit defect 640 is shown such that eighth electrically conductive, electrically parallel trace portion 670h is conductively impaired. FIG. 6A illustrates the manner in which the plurality of integrated pairs 670a&b, 670c&c, 670e&f, 670g&h and 670l&m of electrically conductive, electrically parallel trace portions 670a-m is configured such that solar-cell efficiency is substantially undiminished in an event that any one electrically conductive, electrically parallel trace portion, for example, eighth electrically conductive, electrically parallel trace portion 670h, of the plurality of integrated pairs 670a&b, 670c&c, 670e&f, 670g&h and 670l&m of electrically conductive, electrically parallel trace portions 670a-m is conductively impaired. The arrow 648 indicates the nominal electron-flow through a sixth electrically conductive, electrically parallel trace portion 670f of the plurality of integrated pairs 670a&b, 670c&c, 670e&f, 670g&h and 670l&m of electrically conductive, electrically parallel trace portions 670a-m essentially unaffected by open-circuit defect 640. In the absence of open-circuit defect 640, an electron-flow indicated by arrow 648 would normally flow through any one electrically conductive, electrically parallel trace portion of the plurality of integrated pairs 670a&b, 670c&c, 670e&f, 670g&h and 670l&m of electrically conductive, electrically parallel trace portions 670a-m, in particular, eighth electrically conductive, electrically parallel trace portion 670h. However, when the open-circuit defect 640 is present, this electron-flow divides into two portions shown by arrows 642 and 644: arrow 642 corresponding to that portion of the normal electron-flow flowing to the right along the eighth electrically conductive, electrically parallel trace portion 670h to the terminating busbar 680, and arrow 644 corresponding to that portion of the normal electron-flow flowing to the left along the eighth electrically conductive, electrically parallel trace portion 670h to the seventh electrically conductive, electrically parallel trace portion 670g and then to the right along the seventh electrically conductive, electrically parallel trace portion 670g to the terminating busbar 680. Thus, the net electron-flow represented by arrow 646 flowing to the right along the seventh electrically conductive, electrically parallel trace portion 670g is consequently larger than what would normally flow to the right along the seventh electrically conductive, electrically parallel trace portion 670g to the terminating busbar 680 in the absence of the open-circuit defect 640. It should be noted that open-circuit defect 640 is for illustration purposes only and that embodiments of the present invention compensate for other types of defects in an electrically conductive, electrically parallel trace portion, in general, such as, without limitation to: a delamination of an electrically conductive, electrically parallel trace portion from the terminating solar cell 660, corrosion of an electrically conductive, electrically parallel trace portion, and even complete loss of an electrically conductive, electrically parallel trace portion. In accordance with embodiments of the present invention, in the event a defect completely conductively impairs an electrically conductive, electrically parallel trace portion, the physical spacing between adjacent electrically conductive, electrically parallel trace portions, identified with double-headed arrow 649, may be chosen such that solar-cell efficiency is substantially undiminished. Nevertheless, embodiments of the present invention embrace, without limitation thereto, other physical spacings between adjacent electrically conductive, electrically parallel trace portions in the event defects are less severe than those causing a complete loss of one of the electrically conductive, electrically parallel trace portions.

With reference now to FIG. 6B and further reference to FIG. 6A, in accordance with embodiments of the present invention, a cross-sectional, elevation view 600B of the integrated busbar-solar-cell-current collector 690 of FIG. 6A is shown. FIG. 6B shows the physical interconnection of the terminating solar cell 660 with the terminating busbar 680 in the integrated busbar-solar-cell-current collector 690. In accordance with embodiments of the present invention, the interconnection approach employing a carrier film is also conducive to coupling the integrated busbar-solar-cell-current collector 690 directly to the terminating busbar 680 without requiring solder. Thus, the integrated busbar-solar-cell-current collector 690 further includes a top carrier film 650. The top carrier film 650 includes a first substantially transparent, electrically insulating layer (not shown, but like 550a of FIG. 5B) coupled to the plurality of integrated pairs 670a&b, 670c&c, 670e&f, 670g&h, 670i and 670l&m of electrically conductive, electrically parallel trace portions 670a-m, for example, electrically conductive, electrically parallel trace portion 670a, and disposed above a top portion of the plurality of integrated pairs 670a&b, 670c&c, 670e&f, 670g&h, 670i and 670l&m of electrically conductive, electrically parallel trace portions 670a-m.

With further reference to FIGS. 6A and 6B, in accordance with embodiments of the present invention, the top carrier film 650 further includes a first adhesive medium (not shown, but like 550b of FIGS. 5B and 5C) coupling the plurality of integrated pairs 670a&b, 670c&c, 670e&f, 670g&h, 670i and 670l&m of electrically conductive, electrically parallel trace portions 670a-m to the electrically insulating layer (like 550a of FIG. 5B). The first adhesive medium (like 550b of FIGS. 5B and 5C) allows for coupling the plurality of integrated pairs 670a&b, 670c&c, 670e&f, 670g&h, 670i and 670l&m of electrically conductive, electrically parallel trace portions 670a-m to the terminating solar cell 660 without requiring solder. The terminating solar cell 660 may include an absorber layer 660a, a TCO layer 660b, and a metallic substrate 660c; a backing layer (not shown) may also be disposed between the absorber layer 660a and the metallic substrate 660c. The plurality of integrated pairs of electrically conductive, electrically parallel trace portions 670a-m may be connected electrically in series to form a single continuous electrically conductive line (not shown). The single continuous electrically conductive line may be disposed in a serpentine pattern (not shown, but like the pattern of trace 520 in FIG. 5A) such that the integrated busbar-solar-cell-current collector 690 is configured to collect current from the terminating solar cell 660 and to interconnect electrically to the terminating busbar 680. The plurality of integrated pairs 670a&b, 670c&c, 670e&f, 670g&h, 670i and 670l&m of electrically conductive, electrically parallel trace portions 670a-m may further include a plurality of electrically conductive lines (not shown, but like trace 520 of FIGS. 5B and 5C), any electrically conductive line of the plurality of electrically conductive lines selected from a group consisting of a copper conductive core clad with a silver cladding, a copper conductive core clad with a nickel coating further clad with a silver cladding and an aluminum conductive core clad with a silver cladding.

With further reference to FIGS. 6A and 6B, in accordance with embodiments of the present invention, integrated busbar-solar-cell-current collector 690 may include a supplementary isolation strip (not shown) at an edge 664 of the terminating solar cell 660 and running along the length of the side 662 to provide additional protection at the edge 664 and side 662 of the terminating solar cell 660 from the extended portions, for example, 670x and 670y, of the plurality of integrated pairs 670a&b, 670c&c, 670e&f, 670g&h, 670i and 670l&m of electrically conductive, electrically parallel trace portions 670a-m. In another embodiment of the present invention, the extended portions, for example, 670x and 670y, may be configured (not shown) to provide stress relief and to allow folding the terminating busbar 680 along edge 664 under a back side 668 and at the side 662 of terminating solar cell 660, so that there is less wasted space and open area between the terminating solar cell 660 of one module and the initial solar cell (not shown) of an adjacent module. Moreover, integrated busbar-solar-cell-current collector 690 may include a supplementary carrier-film strip (not shown) at the edge 664 of the terminating solar cell 660 and running along the length of the side 662 disposed above and coupled to top carrier film 650 and the terminating busbar 680 to affix the terminating busbar 680 to the extended portions, for example, 670x and 670y. Alternatively, the integrated busbar-solar-cell-current collector 690 may include the top carrier film 650 extending over the top of the terminating busbar 680 and extended portions, for example, 670x and 670y, to affix the terminating busbar 680 to these extended portions. Thus, these latter two embodiments of the present invention provide a laminate including the terminating busbar 680 disposed between top carrier film 650, or alternatively the supplementary carrier-film strip, and the supplementary isolation strip (not shown) along the edge 664 and side 662 of the terminating solar cell 660. Moreover, the top carrier film 650, or the supplementary carrier-film strip, is conducive to connecting the terminating busbar 680 without requiring solder to the plurality, itself, or to the extended portions, for example, 670x and 670y, of the plurality of integrated pairs 670a&b, 670c&c, 670e&f, 670g&h, 670i and 670l&m of electrically conductive, electrically parallel trace portions 670a-m

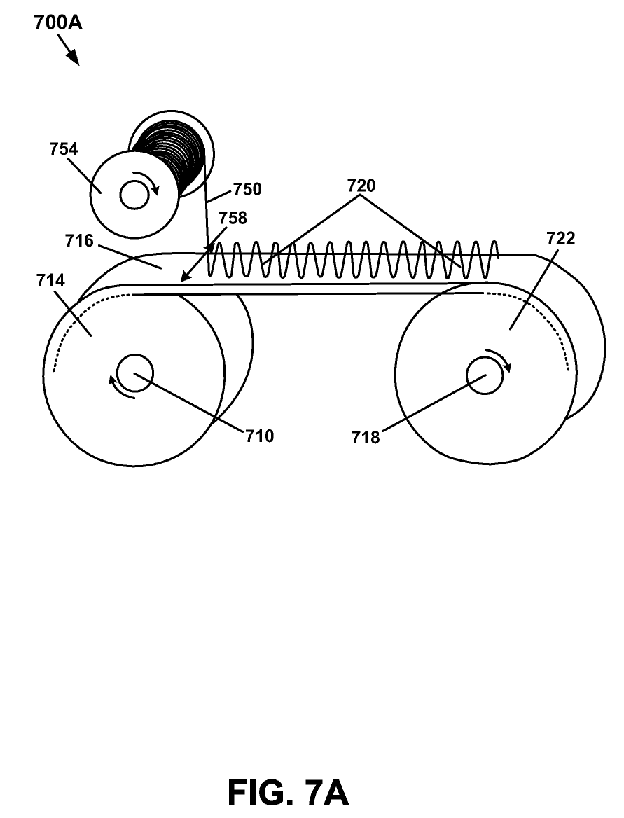

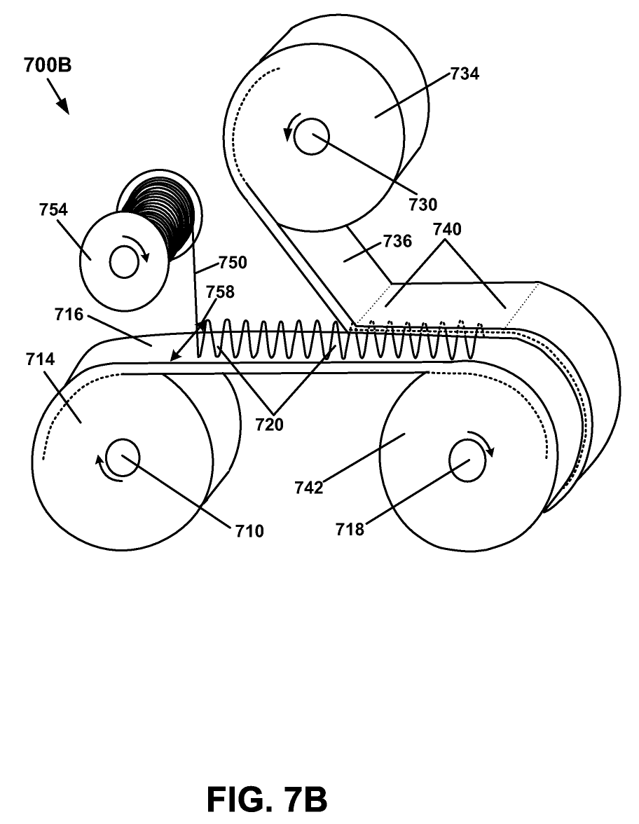

With reference now to FIG. 7A, in accordance with embodiments of the present invention, a combined cross-sectional elevation and perspective view of a roll-to-roll, interconnect-assembly fabricator 700A is shown. FIG. 7A shows the roll-to-roll, interconnect-assembly fabricator 700A operationally configured to fabricate an interconnect assembly 720. A top carrier film 716 including an electrically insulating layer, for example, a first substantially transparent, electrically insulating layer, is provided to roll-to-roll, interconnect-assembly fabricator 700A in roll form from a first roll of material 714. The roll-to-roll, interconnect-assembly fabricator 700A includes an first unwinding spool 710 upon which the first roll of material 714 of the top carrier film 716 including the electrically insulating layer is mounted. As shown, a portion of the first roll of material 714 is unrolled. The unrolled portion of the top carrier film 716 including the electrically insulating layer passes to the right and is taken up on a take-up spool 718 upon which it is rewound as a third roll 722 of interconnect assembly 720, after conductive-trace material 750 is provided from a dispenser 754 and is laid down onto the unrolled portion of the top carrier film 716 including the electrically insulating layer. The dispenser 754 of conductive-trace material 750 may be a spool of wire, or some other container providing conductive-trace material. The conductive-trace material 750 may be laid down onto the unrolled portion of the top carrier film 716 including the electrically insulating layer in an oscillatory motion, but without limitation to a strictly oscillatory motion, indicated by double-headed arrow 758, to create a first plurality of electrically conductive portions configured both to collect current from a first solar cell and to interconnect electrically to a second solar cell such that solar-cell efficiency is substantially undiminished in an event that any one of the first plurality of electrically conductive portions is conductively impaired. As shown in FIG. 7A, a portion of the electrically conductive portions overhang one side of the top carrier film 716 to allow the electrically conductive portions of the trace to interconnect electrically to the second solar cell on the exposed top side of the trace, while the exposed bottom side of the trace, here shown as facing upward on the top carrier film 716, allows the electrically conductive portions of the trace in contact with the top carrier film 716 to interconnect electrically to the first solar cell. Moreover, the conductive-trace material 750 may be disposed in a serpentine pattern to create the plurality of electrically conductive portions configured both to collect current from the first solar cell and to interconnect electrically to the second solar cell. The arrows adjacent to the first unwinding spool 710, and the take-up spool 718 indicate that these are rotating components of the roll-to-roll, interconnect-assembly fabricator 700A; the first unwinding spool 710, and the take-up spool 718 are shown rotating in clockwise direction, as indicated by the arrow-heads on the respective arrows adjacent to these components, to transport the unrolled portion of the first roll of material 714 from the first unwinding spool 710 on the left to the take-up spool 718 on the right.

With reference now to FIG. 7B, in accordance with embodiments of the present invention, a combined cross-sectional elevation and perspective view of a roll-to-roll, laminated-interconnect-assembly fabricator 700B is shown. FIG. 7A shows the roll-to-roll, laminated-interconnect-assembly fabricator 700B operationally configured to fabricate a laminated-interconnect assembly 740. The roll-to-roll, laminated-interconnect-assembly fabricator 700B first fabricates the interconnect assembly 720 shown on the left-hand side of FIG. 7B from the first roll of material 714 of the top carrier film 716 including the electrically insulating layer and from conductive-trace material 750 provided from dispenser 754. Then, the roll-to-roll, laminated-interconnect-assembly fabricator 700B continues fabrication of the laminated-interconnect assembly 740 by applying a bottom carrier film 736 from a second roll 734. The bottom carrier film 736 includes a carrier film selected from a group consisting of a second electrically insulating layer, a structural plastic layer, and a metallic layer, and is coupled to the conductive-trace material 750 and is disposed below a bottom portion of the conductive-trace material 750. If a metallic layer is used for the bottom carrier film 736, a supplementary isolation strip (not shown) of a third electrically insulating layer is added to the laminated-interconnect assembly 740 configured to allow interposition of the third electrically insulating layer between the bottom carrier film 736 and a top surface of the first solar cell to provide additional protection at an edge of the first solar cell and to prevent shorting out the solar cell in the event that the bottom carrier film 736 including the metallic layer should ride down the side of the first solar cell. The laminated-interconnect assembly 740 passes to the right-hand side of FIG. 7B and is taken up on the take-up spool 718 upon which it is wound as a fourth roll 742 of laminated-interconnect assembly 740. The arrows adjacent to the first unwinding spool 710, a second unwinding spool 730 and the take-up spool 718 indicate that these are rotating components of the roll-to-roll, laminated-interconnect-assembly fabricator 700B; the first unwinding spool 710, and the take-up spool 718 are shown rotating in clockwise direction, as indicated by the arrow-heads on the respective arrows adjacent to these components, to transport the unrolled portion of the first roll of material 714 from the first unwinding spool 710 on the left to the take-up spool 718 on the right. The second unwinding spool 730, and the dispenser 754 are shown rotating in a counterclockwise direction and a clockwise direction, respectively, as indicated by the arrow-heads on the respective arrows adjacent to these components, as they release the bottom carrier layer 736 and the conductive-trace material 750, respectively, in fabrication of the laminated-interconnect assembly 740. The double-headed arrow 758 indicates the motion imparted to the conductive trace material by the roll-to-roll, laminated-interconnect-assembly fabricator 700B creates a first plurality of electrically conductive portions configured both to collect current from a first solar cell and to interconnect electrically to a second solar cell such that solar-cell efficiency is substantially undiminished in an event that any one of the first plurality of electrically conductive portions is conductively impaired.

### Sub-Sectioin B: Description of Embodiments of the Present Invention for a Method for Roll-to-Roll Fabrication of an Interconnect Assembly

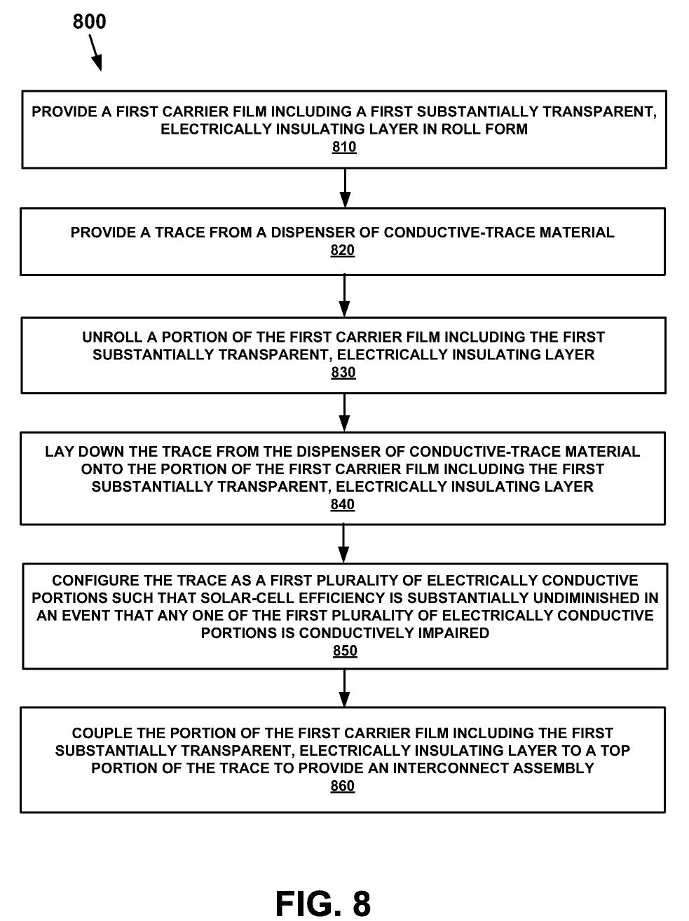

With reference now to FIG. 8, a flow chart illustrates an embodiment of the present invention for a method for roll-to-roll fabrication of an interconnect assembly. At 810, a first carrier film including a first substantially transparent, electrically insulating layer is provided in roll form. At 820, a trace is provided from a dispenser of conductive-trace material. The dispenser may be a spool of wire or other container of conductive-trace material. At 830, a portion of the first carrier film including the first substantially transparent, electrically insulating layer is unrolled. At 840, the trace from the dispenser of conductive-trace material is laid down onto the portion of the first carrier film including the first substantially transparent, electrically insulating layer. At 850, the trace is configured as a first plurality of electrically conductive portions such that solar-cell efficiency is substantially undiminished in an event that any one of the first plurality of electrically conductive portions is conductively impaired. At 860, the portion of the first the first carrier film including the substantially transparent, electrically insulating layer is coupled to a top portion of the trace to provide an interconnect assembly.

In an embodiment of the present invention, configuring the trace also includes: configuring the trace as a second plurality of paired trace portions; configuring a first portion of a paired portion of the second plurality of paired trace portions to allow both collecting current from a first solar cell and electrically interconnecting the first solar cell with a second solar cell; disposing proximately to the first portion, a second portion of the paired portion; and configuring the second portion to allow both collecting current from the first solar cell and electrically interconnecting the first solar cell with the second solar cell. Alternatively, configuring the trace may include disposing the trace in a serpentine pattern that allows for collecting current from the first solar cell and electrically interconnecting to the second solar cell. In an embodiment of the present invention, the method may also include: providing a second carrier film including a second electrically insulating layer; coupling the second carrier film including the second electrically insulating layer to a bottom portion of the trace; and configuring the second electrically insulating layer to allow forming an edge-protecting portion at an edge of the first solar cell. Moreover, the method may include configuring the first substantially transparent, electrically insulating layer to allow forming a short-circuit-preventing portion at an edge of the second solar cell.

### Sub-Section C: Description of Embodiments of the Present Invention for a Method of Interconnecting Two Solar Cells

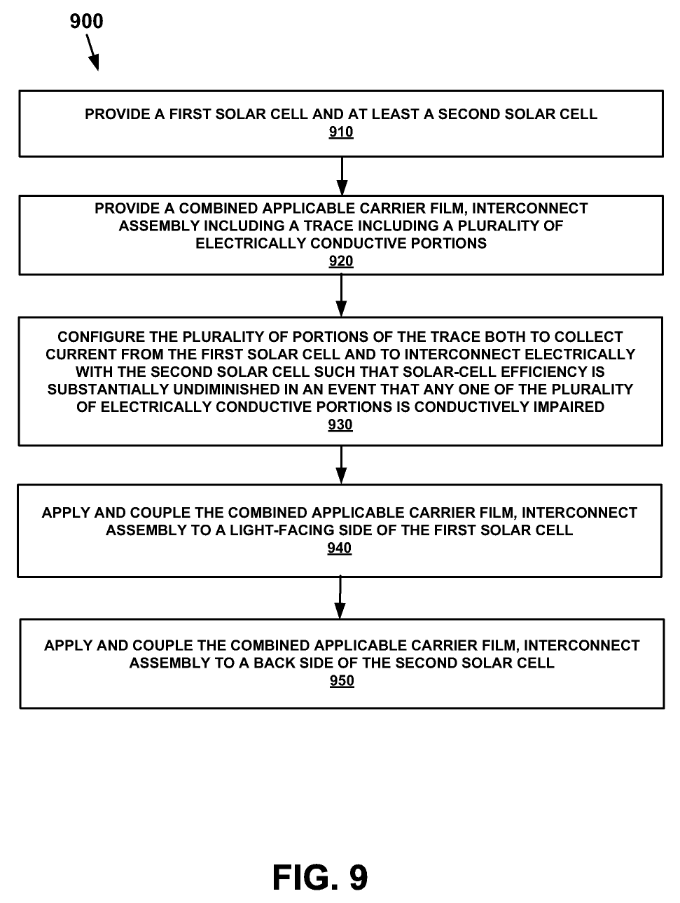

With reference now to FIG. 9, a flow chart illustrates an embodiment of the present invention for a method of interconnecting two solar cells. At 910, a first solar cell and at least a second solar cell are provided. At 920, a combined applicable carrier film, interconnect assembly including a trace including a plurality of electrically conductive portions is provided. At 930, the plurality of electrically conductive portions of the trace is configured both to collect current from the first solar cell and to interconnect electrically with the second solar cell such that solar-cell efficiency is substantially undiminished in an event that any one of the plurality of electrically conductive portions is conductively impaired. At 940, the combined applicable carrier film, interconnect assembly is applied and coupled to a light-facing side of the first solar cell. At 950, the combined applicable carrier film, interconnect assembly is applied and coupled to a back side of the second solar cell.

In an embodiment of the present invention, the method also includes applying and coupling the combined applicable carrier film, interconnect assembly to the light-facing side of the first solar cell without requiring solder. In addition, the method may include applying and coupling the combined applicable carrier film, interconnect assembly to the back side of the second solar cell without requiring solder. Moreover, the method includes applying and coupling the combined applicable carrier film, interconnect assembly to the light-facing side of the first solar cell such that a second electrically insulating layer of the applicable carrier film, interconnect assembly forms an edge-protecting portion at an edge of the first solar cell. The method also includes applying and coupling the combined applicable carrier film, interconnect assembly to the back side of the second solar cell such that a first substantially transparent, electrically insulating layer of the applicable carrier film, interconnect assembly forms a short-circuit-preventing portion at an edge of the second solar cell. The method may also include configuring the trace in a serpentine pattern that allows for collecting current from the first solar cell and electrically interconnecting to the second solar cell.

### Sub-Section D: Physical Description of Embodiments of the Present Invention for a Trace

In accordance with other embodiments of the present invention, the trace does not need to be used in conjunction with the afore-mentioned serpentine interconnect assembly approach, but could be used for other current collection and/or interconnection approaches used in solar cell technology. A trace including a conductive core with an overlying layer of nickel provides the unexpected result that when placed in contact with the TCO layer of a solar cell it suppresses current in the vicinity of short-circuit defects in the solar cell that might occur in the vicinity of the contact of the nickel layer of the trace with the TCO layer. The nickel increases local contact resistance which improves the ability of the solar cell to survive in the event of the formation of a defect, such as a shunt or a near shunt, located in the adjacent vicinity of the contact of the nickel layer of the trace with the TCO layer. If there is such a defect in the vicinity of the contact of the nickel layer of the trace with the TCO layer, the nickel reduces the tendency of the solar cell to pass increased current through the site of the defect, such as a shunt or a near shunt. Thus, the nickel acts as a localized resistor preventing run-away currents and high current densities in the small localized area associated with the site of the defect, such as a shunt or a near shunt. The current-limiting ability of nickel is in contrast, for example, to a low resistivity material such as silver, where the current density becomes so high at the location of the defect due to the high conductivity of silver that nearly almost all the current of the cell would be passed at the location of the defect causing a hot spot that would result in the melting of the silver with the formation of a hole in the solar cell filling with the silver migrating to the site of the defect to form a super-shunt. In contrast, nickel does not readily migrate nor melt in the presence of elevated localized temperatures associated with the site of increased currents attending formation of the defect, such as a shunt or a near shunt. Moreover, in contrast to silver, copper and tin, which tend to electromigrate, migrate or diffuse at elevated temperatures, nickel tends to stay put so that if the site of a shunt occurs in the vicinity of a nickel coated or nickel trace, the nickel has less tendency to move to the location of the shunt thereby further exacerbating the drop of resistance at the shunt site. In addition, experimental results of the present invention indicate that a nickel trace, or a trace including a nickel layer, may actually increase its resistance due the possible formation of a nickel oxide such that the nickel trace, or the trace including the nickel layer, acts like a localized fuse limiting the current flow in the vicinity of the shunt site. In some cases, the efficiency of the solar cell has actually been observed to increase after formation of the shunt defect when the nickel trace, or the trace including the nickel layer, is used in contact with the TCO layer.

With further reference to FIGS. 5B and 5C, in accordance with other embodiments of the present invention, the trace 520 for collecting current from a solar cell, for example, first solar cell 510, includes an electrically conductive line including the conductive core 520A, and the overlying layer 520B that limits current flow to a proximate shunt defect (not shown) in the solar cell, for example, first solar cell 510. The proximate shunt defect may be proximately located in the vicinity of an electrical contact between the overlying layer 520B of the electrically conductive line and the TCO layer 510b of the solar cell, for example, first solar cell 510. The overlying layer 520B of the electrically conductive line of the trace 520 may further include an overlying layer 520B composed of nickel. The conductive core 520A of the electrically conductive line of the trace 520 may further include nickel. The conductive core 520A may also include a material selected from a group consisting of copper, silver, aluminum, and elemental constituents and alloys having high electrical conductivity, which may be greater than the electrical conductivity of nickel. The TCO layer 510b of the solar cell, for example, first solar cell 510, may include a conductive oxide selected from a group consisting of zinc oxide, aluminum zinc oxide and indium tin oxide. In addition, the absorber layer 510a, for example, absorber layer 112 of FIG. 1A, of the solar cell, for example, first solar cell 510, may include copper indium gallium diselenide (CIGS). Alternatively, in embodiments of the present invention, it should be noted that semiconductors, such as silicon, cadmium telluride, and chalcopyrite semiconductors, as well as other semiconductors, may be used as the absorber layer 510a. Moreover, an n-type layer, for example, n-type portion 112b of absorber layer 112 of FIG. 1A, of the solar cell, for example, first solar cell 510, may be disposed on and electrically coupled to a p-type absorber layer, for example, absorber layer 112 of FIG. 1A, of the solar cell, for example, first solar cell 510, and the n-type layer, for example, n-type portion 112b of absorber layer 112 of FIG. 1A, may be selected from a group consisting of a metal oxide, a metal sulfide and a metal selenide.

### Section II:

Physical Description of Embodiments of the Present Invention for a Solar-Cell Module Combined with In-Laminate Diodes and External-Connection Mechanisms Mounted to Respective Edge Regions

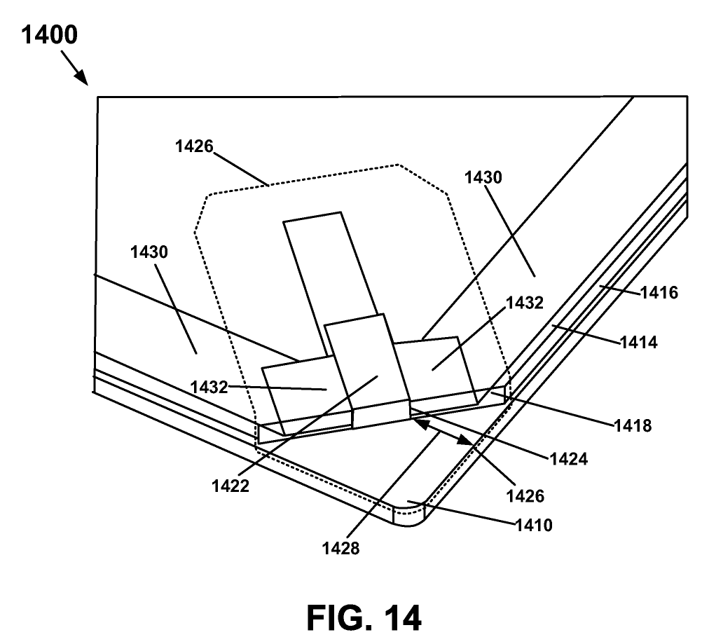

With reference now to FIG. 10, in accordance with embodiments of the present invention, a plan view 1000 is shown of a solar-cell module 1002 combined with external-connection mechanisms (not shown) mounted to respective edge regions and in-laminate-diode assembly 1050. FIG. 10 shows the physical arrangement of the solar-cell module 1002 combined with in-laminate-diode assembly 1050 and external-connection mechanisms mounted to respective edge regions, which may be located at edges 1090, 1092, 1094 and 1096, or at corners 1080, 1082, 1084 and 1086. The solar-cell module 1002 includes a plurality 1010 of solar cells electrically coupled together, for example, solar cells 1012a-1017a and 1012b-1017b, which may be disposed in at least one solar-cell sub-module, for example, solar-cell sub-modules 1010a and 1010b, respectively. (Throughout the following, solar cells: 1012a, 1013a, 1014a, 1015a, 1016a and 1017a; 1012b, 1013b, 1014b, 1015b, 1016b and 1017b; 1022a, 1023a, 1024a, 1025a, 1026a and 1027a; 1022b, 1023b, 1024b, 1025b, 1026b and 1027b; 1032a, 1033a, 1034a, 1035a, 1036a and 1037a; and, 1032b, 1033b, 1034b, 1035b, 1036b and 1037b; are referred to in aggregate as: 1012a-1017a, 1012b-1017b, 1022a-1027a, 1022b-1027b, 1032a-1037a and 1032b-1037b, respectively. Solar-cell sub-modules: 1010a and 1010b, 1020a and 1020b and 1030a and 1030b, are referred to as: 1010a-1010b, 1020a-1020b and 1030a-1030b, respectively.) The plurality 1010 of solar cells 1012a-1017a and 1012b-1017b is electrically interconnected with one another through interconnect assemblies (not shown) similar to those discussed in Section I in FIGS. 4A through 4F. The solar-cell module 1002 also includes the in-laminate-diode assembly 1050 electrically coupled with the plurality 1010 of solar cells 1012a-1017a and 1012b-1017b. The in-laminate-diode assembly 1050 is configured to prevent power loss in the solar-cell module 1002, which can result, from amongst other causes, from shading of a particular solar cell, for example, solar cell 1012a. In addition, the solar-cell module 1002 includes a protective structure (not shown in FIG. 10, but in FIG. 14) at least partially encapsulating the plurality 1010 of solar cells 1012a-1017a and 1012b-1017b. As shown in FIG. 14, the protective structure may include a front glass 1410, which is disposed over a light-facing side of the solar cells 1012a-1017a and 1012b-1017b, and a back glass 1414 that encapsulate the plurality 1010 of solar cells 1012a-1017a and 1012b-1017b. The solar-cell module 1002 also includes a plurality of external-connection mechanisms mounted to a respective plurality of edge regions of the protective structure. An external-connection mechanism of the plurality of external-connection mechanisms is configured to enable collection of current from the plurality 1010 of solar cells 1012a-1017a and 1012b-1017b and to allow interconnection with at least one other external device (not shown). The external device may be selected from the group consisting of a solar-cell module, an inverter, a battery charger, an external load, and an electrical-power-distribution system.

With further reference to FIG. 10, in accordance with embodiments of the present invention, it should be noted that: a photovoltaic-convertor means for converting radiant power into electrical power may be a solar cell; a photovoltaic-convertor module may be a solar-cell module; a photovoltaic-convertor sub-module may be a solar-cell sub-module; an current-shunting means for by-passing current flow may be a diode; an in-laminate, current-shunting assembly means for by-passing current flow may be an in-laminate-diode assembly; an in-laminate, current-shunting sub-assembly means for by-passing current flow may be an in-laminate-diode sub-assembly; and a junction-enclosure means for protecting and electrically isolating electrical connections may be an external-connection mechanism. Moreover, it should be noted that a photovoltaic-convertor array may be a solar-cell array. With the preceding identifications of terms of art, it should be noted that embodiments of the present invention recited herein with respect to a solar cell, a solar-cell module, a solar-cell sub-module, a diode, an in-laminate-diode assembly, an in-laminate-diode sub-assembly, and an external-connection mechanism apply to a photovoltaic-convertor means for converting radiant power into electrical power, a photovoltaic-convertor module, a photovoltaic-convertor sub-module, an in-laminate, current-shunting means for by-passing current flow, an in-laminate, current-shunting assembly means for by-passing current flow, an in-laminate, current-shunting sub-assembly means for by-passing current flow, and a junction-enclosure means for protecting and electrically isolating electrical connections, respectively. Therefore, it should be noted that the preceding identifications of terms of art do not preclude, nor limit embodiments described herein, which are within the spirit and scope of embodiments of the present invention.

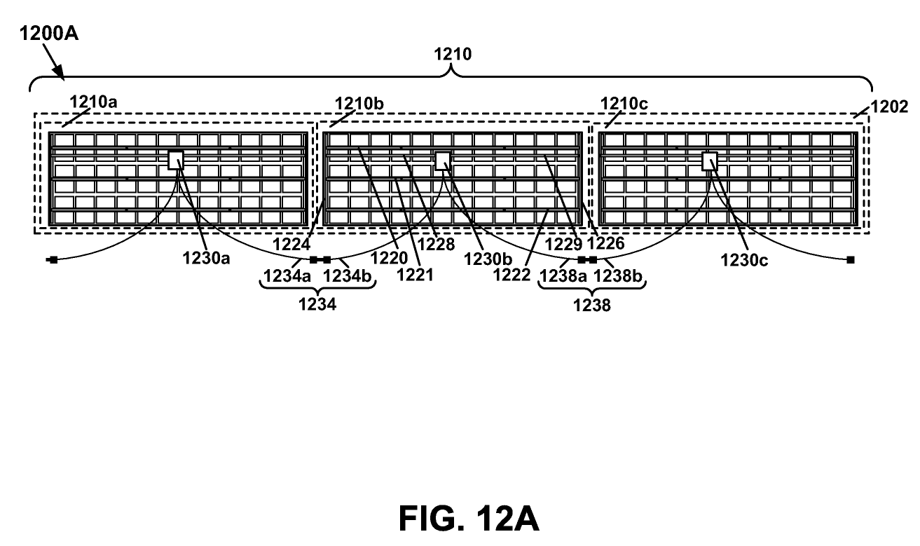

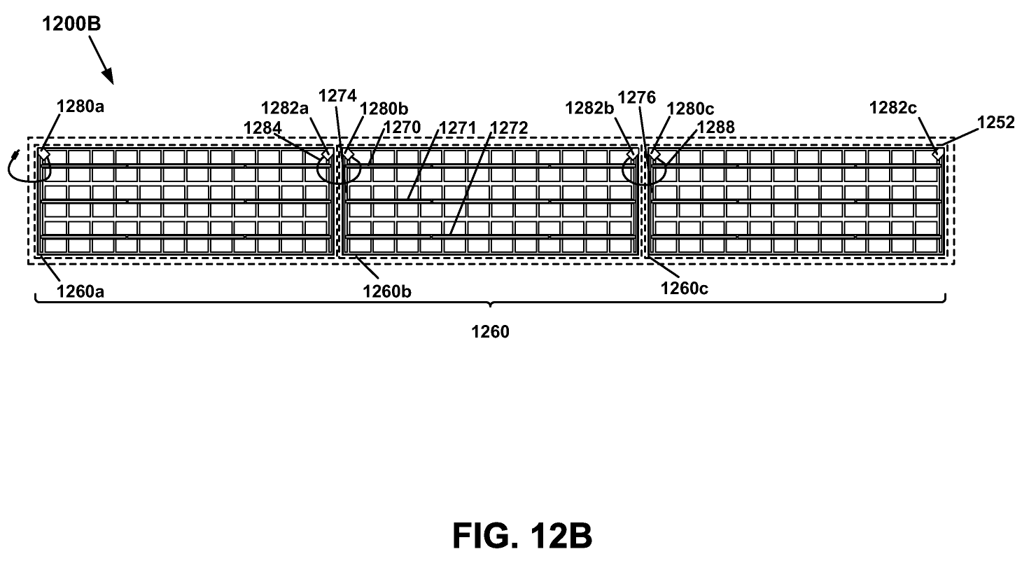

With further reference to FIG. 10, in accordance with embodiments of the present invention, the solar-cell module 1002, identified with solar-cell module 1260b, may be a component of a solar-cell array, for example, solar-cell array 1252 as shown in FIG. 12B. Embodiments of the present invention also encompass the solar-cell array 1252, or alternatively a photovoltaic-convertor array, that may include a plurality of electrically coupled solar-cell modules, for example, solar-cell modules 1260a, 1260b and 1260c. The solar-cell module, for example, solar-cell modules 1260b, of a plurality 1260 of electrically coupled solar-cell modules 1260a, 1260b and 1260c may include a plurality of solar cells, at least one solar-cell sub-module, an in-laminate-diode assembly, a protective structure and a plurality of external-connection mechanisms as for embodiments of the present invention described herein.

With further reference to FIG. 10, in accordance with embodiments of the present invention, the in-laminate-diode assembly 1050 may include at least one in-laminate-diode sub-assembly 1050a, for example, from a plurality of in-laminate-diode sub-assemblies 1050a-1050b without limitation thereto. As shown in FIG. 10, the in-laminate-diode sub-assemblies 1050a-1050b are electrically coupled in parallel with the plurality 1010 of solar cells 1012a-1017a and 1012b-1017b, which may be disposed in solar-cell sub-modules, for example, solar-cell sub-modules 1010a and 1010b, respectively, as shown. (Throughout the following, in-laminate-diode sub-assemblies: 1050a and 1050b, 1060a and 1060b and 1070a and 1070b, are referred to as: 1050a-1050b, 1060a-1060b and 1070a-1070b, respectively.) At least one in-laminate-diode sub-assembly, for example, in-laminate-diode sub-assembly 1050a, includes at least one diode (not shown) and is configured to by-pass current flow around the solar-cell sub-module, for example, solar-cell sub-module 1010a, in an event at least one solar cell, for example, solar cell 1012a, of the plurality of solar cells 1012a-1017a develops high resistance to passage of solar-cell-module current, as may occur in case of shading of a solar-cell. As used herein, an in-laminate diode is a diode included in an in-laminate diode assembly or in-laminate-diode sub-assembly, where the term of art “in-laminate” refers to the disposition of the diode within such an assembly or sub-assembly rather than any inherent functionality of the diode itself. In addition, the solar-cell module 1002 may include a plurality of external-connection mechanisms mounted to respective edge regions, for example, external-connection mechanisms 1280b and 1282b mounted to respective edge regions, for example, corners as shown in FIG. 12B. At least one external-connection mechanism 1282b mounted to respective edge regions of the plurality of external-connection mechanisms 1280b and 1282b may be disposed at a cut corner of a back glass of the solar-cell module, for example, the solar-cell module 1260b. The external-connection mechanism 1280b and 1282b mounted to respective edge regions of the plurality of external-connection mechanisms 280b and 1282b are configured to collect current from the solar-cell module 1260b and to allow interconnection with at least one other external device, for example, the solar-cell module 1260c.

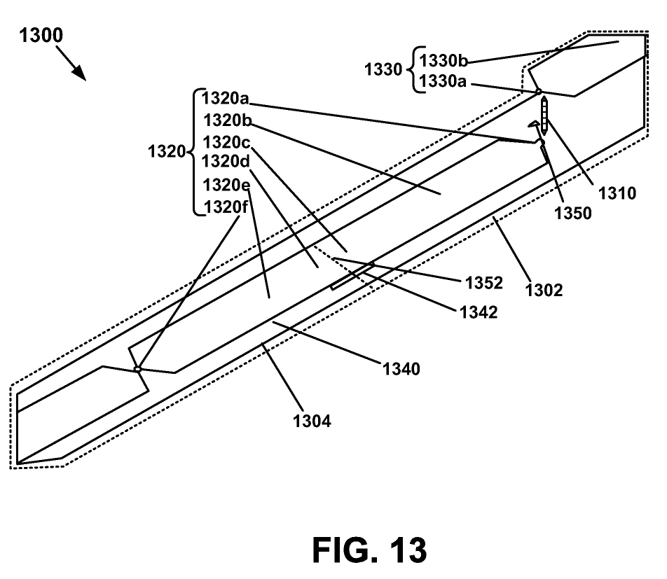

With further reference to FIG. 10, in accordance with embodiments of the present invention, the solar-cell module 1002 may include a second plurality 1020 of solar cells 1022a-1027a and 1022b-1027b. The second plurality 1020 of solar cells 1022a-1027a and 1022b-1027b is electrically interconnected with one another through interconnect assemblies (not shown) similar to those discussed in Section I in FIGS. 4A through 4F. Solar cells may be electrically coupled together in at least one solar-cell sub-module, for example, solar-cell sub-module 1020a may include solar cells 1022a-1027a, and solar-cell sub-module 1020b may include solar cells 1022b-1027b. The solar-cell module 1002 may also include a second in-laminate-diode assembly 1060 including a second plurality of in-laminate-diode sub-assemblies 1060a-1060b such that the in-laminate-diode sub-assemblies 1060a-1060b are electrically coupled in parallel with the second plurality 1020 of solar cells 1022a-1027a and 1022b-1027b, and which may be electrically coupled in parallel with solar-cell sub-modules 1020a-1020b. At least one in-laminate-diode sub-assembly, for example, in-laminate-diode sub-assembly 1060a, includes at least one diode (not shown) and is configured to by-pass current flow around the solar-cell sub-module, for example, solar-cell sub-module 1020a, in an event at least one solar cell, for example, solar cell 1022a, of the plurality 1020 of solar cells including solar cells 1022a-1027a develops high resistance to passage of solar-cell-module current. As shown in FIG. 10, the in-laminate-diode sub-assembly 1060a is also shown with some of its component conductors removed to reveal disposition of a portion of an electrically-insulating-laminate strip with respect to the second in-laminate-diode assembly 1060 and a portion of the second plurality 1020 of solar cells 1022a-1025a, which will be discussed below in greater detail in the description of FIG. 13.

With further reference to FIG. 10, in accordance with embodiments of the present invention, the solar-cell module 1002 may include a third plurality 1030 of solar cells 1032a-1037a and 1032b-1037b. The third plurality 1030 of solar cells 1032a-1037a and 1032b-1037b is electrically interconnected with one another through interconnect assemblies (not shown) similar to those discussed in Section I in FIGS. 4A through 4F. Solar cells may be electrically coupled together in at least one solar-cell sub-module, for example, solar-cell sub-module 1030a may include solar cells 1032a-1037a, and solar-cell sub-module 1030b may include solar cells 1032b-1037b. The solar-cell module 1002 may also include a third in-laminate-diode assembly 1070 including a third plurality of in-laminate-diode sub-assemblies 1070a-1070b such that the in-laminate-diode sub-assemblies 1070a-1070b are electrically coupled in parallel with the third plurality 1030 of solar cells 1032a-1037a and 1032b-1037b, and which may be electrically coupled in parallel with solar-cell sub-modules 1030a-1030b. At least one in-laminate-diode sub-assembly, for example, in-laminate-diode sub-assembly 1070a, includes at least one diode (not shown) and is configured to by-pass current flow around the solar-cell sub-module, for example, solar-cell sub-module 1030a, in an event at least one solar cell, for example, solar cell 1032a, of the third plurality 1030 of solar cells including solar cells 1032a-1037a develops high resistance to passage of solar-cell-module current. As shown in FIG. 10, the in-laminate-diode sub-assemblies 1070a and 1070b are also shown with some of their component conductors removed to reveal disposition of respective electrically-insulating-laminate strips with respect to the third in-laminate-diode assembly 1070 and a portion of the third plurality 1030 of solar cells 1032a-1037a and 1032b-1034b, which will also be discussed below in greater detail in the description of FIG. 13.

With further reference to FIG. 10, in accordance with embodiments of the present invention, a solar-cell sub-module 1010a includes at least one solar cell 1012a. Alternatively, the solar-cell sub-module 1010a may include a plurality of solar cells 1012a-1017a, as shown. A portion 1012a-1017a of the plurality 1010 of solar cells 1012a-1017a and 1012b-1017b of the solar-cell sub-module 1010a is electrically coupled in series. The in-laminate-diode assembly 1050 includes a plurality of in-laminate-diode sub-assemblies 1050a-1050b. At least one in-laminate-diode sub-assembly 1050a includes at least one diode (not shown) is configured to by-pass current flow around the solar-cell sub-module 1010a to prevent power loss in the solar-cell module 1002. The in-laminate-diode sub-assembly 1050a is configured to by-pass current flow around the solar-cell sub-module 1010a such that the diode (not shown) of the in-laminate-diode assembly 1050a is electrically coupled in parallel with the solar-cell sub-module 1010a with reverse polarity to polarities of the portion 1012a-1017a of the plurality 1010 of solar cells 1012a-1017a and 1012b-1017b of the solar-cell sub-module 1010a. The plurality of solar-cell sub-modules 1010a-1010b is electrically coupled in series. In addition, the plurality of in-laminate-diode sub-assemblies 1050a-1050b is electrically coupled in series.

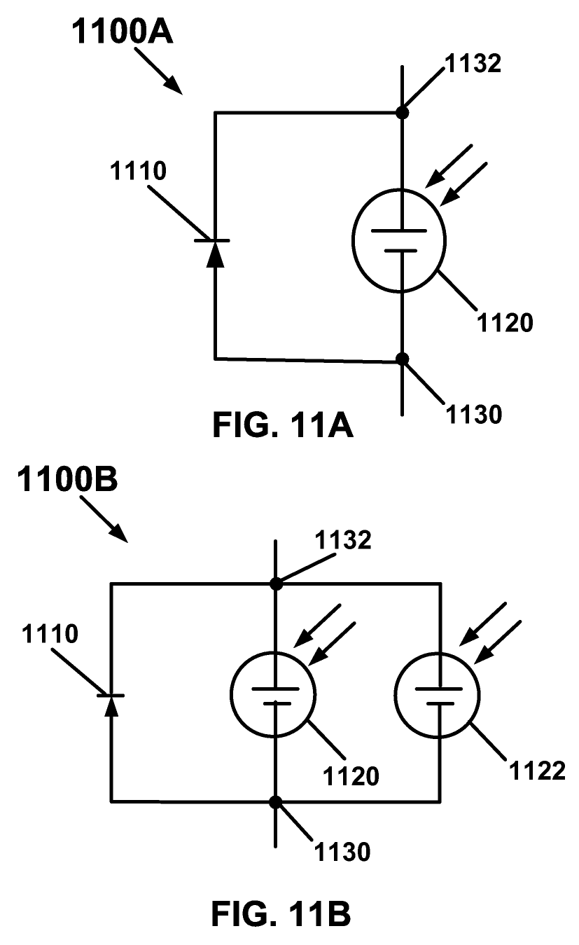

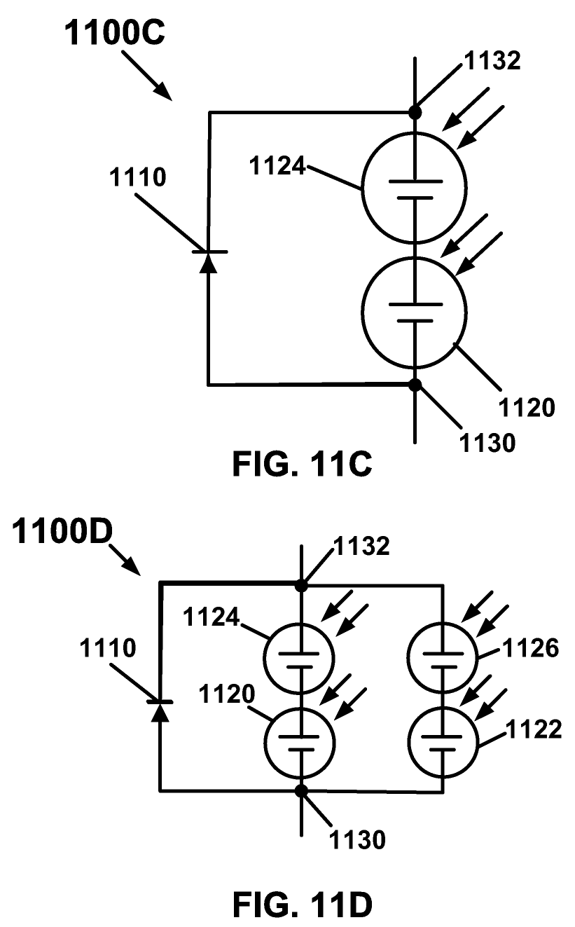

With reference now to FIGS. 11A-11D, several embodiments of the present invention are shown that illustrate the manner in which a diode may be electrically coupled with at least one or a plurality of solar cells. Within the spirit and scope of embodiments of the present invention, at least one or the plurality of solar cells may be disposed in the solar-cell sub-module, and the diode may be disposed in an in-laminate-diode sub-assembly of an in-laminate diode assembly. FIG. 11A shows a schematic diagram 1100A of a diode 1110 used to by-pass current around a solar cell 1120 and electrically coupled in parallel with one solar cell 1120. The diode 1110 is electrically coupled in parallel to the solar cell 1120 at a first terminal 1132 and at a second terminal 1130. To by-pass current around the solar cell 1120 in an event that the solar cell 1120 develops a high resistance to the passage of solar-cell module current, the diode 1110 is coupled to solar cell 1120 with reverse polarity to that of the solar cell 1120. FIG. 11B shows a schematic diagram 1100B of the diode 1110 used to by-pass current around a plurality of solar cells and electrically coupled in parallel with the plurality of solar cells that are electrically coupled in parallel. The diode 1110 is electrically coupled in parallel to the combination of solar cell 1120 and a parallel solar cell 1122. The diode 1110 is electrically coupled with the parallel combination of solar cells 1120 and 1122 at first terminal 1132 and at second terminal 1130. To by-pass current around the parallel combination of solar cells 1120 and 1122 in an event that at least one of the solar cells 1120 or 1122 develops a high resistance to the passage of solar-cell module current, the diode 1110 is coupled to the solar cells 1120 and 1122 with reverse polarity to both of the solar cells 1120 and 1122. FIG. 11C shows a schematic diagram 1100C of the diode 1110 used to by-pass current around a plurality of solar cells and electrically coupled in parallel with the plurality of solar cells 1120 and 1124 that are electrically coupled in series. The diode 1110 is electrically coupled in parallel to the combination of solar cell 1120 and solar cell 1124 coupled in series with solar cell 1120. The diode 1110 is electrically coupled with the series combination of solar cells 1120 and 1124 at first terminal 1132 and at second terminal 1130. To by-pass current around the series combination of solar cells 1120 and 1124 in an event that at least one of the solar cells 1120 or 1124 develops a high resistance to the passage of solar-cell module current, the diode 1110 is coupled to the solar cells 1120 and 1122 with reverse polarity to both of the solar cells 1120 and 1124. FIG. 1 ID shows a schematic diagram 1100D of a diode used to by-pass current around a plurality of solar cells and electrically coupled in parallel with the plurality of solar cells that are electrically coupled in series and in parallel. The diode 1110 is electrically coupled in parallel to the combination of solar cell 1120 and solar cell 1124 coupled in series with solar cell 1120 and the combination of solar cell 1122 and solar cell 1126 coupled in series with solar cell 1122. The diode 1110 is electrically coupled with the series/parallel combination of solar cells 1120, 1124, 1122 and 1126 at first terminal 1132 and at second terminal 1130. To by-pass current around the series/parallel combination of solar cells 1120, 1124, 1122 and 1126 in an event that at least one of the solar cells 1120, 1124, 1122 and 1126 develops a high resistance to the passage of solar-cell module current, the diode 1110 is coupled to the solar cells 1120, 1124, 1122 and 1126 with reverse polarity to the solar cells 1120, 1124, 1122 and 1126. In accordance with embodiments of the present invention, a solar-cell sub-module may be selected from the group consisting of one solar cell, a parallel combination of solar cells, a series combination of solar cells and a series/parallel combination of solar cells. Moreover, although embodiments of the present invention have been shown as just two solar cells electrically coupled in series, and just two parallel legs of a circuit of solar cells electrically coupled in parallel, embodiments of the present invention include pluralities of series coupled solar cells greater than two, and pluralities of parallel coupled solar cells or parallel coupled pluralities of series coupled solar cells greater than two. Therefore, embodiments of the present invention include a diode electrically coupled in parallel with any network that includes a configuration of interconnected solar cells, in which the diode serves to by-pass current around the network in an event the network, or alternatively a solar cell within the network, develops high resistance to the flow of current through the solar-cell module.

With further reference to FIG. 10, in accordance with embodiments of the present invention, the solar-cell module 1002 includes at least one pair of first and terminating busbars 1019a and 1019b, respectively, electrically coupled to a first end and a terminating end of the plurality 1010 of solar-cells 1012a-1017a and 1012b-1017b. The first busbar 1019a may be disposed on and electrically coupled to a back side of a first solar cell, for example, solar cell 1012a. The terminating busbar 1019b may be disposed proximately to and electrically coupled to a light-facing side of a terminating solar cell 1017b. The pair of first and terminating busbars, respectively, 1019a and 1019b is electrically coupled to the pair of external-connection mechanisms mounted to respective edge regions, respectively, for example, located at corners 1080 and 1082. Alternatively, the solar-cell module 1002 may also include other pairs of first and terminating busbars (not shown), which may be electrically coupled to a first end and a terminating end of the second plurality 1020 of solar-cells 1022a-1027a and 1022b-1027b, or the third plurality 1030 of solar-cells 1032a-1037a and 1032b-1037b. Other first busbars may be disposed on and electrically coupled to back sides of respective first solar cells 1022a and 1032a. Other terminating busbars may be disposed proximately to and electrically coupled to light-facing sides of respective terminating solar cells 1027b and 1037b. The other pairs of first and terminating busbars may also be electrically coupled to the pair of external-connection mechanisms mounted to respective edge regions, respectively, for example, located at corners 1080 and 1082. The first busbar 1019a and the other first busbars may be separate entities that may be separated by one or more gaps; and, the terminating busbar 1019b and the other terminating busbars may be separate entities that may be separated by a second set of one or more gaps. In an embodiment of the present invention, the first busbar 1019a may be electrically coupled together with the other first busbars and the terminating busbar 1019b may be electrically coupled together with the other terminating busbars such that pluralities 1010, 1020 and 1030 of solar cells are electrically coupled in parallel. However, as shown in FIG. 10, there are no other busbars besides first busbar and terminating busbars 1019a and 1019b; only a single first busbar 1019a and a single terminating busbars 1019b electrically couple the pluralities 1010, 1020 and 1030 of solar cells in parallel.

With further reference to FIG. 10, in accordance with embodiments of the present invention, the solar-cell module 1002 may further include an integrated busbar-solar-cell-current collector as described above in Section I and shown in FIGS. 6A and 6B. The integrated busbar-solar-cell-current collector 690 includes the terminating busbar 680, identified with the terminating busbar 1019b of solar-cell module 1002, and the integrated solar-cell, current collector 670. The integrated solar-cell, current collector 670 includes the plurality of integrated pairs 670a&b, 670c&d, 670e&f, 670g&h, and 670l&m and 670i of electrically conductive, electrically parallel trace portions 670a-m. The plurality of integrated pairs 670a&b, 670c&c, 670e&f, 670g&h, 670i and 670l&m of electrically conductive, electrically parallel trace portions 670a-m is configured both to collect current from the terminating solar cell 660, identified with solar cell 1017b, and to interconnect electrically to the terminating busbar 680. The plurality of integrated pairs 670a&b, 670c&c, 670e&f, 670g&h, 670i and 670l&m of electrically conductive, electrically parallel trace portions 670a-m is configured such that solar-cell efficiency is substantially undiminished in an event that any one electrically conductive, electrically parallel trace portion, for example, 670h, of the plurality of integrated pairs 670a&b, 670c&c, 670e&f, 670g&h, 670i and 670l&m of electrically conductive, electrically parallel trace portions 670a-m is conductively impaired. The terminating busbar 680 may be disposed above, or below, and coupled electrically to extended portions, for example, extended portions 670x and 670y, of the plurality of integrated pairs 670a&b, 670c&c, 670e&f, 670g&h, 670i and 670l&m of electrically conductive, electrically parallel trace portions 670a-m configured such that the terminating busbar 680 is configured to reduce shadowing of the terminating solar cell 660. The extended portions 670x and 670y of the plurality of integrated pairs of electrically conductive, electrically parallel trace portions 670a&b, 670c&c, 670e&f, 670g&h, 670i and 670l&m allow the terminating busbar 680 to fold under the back side 668 of the terminating solar cell 660, identified with the terminating solar cell 1017b of solar-cell module 1002. Therefore, in accordance with embodiments of the present invention, the terminating busbar 680, identified with the terminating busbar 1019b of solar-cell module 1002, may be folded under the back side 668 of the terminating solar cell 660, identified with the terminating solar cell 1017b of solar-cell module 1002. Consequently, but without limitation to the folded-under configuration for the terminating busbar 680 described above, the solar-cell module 1002 may be arranged with a configuration to minimize wasted solar-collection space within the solar-cell module 1002 such that solar-cell-module efficiency is greater than solar-cell-module efficiency in the absence of such configuration, in accordance with embodiments of the present invention.

With further reference to FIG. 10, in accordance with embodiments of the present invention, the solar-cell module 1002 may further include an interconnect assembly 420 as described above in Section I and shown in FIGS. 4B and 4C. The solar-cell module 404, identified with solar-cell module 1002, includes the first solar cell 410, identified with solar cell 1012a, at least the second solar cell 430, identified with solar cell 1013a, and the interconnect assembly 420 disposed above the light-facing side 416 of the absorber layer of the first solar cell 410. The interconnect assembly 420 includes the trace including the plurality of electrically conductive portions 420a, 420b, 420c, 420i and 420m. The plurality of electrically conductive portions 420a, 420b, 420c, 420i and 420m is configured both to collect current from the first solar cell 410 and to interconnect electrically to the second solar cell 430. The plurality of electrically conductive portions 420a, 420b, 420c, 420i and 420m is configured such that solar-cell efficiency is substantially undiminished in an event that any one of the plurality of electrically conductive portions 420a, 420b, 420c, 420i and 420m is conductively impaired. In accordance with embodiments of the present invention, the plurality of electrically conductive portions 420a, 420b, 420c, 420i and 420m of the interconnect assembly 420 may be coupled electrically in series to form a single continuous electrically conductive line. In addition, the trace of the interconnect assembly 420 may be disposed in a serpentine pattern such that the interconnect assembly 420 is configured to collect current from the first solar cell 410 and to interconnect electrically to the second solar cell 430.

With further reference to FIG. 10, in accordance with embodiments of the present invention, the trace of the interconnect assembly 420 interconnecting the solar cells 1012a and 1013a of the solar-cell module 1002 is further described above in Section I and shown in FIGS. 5B and 5C. The trace 520 may further include an electrically conductive line including a conductive core 520A and at least one overlying layer 520B overlying the conductive core 520A. Alternatively, the trace 520 may include the electrically conductive line including the conductive core 520A including nickel, without the overlying layer 520B; or, the trace 520 may include the electrically conductive line including the conductive core 520A including material having greater conductivity than nickel and the overlying layer 520B including nickel.

With reference now to FIG. 12B, in accordance with embodiments of the present invention, a plan view 1200B of the solar-cell array 1252 including the plurality 1260 of solar-cell modules 1260a, 1260b and 1260c is shown. FIG. 12B shows the plurality 1260 of solar-cell modules 1260a, 1260b and 1260c combined with external-connection mechanisms mounted to respective edge regions and in-laminate-diode assemblies. For example, solar-cell module 1260b includes a first in-laminate-diode assembly 1270, a second in-laminate-diode assembly 1271 and a third in-laminate-diode assembly 1272; solar-cell module 1260b also includes a first busbar 1274 and a terminating busbar 1276 each electrically coupled with the first, second and third in-laminate-diode assemblies 1270, 1271 and 1272. The solar-cell module 1260b further includes a first external-connection mechanism 1280b, for example, a first junction box, mounted to a first edge region, for example, a first corner, of the protective structure and a second external-connection mechanism 1282b, for example, a second junction box, mounted to a second edge region, for example, a second corner, of the protective structure. The first external-connection mechanism 1280b mounted to a first respective edge region is configured to enable collection of current from the solar cells of the solar-cell module 1260b and to allow interconnection with at least one other external device, as shown here solar-cell module 1260a. Similarly, the second external-connection mechanism 1282b mounted to a second respective edge region is configured to enable collection of current from the solar-cell sub-modules of the solar-cell module 1260b and to allow interconnection with at least one other external device, as shown here solar-cell module 1260c. In embodiments of the present invention, the solar-cell module 1260b is coupled in series with the other solar-cell module 1260a, and also solar-cell module 1260c. However, in accordance with embodiments of the present invention, solar-cell modules may be interconnected in parallel or series/parallel combinations which are within the spirit and scope of the embodiments of the present invention.

With further reference to FIG. 12B, in accordance with embodiments of the present invention, solar-cell module 1260a also includes first external-connection mechanism 1280a, for example, a first junction box, mounted to a first edge region, for example, a first corner, of the protective structure of solar-cell module 1260a and a second external-connection mechanism 1282a, for example, a second junction box, mounted to a second edge region, for example, a second corner, of the protective structure of solar-cell module 1260a. Similarly, solar-cell module 1260c also includes a first external-connection mechanism 1280c, for example, a first junction box, mounted to a first edge region, for example, a first corner, of the protective structure of solar-cell module 1260c and a second external-connection mechanism 1282c, for example, a second junction box, mounted to a second edge region, for example, a second corner, of the protective structure of solar-cell module 1260c.

With further reference to FIG. 12B, in accordance with embodiments of the present invention, the external-connection mechanism 1280b mounted to its respective edge region of solar-cell module 1260b is disposed in a configuration opposite the external-connection mechanism 1282b mounted to its respective edge region of solar-cell module 1260b on a lateral side of the solar-cell module 1260b. This configuration, when applied to the plurality 1260 of all solar-cell modules 1260a, 1260b and 1260c, allows the two solar-cell modules 1260a and 1260b with external-connection mechanisms 1282a and 1280b mounted to respective edge regions to be disposed on respective lateral sides of the two solar-cell modules 1260a and 1260b. The solar-cell modules 1260a and 1260b, thus configured, may be intercoupled with interconnector 1284. Thus, the second external-connection mechanism 1282a of the first solar-cell module 1260a may be disposed proximately to the first external-connection mechanism 1280b of the second solar-cell module 1260b. Alternatively, the first external-connection mechanism 1280c of the third solar-cell module 1260c may be disposed proximately to the second the second external-connection mechanism 1282b of the second solar-cell module 1260b. Thus, in accordance with embodiments of the present invention, a first external-connection mechanism of a plurality of external-connection mechanisms of a solar-cell module is disposed proximate to a second external-connection mechanism of a second plurality of external-connection mechanisms of another solar-cell module. Moreover, in accordance with embodiments of the present invention, a first external-connection mechanism of a plurality of external-connection mechanisms of a solar-cell module, for example, the first external-connection mechanism 1280c of third solar-cell module 1260c, and a second external-connection mechanism of a plurality of external-connection mechanisms of a second solar-cell module, for example, the second external-connection mechanism 1282b of solar-cell module 1260b, are arranged on their respective solar-cell modules 1260c and 1260b to minimize a length of an interconnector 1288 between the first external-connection mechanism 1280c and the second external-connection mechanism 1282b. Thus, the solar-cell modules 1260a, 1260b and 1260c are intercoupled to form the solar-cell array 1252. Furthermore, in accordance with embodiments of the present invention, a first external-connection mechanism of a plurality of external-connection mechanisms of a solar-cell module may be selected from the group consisting of a wire, a connector, a lead, and a junction box. Also, an edge region may be selected from the group consisting of an edge of the solar-cell module and a corner of the solar-cell module, where two edges may meet.

With reference now to FIG. 12A, the embodiments of the present invention described for FIG. 12B are contrasted with another embodiment of the present invention that employs centrally-mounted junction boxes 1230a, 1230b and 1230c. FIG. 12A is a plan view 1200A of a solar-cell array 1202 including a plurality 1210 of solar-cell modules 1210a, 1210b and 1210c combined with centrally-mounted junction boxes 1230a, 1230b and 1230c and in-laminate-diode assemblies 1220, 1212 and 1222 (shown only for solar-cell module 1210b). Solar-cell module 1210b includes a first in-laminate-diode assembly 1220, a second in-laminate-diode assembly 1221 and a third in-laminate-diode assembly 1222. Solar-cell module 1210b also includes a first busbar 1224 and a terminating busbar 1226 each electrically coupled with the first, second and third in-laminate-diode assemblies 1220, 1221 and 1222. Because the junction box 1230b of solar-cell module 1210b is centrally mounted, centrally-mounted junction box 1230b requires additional wiring to collect current from the solar-cell module 1210b. For example, a first supplemental busbar 1228 is electrically coupled to the first busbar 1224; and a second supplemental busbar 1229 is electrically coupled to the terminating busbar 1226. Similarly, because the junction box 1230b of solar-cell module 1210b is centrally mounted, long interconnectors are required between solar-cell modules. For example, a first interconnector 1234 between centrally-mounted junction boxes 1230a and 1230b is required to interconnect solar-cell modules 1210a and 1210b; and, a second interconnector 1238 between centrally-mounted junction boxes 1230b and 1230c is required to interconnect solar-cell modules 1210b and 1210c. As shown in FIG. 12A, the first interconnector 1234 includes two portions 1234a and 1234b which attach respectively to centrally-mounted junction boxes 1230a and 1230b, and are provided with connectors joining the two portions together; and, the second interconnector 1238 includes two portions 1238a and 1238b which attach respectively to centrally-mounted junction boxes 1230b and 1230c, and are provided with connectors joining the two portions together. This arrangement is contrasted with the short interconnectors 1284 and 1288 shown in FIG. 12B. Thus, the interconnection arrangement shown in FIG. 12B is less costly, because it requires less wiring, and improves solar-cell array efficiency, because there is less parasitic series resistance than would obtain with the additional wiring shown in FIG. 12A.

With further reference to FIGS. 12A and 12B, another distinguishing feature of embodiments of the present invention of FIG. 12B is that the use of an in-laminate-diode assembly facilitates the use of a plurality of external-connection mechanisms mounted to a respective plurality of edge regions. For embodiments of the present invention of FIG. 12A having centrally mounted junction boxes, a single diode included in the junction box would typically be employed instead of the in-laminate-diode assemblies, as shown. To the inventors' knowledge, one of the reasons those skilled in the art have not considered using separate junction boxes is because of the difficulty in placing a diode within separated junction boxes to provide the by-pass protection discussed above. Thus, a distinguishing feature of embodiments of the present invention is the use of an in-laminate-diode assembly that allows the use of separate junction boxes without the necessity of including diodes within a junction box.

With reference now to FIG. 13, in accordance with embodiments of the present invention, a combined perspective-plan and expanded view 1300 of an in-laminate-diode sub-assembly 1302 with diode 1310 is shown at the top and right of the figure. Also, towards the bottom and left of FIG. 13, a perspective-plan view of a second in-laminate-diode sub-assembly 1304 in a more fully assembled state is shown. The in-laminate-diode assembly of a solar-cell module, for example, in-laminate-diode assembly 1050 of solar-cell module 1002 of FIG. 10, may include a plurality of in-laminate-diode sub-assemblies, for example, in-laminate-diode sub-assemblies 1050a and 1050b. Alternatively, an in-laminate-diode assembly may include at least one in-laminate-diode sub-assembly. The in-laminate-diode sub-assembly 1302, which may be identified with in-laminate-diode sub-assembly 1050b, includes the diode 1310. The in-laminate-diode sub-assembly also includes a first conductor 1320 electrically coupled to the diode 1310. The first conductor 1320 is configured to couple electrically with a first terminal, which may be electrically coupled to a back side, of a primary solar cell of the solar-cell sub-module. The in-laminate-diode sub-assembly 1302 also includes a second conductor 1330 electrically coupled to the diode 1310, the second conductor 1330 configured to couple electrically with a second terminal, which may be electrically coupled to a light-facing side, of a last solar cell of the solar-cell sub-module.

With further reference to FIG. 13, in accordance with embodiments of the present invention, the diode 1310 is disposed between the first conductor 1320 and the second conductor 1330. In the expanded view at the top and right of FIG. 13, the disposition of the diode 1310 between first and second conductors 1320 and 1330 is indicated by a double-headed arrow 1350. The diode 1310 is disposed between a first tab portion 1320a of first conductor 1320 and a second tab portion 1330a of second conductor 1330. In an embodiment of the present invention, the diode may be a simple chip diced from a silicon wafer having a pn junction, as may be the case for an initially homogenously doped wafer with a diffused or implanted dopant profile of opposite type from a dopant species used in growing a boule from which the wafer is sliced. At least one of the first and second conductors 1320 and 1330 may be configured as a heat sink to remove heat generated by the diode 1310, although a heat-dissipating function may be provided by separate components. Because first and second conductors 1320 and 1330 may have the dual function of both providing an electrical path for, and dissipating heat generated by, current that by-passes a solar-cell sub-module with high resistance, both first conductor 1320 and second conductor 1330 may have a large current-carrying and heat-dissipating portions 1320b and 1330b, respectively. Alternatively, the in-laminate-diode assembly may be made with separate components for the heat-spreading function and the current-carrying function. Therefore, the first and second conductors 1320 and 1330 may be configured to provide an electrical path for current that by-passes a solar-cell sub-module; and, separate heat sinks configured as separate components from the first and second conductors 1320 and 1330 may be provided to dissipate heat generated by current that by-passes a solar-cell sub-module. In addition, both first conductor 1320 and second conductor 1330 may have broad low-contact-resistance portions 1320c (not shown for second conductor 1330) for making electrical contact and electrically coupling with respective portions of solar cells, or other components, for example, busbars, in the solar-cell sub-module, which the in-laminate-diode sub-assembly protects. In addition, the in-laminate-diode sub-assembly 1302 includes an electrically-insulating-laminate strip 1340. The electrically-insulating-laminate strip 1340 may be disposed between a plurality of first and second terminals, which may be back sides, of solar cells of the solar-cell sub-module, and the first conductor 1320 and the second conductor 1330. In an embodiment of the present invention, the plurality of first and second terminals of solar cells may be exclusive of the back side of the primary, or first, solar cell of a solar-cell sub-module.

With further reference to FIG. 13, in accordance with embodiments of the present invention, the back side of a solar cell may provide electrical coupling to both the light-facing side of one solar cell in the solar-cell sub-module and the back side of an adjacent solar cell in an adjacent solar-cell sub-module as for the interconnect assembly described above for FIGS. 4A-4F. The first terminal may be electrically coupled to a positive terminal or a negative terminal of a solar cell in the solar-cell sub-module with which the diode is electrically coupled in parallel as described above for FIGS. 11A-11D. Similarly, the second terminal may be electrically coupled to a positive terminal or a negative terminal of a solar cell in the solar-cell sub-module with which the diode is electrically coupled in parallel, but the second terminal will be electrically coupled to the terminal of the solar cell having opposite polarity to that of the terminal of the solar cell to which the first terminal is electrically coupled. For example, if the first terminal is electrically coupled to a positive terminal of a solar cell, the second terminal will be electrically coupled to a negative terminal of a solar cell. However, the polarity of the diode will always be electrically coupled with opposite to the polarity of the solar cell terminals with which the first and second terminals are electrically coupled as described above for FIGS. 11A-11D. In an embodiment of the present invention, the back side of a solar cell corresponds to positive terminal of the solar cell, and the light-facing side corresponds to negative terminal of the solar cell, as for the CIGS solar cells described in FIGS. 1A-1B. However, it should be noted that nothing precludes the application of embodiments of the present invention to solar-cell modules where the back side of a solar cell corresponds to a negative terminal of the solar cell, and the light-facing side corresponds to a positive terminal of the solar cell, or alternatively where both the positive and negative terminals of the solar cell may be disposed on the same side of the solar cell, whether it may be a back side or a light-facing side, so that such embodiments of the present invention are within the spirit and scope of embodiments of the present invention.

With further reference to FIG. 13, in accordance with embodiments of the present invention, the in-laminate-diode sub-assembly 1302 further includes the electrically-insulating-laminate strip 1340 configured to allow access of at least one of the first and second conductors 1320 and 1330 to a solar cell of the plurality of solar cells of a solar-cell module, or solar-cell sub-module, for electrically coupling with the solar cell. For example, the electrically-insulating-laminate strip 1340 may include a continuous electrically-insulating-laminate strip with an access region 1342 through which the first conductor electrically couples with the back side of the primary solar cell. Alternatively, the electrically-insulating-laminate strip 1340 may include a plurality of separate electrically-insulating-laminate sub-strips separated by gaps corresponding with first and second terminals at which an in-laminate-diode sub-assembly makes contact with solar cells of the solar-cell sub-module. Therefore, the access region 1342 may be selected from the group consisting of a window, an opening, an aperture, a gap, and a discontinuity in the electrically-insulating-laminate strip 1340. As shown in FIG. 13, this also allows the second conductor 1330 to electrically couple with the light-facing side of the last solar cell of the solar-cell sub-module, because the light-facing side of the last solar cell of the solar-cell sub-module may be electrically coupled in common with the back side of the primary solar cell of an adjacent solar-cell sub-module through an interconnect assembly between the back side of the primary solar cell and the light-facing side of the last solar cell of adjacent solar-cell sub-modules (not shown).

With further reference to FIG. 13, in accordance with embodiments of the present invention, the in-laminate-diode sub-assembly 1302 further includes at least one of the first and second conductors 1320 and 1330 structured to enable a laminated electrical connection between at least one of the first and second conductors 1320 and 1330 and another component of the solar-cell module. Another component of the solar-cell module may be a first busbar, a terminating busbar and the terminal of a solar cell of a solar-cell sub-module. The laminated electrical connection does not require solder, welding, a conducting adhesive or any other material disposed between a first contacting surface of the first conductor 1320 and/or second conductor 1330 and a second contacting surface of the other component of the solar-cell module to which the first conductor 1320 and/or second conductor 1330 are electrically connected. The laminated electrical connection requires only that a mechanical pressure be applied to hold the first conductor 1320 and/or second conductor 1330 in intimate contact with the other component of the solar-cell module to which the first conductor 1320 and/or second conductor 1330 are electrically connected.

With further reference to FIG. 10 and FIG. 13, in accordance with embodiments of the present invention, the first conductor 1320 may further include a first electrically-conducting-laminate strip configured to couple electrically with a first terminal of an adjacent last solar cell, for example, solar cell 1017a, of a first adjacent solar-cell sub-module, for example, solar-cell sub-module 1010a, and electrically coupled with a first adjacent diode. In an embodiment of the present invention, the first terminal of the adjacent last solar cell of the first adjacent solar-cell sub-module may be a light-facing side of the adjacent last solar cell of the first adjacent solar-cell sub-module. Thus, the first electrically-conducting-laminate strip has the function of both the first conductor 1320 of in-laminate-diode sub-assembly 1302 and the second conductor of second in-laminate-diode sub-assembly 1304. As shown in FIG. 13, the first conductor 1320 of in-laminate-diode sub-assembly 1302 has portions 1320d, 1320e and 1320f that serve, respectively, as a broad low-contact-resistance portion 1320d, a large current-carrying and heat-dissipating portion 1320e and a second tab portion 1320f as a second conductor of second in-laminate-diode sub-assembly 1304. Alternatively, the second conductor of second in-laminate-diode sub-assembly 1304 may be separated from the first conductor 1320 of in-laminate-diode sub-assembly 1302 along dashed line 1352 to provide the functions of the broad low-contact-resistance portion 1320d, the large current-carrying and heat-dissipating portion 1320e and the second tab portion 1320f of the second conductor of second in-laminate-diode sub-assembly 1304. Similarly, in accordance with embodiments of the present invention, the second conductor 1330 may further include a second electrically-conducting-laminate strip configured to couple electrically with a second terminal of an adjacent primary solar cell, for example, solar cell 1012b, of a second adjacent solar-cell sub-module, for example, solar-cell sub-module 1010b, and electrically coupled with a second adjacent diode. In an embodiment of the present invention, the second terminal of the adjacent primary solar cell of the second adjacent solar-cell sub-module may be a back side of the adjacent primary solar cell of the second adjacent solar-cell sub-module. Alternatively, the first terminal and the second terminal may be configured as described in the preceding paragraphs, particularly as described for FIGS. 11A-11D.

With reference now to FIG. 14, FIG. 10 and FIG. 12, in accordance with embodiments of the present invention, a combined plan and perspective view 1400 of a lead 1422 at a cut corner 1418 of the back glass 1414 of a solar-cell module, for example, solar-cell module 1002, is shown. The lead 1422 is shown here as a folded-over lead, without limitation thereto for embodiments of the present invention. An external-connection mechanism of the solar-cell module is electrically coupled to the lead 1422 at an edge region, for example, the cut corner 1418, of the plurality of edge regions of the protective structure of the solar-cell module, for example, solar-cell module 1002. The lead 1422 is electrically coupled to the plurality of solar cells, for example, plurality 1010 of solar cells 1012a-1017a and 1012b-1017b. As described above, an external-connection mechanism of the solar-cell module may be selected from the group consisting of a wire, a connector, a lead, and a junction box, for example, external-connection mechanism 1282b as discussed here; and, an edge region may be selected from the group consisting of an edge of the solar-cell module and a corner of the solar-cell module, where two edges may meet, for example, cut corner 1418 as discussed here. The junction box, for example, external-connection mechanism 1282b, of the solar-cell module, for example, solar-cell module 1260b, may be electrically coupled to an interconnector, for example, interconnector 1288, through the lead 1422 at the cut corner 1418 of the back glass 1414 of the solar-cell module 1260b. The lead 1422 may be intercoupled with appropriate lugs and internal wiring to an external terminal junction of the junction box, for example, external-connection mechanism 1282b, to provide this electrical coupling. The lead 1422 may be electrically coupled to the plurality of solar-cell sub-modules, for example, solar-cell sub-modules 1010a-1010b, through a busbar (not shown) to which it is electrically coupled. In embodiments of the present invention, the lead 1422 at the edge region, for example, cut corner 1418, of the plurality of edge regions of the protective structure, for example, back glass 1414, may include a copper lead.

With further reference to FIG. 14 and FIG. 10, in accordance with embodiments of the present invention, an edge 1424 of the lead 1422 at the edge region, for example, cut corner 1418, of the protective structure, for example, front glass 1410 or back glass 1414, is located at a distance 1428 at least three-eighths of an inch from a nearest externally accessible portion of the protective structure, for example, a joint 1426 between the external-connection mechanism (not shown) and the front glass 1410 or back glass 1414, proximate to the edge of the lead. For example, the edge 1424 of the lead at the cut corner 1418 of the front glass 1410 or back glass 1414 may be located no closer than the distance 1428 of three-eighths of an inch from the joint 1426 that an external-connection mechanism, for example, a junction box, makes with the protective structure, for example, front glass 1410 or back glass 1414. Alternatively, the edge region may be a set-off notch (not shown) at an edge, for example, edges 1090, 1092, 1094 and 1096 as shown in FIG. 10, of the protective structure, rather than the cut corner 1418, at which an external-connection mechanism, for example, a junction box might be disposed. It should be noted that the joint 1426 between the outer surface of the junction box and the front glass 1410 or back glass 1414 is the nearest externally accessible portion of the protective structure. The three-eighths of an inch distance 1428 between this joint 1426 and the edge 1424 of the lead 1422 would provide a safe distance against the intrusive migration of water along the interface between encapsulating adhesives used to attach the junction box to the front glass 1410 or back glass 1414 and potting compounds used in the junction box to electrically insulate the lead 1422. A distance shorter than the three-eighths of an inch distance 1428 might cause an electrical shock hazard for a potential difference above ground potential, greater than or equal to 600 volts, on the lead 1422. In addition, the lead 1422 at the edge region, for example, cut corner 1418, of the protective structure, for example, back glass 1414, may include a portion of a busbar (not shown) attached to the plurality of solar cells, for example, the plurality 1010 of solar cells 1012a-1017a and 1012b-1017b. As shown in FIG. 14, the front glass 1410 and the back glass 1414 that encapsulate the plurality of solar cells, for example, the plurality 1010 of solar cells 1012a-1017a and 1012b-1017b, provides a protective structure for the solar-cell module, for example, solar-cell module 1002 as shown in FIG. 10. In accordance with embodiments of the present invention, the lead 1422 at the edge region, for example, cut corner 1418, is sealed between the front glass 1410 of the protective structure and a bottom portion, for example, back glass 1414, of the protective structure with a first layer 1430 of polymeric sealing material and a second layer 1432 of polymeric sealing material. The first layer 1430 of polymeric sealing material is disposed between a lead-facing portion of the front glass 1410 and the lead 1422, and the second layer 1432 of polymeric sealing material is disposed between a lead-facing portion of the bottom portion of the protective structure and the lead 1422. In embodiments of the present invention, the polymeric sealing material may be a butyl-based sealing material. The bottom portion of the protective structure may be a back glass 1414 but without limitation thereto for embodiments of the present invention; for example, the bottom portion might be a non-transparent electrically insulating material other than glass. To the inventors' knowledge, the use of this double application of polymeric sealing material to seal a lead emerging from between the edges of the protective structure, for example, front glass 1410 and back glass 1414, of a solar-cell module has not been used prior to its use in embodiments of the present invention.

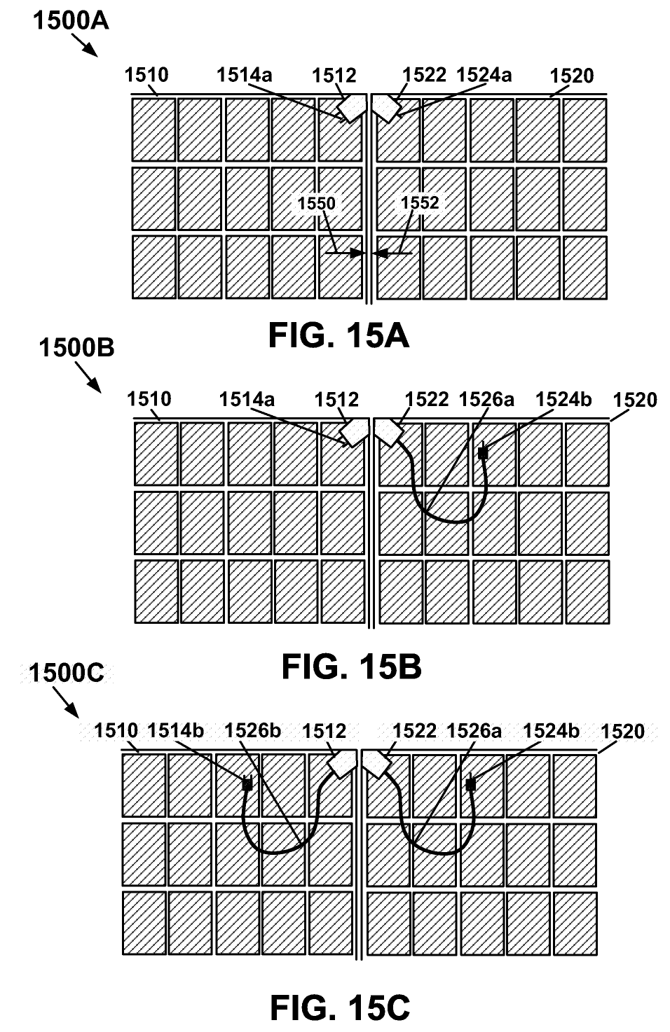

With reference now to FIGS. 15A, 15B and 15C, in accordance with embodiments of the present invention, various interconnection schemes for interconnecting solar-cell modules having a variety of external-connection mechanisms are shown. The external-connection mechanisms are selected from the group consisting of junction boxes with an integrally attached male connector or an integrally attached female receptacle, and junction boxes with integrally attached leads having an attached male connector or an attached female receptacle. The embodiments of the present invention described for FIGS. 15A, 15B and 15C are but representative of embodiments of the present invention and are provided without limitation thereto, as other embodiments of the present invention for interconnecting two solar-cell modules are also within the spirit and scope of embodiments of the present invention.

With reference now to FIG. 15A, in accordance with embodiments of the present invention, a plan view 1500A of a first junction box 1512 of a first solar-cell module 1510 with a female receptacle 1514a and a second junction box 1522 of a second solar-cell module 1520 with a male connector 1524a configured to allow interconnection with the first solar-cell module 1510 is shown. An interconnector (not shown) provided with the male connector at one end and a female receptacle at the other end may be used to interconnect first and second solar cell modules 1510 and 1520. Junction boxes 1512 and 1522 may be mounted on the respective corners of their respective solar-cell modules 1510 and 1520 with adhesives, and the internal wiring and connections with respective leads of their respective solar-cell modules 1510 and 1520 may be protected from the environment with suitable electrical potting compounds. In accordance with embodiments of the present invention, the separation between first and second solar-cell modules 1510 and 1520, indicated by a gap between arrows 1550 and 1552, may also be minimized so as to reduce the length of an interconnector (not shown) between first and second solar-cell modules 1510 and 1520. Minimizing the separation between solar-cell modules improves solar-cell array efficiency by reducing wasted solar-collection space over the foot-print of the solar-cell array, as well as reducing the parasitic series resistance associated with a long interconnector having to span a large separation between first and second solar-cell modules 1510 and 1520. Thus, in accordance with embodiments of the present invention, the solar-cell modules are arranged with a configuration to minimize wasted solar-collection space within the solar-cell array such that solar-cell-array efficiency is greater than solar-cell-array efficiency in the absence of the configuration.

With reference now to FIG. 15B, in accordance with embodiments of the present invention, a plan view 1500B of an interconnector 1526a with a male connector 1524b integrally attached to the second junction box 1522 of the second solar-cell module 1520 and configured to allow interconnection with the first junction box 1512 with the female receptacle 1514a of the first solar-cell module 1510 is shown. In accordance with embodiments of the present invention, the interconnector 1526a between the second junction box 1522 of the second solar-cell module 1520 and the first junction box 1512 of the first solar-cell module 1510 may be a flexible interconnector. The interconnector 1526a between the second junction box 1522 of the second solar-cell module 1520 and the first junction box 1512 of the first solar-cell module 1510 may also be a rigid interconnector. The interconnector 1526a may be integrally attached to the second junction box 1522 of the second solar-cell module 1520 and configured to allow interconnection with the first junction box 1512 of the first solar-cell module 1510 such that the interconnector 1526a has the male connector 1524b to interconnect to the female receptacle 1514a integrally attached to the first junction box 1512 of the first solar-cell module 1510.

With reference now to FIG. 15C, in accordance with embodiments of the present invention, a plan view 1500C of an interconnector 1526b with a female receptacle 1514b integrally attached to the first junction box 1512 of the first solar-cell module 1510, and of the interconnector 1526a with the male connector 1524b integrally attached to the second junction box 1522 of the second solar-cell module 1520 and configured to allow interconnection with the first junction box 1512 is shown. In accordance with embodiments of the present invention, the interconnector 1526a attached to the second junction box 1522 of the second solar-cell module 1520 may be a flexible interconnector. Similarly, the interconnector 1526b attached to the first junction box 1512 of the first solar-cell module 1510 may be a flexible interconnector. The interconnector 1526a attached to the second junction box 1522 of the second solar-cell module 1520 and the first junction box 1512 of the first solar-cell module 1510 may also be a rigid interconnector. Similarly, the interconnector 1526b attached to the first junction box 1512 of the first solar-cell module 1510 may be a rigid interconnector. The interconnectors 1526a and 1526b may be integrally attached to their respective junction boxes 1522 and 1512 and configured to allow interconnection of the first junction box 1512 of the first solar-cell module 1510 to the second junction box 1522 of the second solar-cell module 1520 through the interconnection of the male connector 1524b with the female receptacle 1514b.

### Section III:

### Physical Description of Embodiments of the Present Invention for a Power-Loss-Inhibiting Current-Collector and a Combined Solar-Cell, Power-Loss-Inhibiting Current-Collector

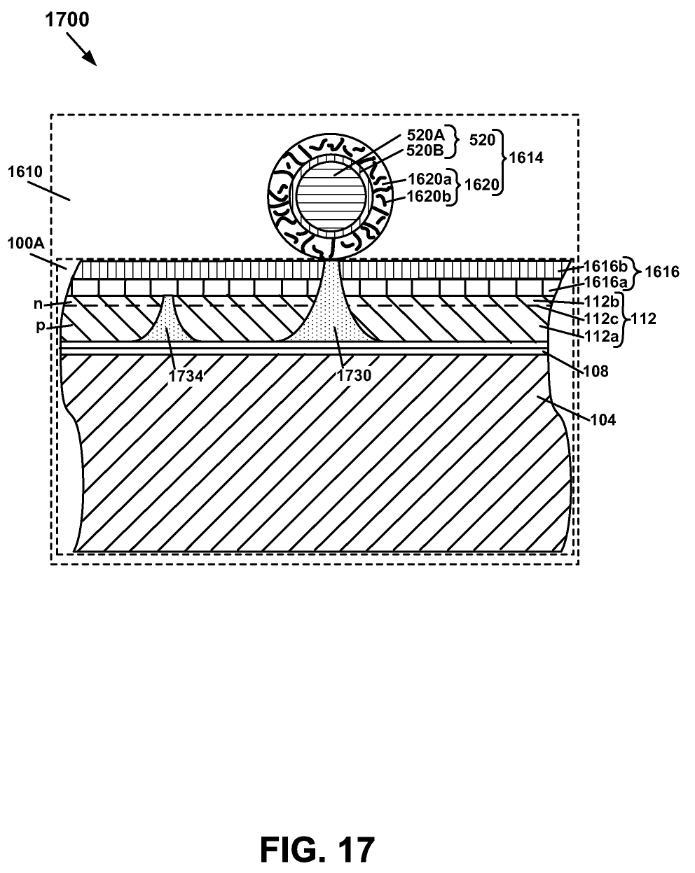

With reference now to FIG. 16, in accordance with embodiments of the present invention, a first cross-sectional elevation view 1600 of a combined solar-cell, power-loss-inhibiting current-collector 1610 is shown. FIG. 16 shows the physical arrangement of a power-loss-inhibiting current-collector 1614 on a light-facing side of a solar cell 100A and a first example microstructure of a positive-temperature-coefficient-of-electrical-resistance (PTCR) structure in a current-limiting portion 1620 of the power-loss-inhibiting current-collector 1614 under normal operating conditions. The combined solar-cell, power-loss-inhibiting current-collector 1610 includes the solar cell 100A and the power-loss-inhibiting current-collector 1614. The power-loss-inhibiting current-collector 1614 includes a trace 520 for collecting current from the solar cell 100A and a current-limiting portion 1620 of the power-loss-inhibiting current-collector 1614 coupled with the trace 520. The current-limiting portion 1620 is configured to regulate current flow through the power-loss-inhibiting current-collector 1614. The current-limiting portion 1620 possesses the property that, in the absence of a shunt defect 1730 (see FIG. 17) in the solar cell 100A, the current-limiting portion 1620 has high conductivity, but, in the presence of the shunt defect 1730 (see FIG. 17) in the solar cell 100A in proximity to a contact between the current-limiting portion 1620 of a segment of the power-loss-inhibiting current-collector 1614 and the solar cell 100A, the current-limiting portion 1620 located in proximity to a contact between the current-limiting portion 1620 of the segment of the power-loss-inhibiting current-collector 1614 has low conductivity, as will be subsequently described in greater detail. In other words, the current-limiting portion 1620 is designed so that the current-limiting portion 1620 is thin enough and conductive enough that efficiency of the solar cell 100A, and correspondingly, efficiency of a solar-cell module and efficiency of a solar-cell array incorporating the solar cell 100A are not lost; but also, the current-limiting portion 1620 is designed so that the thickness and conductivity of the current-limiting portion 1620 are balanced to prevent excessive current flow through the shunt defect 1730 (see FIG. 17).

With further reference to FIG. 16, in accordance with one embodiment of the present invention, it is noted that the current-limiting portion 1620, although shown as having the first example microstructure of a PTCR structure, need not have such microstructure, nor indeed even include PTCR material. Therefore, encompassed within the spirit and scope of embodiments of the present invention, are a current-limiting portion 1620 including, and fabricated from, a current-limiting material, or a combination of a PTCR material with a current-limiting material, that provide current-limiting characteristics, or behavior, to the power-loss-inhibiting current-collector 1614. Furthermore, it is noted that PTCR materials as described herein are current-limiting materials, and that current-limiting materials may have a positive temperature coefficient of electrical resistance, although such current-limiting materials need not have the PTCR structure as subsequently described. Thus, embodiments of the present invention shown in FIG. 16, and subsequently FIG. 17, should not be construed to preclude the use of current-limiting material, or a combination of a PTCR material with a current-limiting material, in the current-limiting portion 1620 of the power-loss-inhibiting current-collector 1614.

With further reference to FIG. 16, in accordance with one embodiment of the present invention, the first example microstructure of the PTCR structure in the current-limiting portion 1620 of the power-loss-inhibiting current-collector 1614 is shown that imparts low resistance to the power-loss-inhibiting current-collector 1614 under normal operating conditions. The current-limiting portion 1620 that includes the PTCR structure having a positive temperature coefficient of electrical resistance includes a low-conductivity matrix portion 1620a and a plurality of high-conductivity portions 1620b, which may include conductive filler, dispersed in the low-conductivity matrix portion 1620a. In the low-electrical-resistance state, the high-conductivity portions 1620b provide a high-conductivity pathway for the flow of current between the trace 520 and the solar cell 100A. In one embodiment of the present invention, the example microstructure of the PTCR structure in the current-limiting portion 1620 includes high-conductivity portions 1620b including a dispersion of filaments of high-conductivity material in the low-conductivity matrix portion 1620a. The dispersion of filaments of high-conductivity material may be arranged as a percolating network that provides a high-conductivity pathway for the flow of current between the trace 520 and the solar cell 100A under normal operating conditions, such as conditions occurring during solar illumination.

With further reference to FIG. 16, and FIGS. 5B and 5C as described in Section I above, in accordance with embodiments of the present invention, the trace 520 may further include an electrically conductive line including an electrically conductive core 520A with at least one overlying layer 520B. In one embodiment of the present invention, the electrically conductive line may include the electrically conductive core 520A including a material having greater conductivity than nickel, for example, copper, with an overlying layer 520B including nickel. In another embodiment of the present invention, the electrically conductive line may include the electrically conductive core 520A including nickel without the overlying layer 520B. The electrically conductive line may also be selected from a group consisting of an electrically conductive copper core clad with a silver cladding, an electrically conductive copper core clad with a nickel coating further clad with a silver cladding and an electrically conductive aluminum core clad with a silver cladding.

With further reference to FIG. 16, in accordance with embodiments of the present invention, the current-limiting portion 1620 includes a layer of current-limiting material disposed coating at least a portion of the trace 520. Therefore, in accordance with embodiments of the present invention, the interconnect assembly, the solar-cell current collector, and the integrated busbar-solar-cell-current collector as described in Section I and embodiments of the present invention incorporating the interconnect assembly, the solar-cell current collector, and the integrated busbar-solar-cell-current collector as described in Section II may further include the power-loss-inhibiting current-collector 1614, wherein a trace 520 within, respectively, the interconnect assembly, the solar-cell current collector, and the integrated busbar-solar-cell-current collector is configured so that the current-limiting portion 1620 of the power-loss-inhibiting current-collector 1614 includes the layer of current-limiting material disposed coating at least a portion of the trace 520. In addition, in accordance with embodiments of the present invention, the solar-cell module as described in Section I and embodiments of the present invention incorporating the solar-cell module as described in Section II may further include a first combined solar-cell, power-loss-inhibiting current-collector 1610 and at least a second combined solar-cell, power-loss-inhibiting current-collector and an interconnect assembly, wherein the trace 520 of the interconnect assembly is configured so that the current-limiting portion 1620 of the power-loss-inhibiting current-collector 1614 includes the layer of current-limiting material disposed coating at least a portion of the trace 520. Moreover, as embodiments of the present invention describing a solar-cell array include solar-cell modules, embodiments of the present invention for a solar-cell array incorporate embodiments for a power-loss-inhibiting current-collector 1614 and a combined solar-cell, power-loss-inhibiting current-collector 1610 such that the interconnect assemblies of solar-cell modules in the solar-cell array may further include the power-loss-inhibiting current-collector 1614, wherein the trace 520 of the respective interconnect assemblies is configured so that the current-limiting portion 1620 of the power-loss-inhibiting current-collector 1614 includes the layer of current-limiting material disposed coating at least a portion of the trace 520.

With further reference to FIG. 16, in accordance with embodiments of the present invention, it should be noted that: a photovoltaic-convertor means for converting radiant power into electrical power may be a solar cell 100A; a system for photovoltaic current-collection may be a power-loss-inhibiting current-collector 1614; an electrical-conduction means for collecting current may be a trace 520; a current-regulating means for limiting current to a portion of the system for photovoltaic current-collection may be a current-limiting portion 1620 of the power-loss-inhibiting current-collector 1614. With the preceding identifications of terms of art, it should be noted that embodiments of the present invention recited herein with respect to a solar cell 100A, a power-loss-inhibiting current-collector 1614, a trace 520, and a current-limiting portion 1620 of the power-loss-inhibiting current-collector 1614 apply to a photovoltaic-convertor means for converting radiant power into electrical power, a system for photovoltaic current-collection, an electrical-conduction means for collecting current, and a current-regulating means for limiting current to a portion of the system for photovoltaic current-collection, respectively. Therefore, it should be noted that the preceding identifications of terms of art do not preclude, nor limit embodiments described herein, which are within the spirit and scope of embodiments of the present invention.

With further reference to FIG. 16 and as described above in Section I with reference to FIG. 1A, in accordance with an embodiment of the present invention, the solar cell 100A includes a metallic substrate 104, an absorber layer 112 disposed on the metallic substrate 104, a conductive backing layer 108 that may be disposed between the absorber layer 112 and the metallic substrate 104, and TCO layers 1616 (identified with the TCO layers 116 of FIG. 1A), which may include one or more layers, here shown as 1616a and 1616b, disposed between the absorber layer 112 and the power-loss-inhibiting current-collector 1614.

With further reference to FIG. 16, in accordance with an embodiment of the present invention, the absorber layer 112 may include a layer of the material, copper indium gallium diselenide (CIGS) having the chemical formula Cu(In₁₋ₓGaₓ)Se₂, as described above in Section I with reference to FIG. 1A. Moreover, in embodiments of the present invention, it should be noted that semiconductors, such as silicon and cadmium telluride, as well as other semiconductors, may be used as the absorber layer 112. As shown, the absorber layer 112 includes a p-type portion 112a and an n-type portion 112b. As a result, a pn homojunction 112c is produced in the absorber layer 112 that serves to separate charge carriers that are created by light incident on the absorber layer 112. Alternatively, the absorber layer 112 may include only a p-type chalcopyrite semiconductor layer, such as a CIGS material layer, and a pn heterojunction may be produced between the absorber layer 112 and an n-type layer, such as a metal oxide, metal sulfide or metal selenide, disposed on its top surface in place of the n-type portion 112b shown in FIG. 16. However, embodiments of the present invention are not limited to pn junctions fabricated in the manner described above, but rather a generic pn junction produced either as a homojunction in a single semiconductor material, or alternatively a heterojunction between two different semiconductor materials, is within the spirit and scope of embodiments of the present invention. Moreover, in embodiments of the present invention, it should be noted that semiconductors, such as silicon and cadmium telluride, as well as other semiconductors, may be used as the absorber layer 112.

With further reference to FIG. 16, in accordance with an embodiment of the present invention, TCO layers 1616 are disposed on the surface of the n-type portion 112b of the absorber layer 112. The TCO layers 1616 may include one or more TCO layers 1616a and 1616b, but without limitation to two layers as shown. Moreover, embodiments of the present invention also encompass without limitation within their scope a single TCO layer in place of the TCO layers 1616 shown in FIG. 16. In an embodiment of the present invention, a first TCO layer 1616a is disposed between the absorber layer 112 and a second TCO layer 1616b. The first TCO layer 1616a may include resistive aluminum zinc oxide (RAZO), r-AlₓZn₁₋ₓO_{y}, where the subscripts x and y indicate that the relative amount of the constituents may be varied. RAZO is also known in the art as reactive aluminum zinc oxide because deposition by reactive sputtering in an oxygen atmosphere may be used to provide an excess of oxygen making the material more resistive. The second TCO layer 1616b is disposed between the first TCO layer 1616a and the power-loss-inhibiting current-collector 1614. The second TCO layer 1616b may include aluminum zinc oxide (AZO), AlₓZn₁₋ₓO_{y}, where the subscripts x and y indicate that the relative amount of the constituents may be varied. AZO is a more conductive material than RAZO. Alternatively, the second TCO layer 1616b may include indium tin oxide (ITO), InₓSn₁₋ₓO_{y}, where the subscripts x and y indicate that the relative amount of the constituents may be varied. In addition, as described above in Section I with reference to FIG. 1A, the TCO layers 1616 (identified with the TCO layers 116 of FIG. 1A), may include other materials, such as zinc oxide, ZnO, and oxides produced by reactively sputtering in an oxygen atmosphere from a metallic target, such as zinc, Zn, Al—Zn alloy, or In—Sn alloy targets.

With further reference to FIG. 16, in accordance with an embodiment of the present invention, under normal operating conditions that occur, for example, with solar illumination of the solar cell 100A, electrical current will trickle through the RAZO and will be collected by the power-loss-inhibiting current-collector 1614. As used herein, it should be noted that the phrases “collecting current” and “current-collector” refers to collecting current carriers of either sign, whether they be positively charged holes or negatively charged electrons; for the structure shown in FIG. 16 in which the TCO layer 1616 is disposed on the n-type portion 112b, the current carriers collected are negatively charged electrons; but, embodiments of the present invention apply, without limitation thereto, to solar-cell configurations where a p-type layer is disposed on an n-type absorber layer, in which case the current carriers collected may be positively charged holes. Therefore, the term “current-collector” as used herein does not imply a polarity of current flow, but rather the functionality of collecting charge carriers associated with an electrical current.

With further reference to FIG. 16, in accordance with an embodiment of the present invention, when the pn junction of the solar cell 100A is reverse biased, the RAZO acts as a barrier to current flow. In particular, if a shunt defect 1730 (see FIG. 17) is present in the solar cell 100A in proximity to a contact between a segment of the power-loss-inhibiting current-collector 1614 and the solar cell 100A, the RAZO acts as a barrier to current flow. In the absence of the RAZO, the presence of shunt defects degrades the performance of the solar cell 100A due to the parasitic conductance created in the solar cell 100A at a site of the shunt defect 1730 (see FIG. 17). If the solar cell 100A is also shaded, the shunt defects can result in hot spots. However, even for a current collector, integrated busbar-solar-cell-current collector, or current-collecting interconnect assembly, lacking the current-limiting portion 1620, if RAZO is present, and if the solar cell 100A is shaded and a shunt defect 1730 (see FIG. 17) is present in the solar cell 100A, but not in proximity to a contact between a segment of the current collector, integrated busbar-solar-cell-current collector, or current-collecting interconnect assembly, and the solar cell 100A, the RAZO may act as a barrier to current flow, reducing this parasitic conductance. By carefully controlling the conductivities and thicknesses of the TCO layer 1616, including materials selected from the group of materials consisting of intrinsic zinc oxide, i-ZnO, AZO and RAZO, the parasitic conductance can in such cases be limited to a finite region surrounding the site of the shunt defect 1730 (see FIG. 17), even for a current collector, integrated busbar-solar-cell-current collector, or current-collecting interconnect assembly, lacking the current-limiting portion 1620. This approach of controlling the conductivities and thicknesses of the TCO layers 1616 works well, unless the current collector, integrated busbar-solar-cell-current collector, or current-collecting interconnect assembly, is located directly above the site of the shunt defect 1730 (see FIG. 17).

Therefore, RAZO alone may not be sufficient to prevent the formation of a hot spot at the site of the shunt defect 1730 (see FIG. 17), especially under exacerbating circumstances such as shading of the solar cell 100A, so that catastrophic melting of the absorber layer 112 may occur at the site of the shunt defect 1730 (see FIG. 17) with the production of a hard short in the solar cell 10A. As a result of such a shunt defect 1730 (see FIG. 17) and in the event that a hot spot develops in proximity to a contact between a segment of the trace 520 and the solar cell 100A, solar-cell efficiency, solar-cell module efficiency and solar-cell array efficiency is substantially diminished. As will be discussed next, embodiments of the present invention ameliorate this condition such that power loss is mitigated, and correspondingly solar-cell efficiency, solar-cell module efficiency and solar-cell array efficiency are substantially undiminished, in an event that a hot spot develops in proximity to a contact between a segment of the trace 520 and the solar cell 100A by regulating current flow through the power-loss-inhibiting current-collector 1614. It should be noted that as used herein the phrase, “substantially undiminished,” with respect to solar-cell efficiency, solar-cell module efficiency and solar-cell array efficiency means that the solar-cell efficiency, solar-cell module efficiency and solar-cell array efficiency are not reduced below an acceptable level of productive performance. Conversely, as used herein the phrase, “substantially diminished,” with respect to solar-cell efficiency, solar-cell module efficiency and solar-cell array efficiency means that the solar-cell efficiency, solar-cell module efficiency and solar-cell array efficiency are reduced below an acceptable level of productive performance.

With reference now to FIG. 17, in accordance with embodiments of the present invention, a second cross-sectional elevation view 1700 of a combined solar-cell, power-loss-inhibiting current-collector 1610 is shown. FIG. 17 shows the physical arrangement of the power-loss-inhibiting current-collector 1614 on the light-facing side of the solar cell 100A and a second example microstructure of the PTCR structure in the current-limiting portion 1620 of the power-loss-inhibiting current-collector 1614 that develops with occurrence of the shunt defect 1730 in the solar cell 100A located in proximity to a contact between the current-limiting portion 1620 of a segment of the power-loss-inhibiting current-collector 1614 and the solar cell 100A. As shown in FIG. 17, the metallic substrate 104, the conductive backing layer 108, the absorber layer 112, including the p-type portion 112a, the n-type portion 112b and the pn junction 112c, and TCO layers 1616, which may include one or more layers, here shown as 1616a and 1616b, are arranged as described above for FIG. 16. Similarly, the trace 520, including the electrically conductive core 520A with at least one overlying layer 520B, is also arranged as described above for FIG. 16. As noted above, the current-limiting portion 1620 of the power-loss-inhibiting current-collector 1614 is configured to regulate current flow through the power-loss-inhibiting current-collector 1614.

With further reference to FIG. 17, in one example embodiment of the present invention, regulation of the current flow occurs by formation of an altered microstructure in the PTCR structure of the current-limiting portion 1620 that develops with occurrence of the shunt defect 1730 in the solar cell 100A located in proximity to a contact between the current-limiting portion 1620 of a segment of the power-loss-inhibiting current-collector 1614 and the solar cell 100A. The second example microstructure, which may be identified with this altered microstructure, of the PTCR structure in the current-limiting portion 1620 of the power-loss-inhibiting current-collector 1614 imparts high resistance to the power-loss-inhibiting current-collector 1614 with occurrence of the shunt defect 1730. In a high-electrical-resistance state, the PTCR structure in the current-limiting portion 1620 still includes the low-conductivity matrix portion 1620a and the plurality of high-conductivity portions 1620b dispersed in the low-conductivity matrix portion 1620a. However, in the high-electrical-resistance state, the high-conductivity pathway for the flow of current between the trace 520 and the solar cell 100A through the high-conductivity portions 1620b is disrupted. Thus, the current-limiting portion 1620 of a segment of the power-loss-inhibiting current-collector 1614 has a resistance that increases with occurrence of the shunt defect 1730 in the solar cell 100A located in proximity to a contact between the current-limiting portion 1620 of the segment of the power-loss-inhibiting current-collector 1614 and the solar cell 100A.

With further reference to FIG. 17, in the example embodiment of the present invention, the second example microstructure of the PTCR structure in the current-limiting portion 1620 includes high-conductivity portions 1620b including a dispersion of disconnected high-conductivity material in the low-conductivity matrix portion 1620a. To the inventors' knowledge, the exact nature of the mechanism by which development of the high-electrical-resistance state occurs in not known; but, in one proposed mechanism for the development of the high-electrical-resistance state, the dispersion of disconnected high-conductivity material may be arranged as a non-percolating distribution that inhibits the flow of current between the trace 520 and the solar cell 100A with occurrence of the shunt defect 1730 in the solar cell 100A located in proximity to a contact between the current-limiting portion 1620 of the segment of the power-loss-inhibiting current-collector 1614 and the solar cell 100A. The current-limiting portion 1620 is configured to regulate current flow through the power-loss-inhibiting current-collector 1614 such that solar-cell efficiency, solar-cell module efficiency and solar-cell array efficiency is substantially undiminished in an event that the shunt defect 1730 develops in proximity to a contact between the current-limiting portion 1620 of the segment of the power-loss-inhibiting current-collector 1614 and the solar cell 100A. The shunt defect 1730 can produce a hot spot, especially under exacerbating circumstances such as shading of the solar cell 100A, so that catastrophic melting of the absorber layer 112 and melting, segregation, or at least separation of the high-conductivity material in the low-conductivity matrix 1620a occurs causing disruption of the percolating network that provides the low-conductivity pathway present under normal operating conditions. By increasing the resistance of the current-limiting portion 1620 of the power-loss-inhibiting current-collector 1614, shunt current flowing through the shunt defect 1730 is substantially attenuated and power loss in the affected solar cell 100A is inhibited. It should be noted that as used herein the phrase, “substantially attenuated,” with respect to shunt current flowing through the shunt defect 1730 means that shunt current flowing through the shunt defect 1730 is so reduced as to maintain an acceptable level of productive performance and efficiency of the affected solar cell 100A, solar-cell module and solar-cell array containing the shunt defect 1730. With the mitigation of the effects of shunt current through the shunt defect 1730, a short-circuit of the current collected from productive solar-cells in a solar-cell module and solar-cell array may be effectively reduced, and the power loss associated with the short-circuit is inhibited. Thus, the current-limiting portion 1620 of the power-loss-inhibiting current-collector 1614 is configured to regulate current flow through the power-loss-inhibiting current-collector 1614 by inhibiting the power loss due to a shunt current flowing through the shunt defect 1730 and maintaining solar-cell efficiency, solar-cell module efficiency and solar-cell array efficiency substantially undiminished in an event that the shunt defect 1730 develops in proximity to the contact between the current-limiting portion 1620 of the segment of the power-loss-inhibiting current-collector 1614 and the solar cell 100A. Also, a partial shunt defect 1734, which only shunts current through a portion of the solar cell 100A, here shown as extending across just the absorber layer 112, can produce similar effects as described above for the shunt defect 1730, here shown as a complete shunt across the entire thickness of the solar cell 100A. Embodiments of the present invention also remedy the effects of these partial shunt defects, for example, partial shunt defect 1734.

With further reference to FIG. 17, in the example embodiment of the present invention, the PTCR structure of the current-limiting portion 1620 acts as a “current spreader” under normal operating conditions, but results in a “built-in” fuse that increases resistance as more current leaks into the site of the shunt defect 1730, which automatically increases the resistance to current flow through the shunt defect 1730. The increased resistance inhibits formation of a hot spot and limits parasitic resistances during a shading event of the solar cell 100A. At low temperatures, the PTCR characteristic is such that the PTCR structure of the current-limiting portion 1620 conducts freely allowing the trace 520 to gather current under normal operating conditions so that the solar cell 100A retains high solar-cell efficiency. As described above, the PTCR structure of the current-limiting portion 1620 is disposed between the trace 520 of the power-loss-inhibiting current-collector 1614 and the TCO layers 1616. The PTCR structure in the current-limiting portion 1620 may be fabricated on the trace 520 by coating the trace 520 with a PTCR ink or PTCR thermoplastic. The PTCR ink or PTCR thermoplastic may include conductive constituents such as silver, tin, nickel, or carbon utilized to control the PTCR characteristics of the PTCR structure in the current-limiting portion 1620 of the power-loss-inhibiting current-collector 1614.

Alternatively, the PTCR structure in the current-limiting portion 1620 of the power-loss-inhibiting current-collector 1614 may exhibit self-regulating current control characteristics based on the following alternative proposed mechanism: at lower temperatures, the PTCR structure of the current-limiting portion 1620 may contract on a microscopic scale that might result in making electrical contact between the high-conductivity portions 1620b producing high-conductivity paths for the current flow; but, on the other hand, at higher temperature, when current through the shunt defect 1730 results in a localized temperature increase, the PTCR structure of the current-limiting portion 1620 may expand that might result in breaking electrical contact between the high-conductivity portions 1620b destroying high-conductivity paths for current flow through the shunt defect 1730, which would reduce the conductivity and current loss at the site of the shunt defect 1730 and would prevent the formation of a hot spot. It should be noted that this alternative mechanism is not necessarily inconsistent with the mechanism discussed earlier. Thus, the behavior of the current-limiting portion 1620 might be likened to the behavior of a fully reversible fuse: closing a circuit and facilitating paths to current flow at low temperature; but, opening a circuit and inhibiting paths to current flow at high temperature, so that the current-limiting portion 1620 self-regulates the current flow through the trace 520 depending on the occurrence of the shunt defect 1730 in proximity to the trace 520. Thus, the current-limiting portion 1620 prevents the catastrophic effects of the shunt defect 1730 in direct juxtaposition to the trace 520 by blocking the formation of a high-conductivity path for, and by inhibiting the flow of, shunting current through the shunt defect 1730.

With further reference to FIG. 17, in another example embodiment of the present invention, the high-conductivity material may be a metal with a tendency to agglomerate in nodules in the low-conductivity matrix 1620a due to an increased temperature above ambient in the vicinity of an incipient hot spot associated with the shunt defect 1730. However, the use of other current-limiting materials that provide regulation of current flow through a current-limiting portion 1620 of the power-loss-inhibiting current-collector 1614 without microstructural changes associated with PTCR material of a PTCR structure within the current-limiting portion 1620 is also within the spirit and scope of embodiments of the present invention.

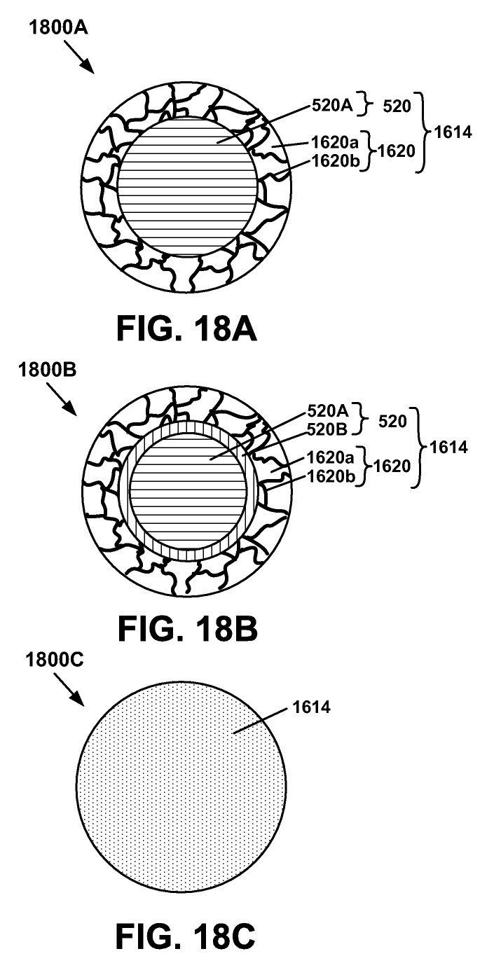

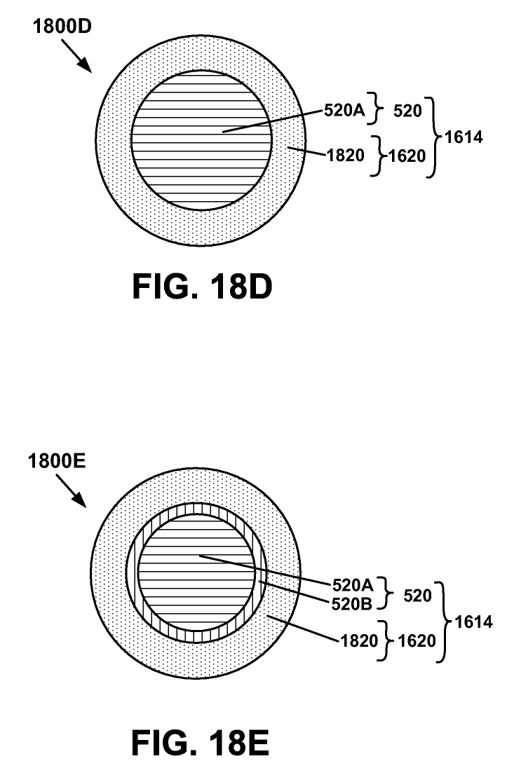

With reference now to FIG. 18A, in accordance with embodiments of the present invention, an elevation view 1800A of a first example of a power-loss-inhibiting current-collector 1614 is shown. FIG. 18A shows the physical structure of the trace 520, including the electrically conductive core 520A, and the PTCR structure in the current-limiting portion 1620 of the power-loss-inhibiting current-collector 1614, including the low-conductivity matrix portion 1620a and the plurality of high-conductivity portions 1620b dispersed in the low-conductivity matrix portion 1620a. The power-loss-inhibiting current-collector 1614 includes the trace 520 for collecting current from the solar cell 100A (see FIGS. 16 and 17) and the PTCR structure of the current-limiting portion 1620 coupled with the trace 520. The PTCR structure of the current-limiting portion 1620 is configured to regulate current flow through the power-loss-inhibiting current-collector 1614. The trace 520 includes the electrically conductive core 520A. The trace 520 may also include nickel. The PTCR structure of the current-limiting portion 1620 may include a layer of PTCR material disposed coating at least a portion of the trace 520. The current-limiting portion 1620 that includes the PTCR structure having a positive temperature coefficient of electrical resistance includes the low-conductivity matrix portion 1620a and the plurality of high-conductivity portions 1620b dispersed in the low-conductivity matrix portion 1620a.

As shown in FIGS. 16, 17 and 18A, the low-conductivity matrix portion 1620a of the PTCR structure in the current-limiting portion 1620 may be selected from the group of materials consisting of a thermoplastic, an epoxy, an adhesive, an electrical varnish and a binder of an ink. The plurality of high-conductivity portions 1620b dispersed in the low-conductivity matrix portion 1620a of the PTCR structure in the current-limiting portion 1620 may be selected from the group of materials consisting of silver, tin, nickel, and carbon, for example, carbon in the form of graphite or carbon black. In general, materials suitable for the current-limiting portion 1620 may be selected from the group of materials consisting of an oxide, a nitride, a carbide, a carbon-containing coating material, a PTCR ink, a PTCR epoxy, a PTCR thermoplastic, a varnish and an adhesive. For the provision of PTCR material in the current-limiting portion 1620, multiple vendors are available, for example: DuPont, Emerson & Cuming, and Sun Chemical. The inventors of embodiments of the present invention are engaged in on-going research and development to find an optimum mixture and formulation of materials for the high-conductivity portions 1620b with the low-conductivity matrix portion 1620a of the PTCR structure in the current-limiting portion 1620 for the power-loss-inhibiting current-collector 1614, but have not as yet found the optimum mixture and formulation of materials. As PTCR materials are well known, for example, from applications to self-regulating heating cables, research and development to find an optimum mixture and formulation of materials for the high-conductivity portions 1620b with the low-conductivity matrix portion 1620a of the PTCR structure in the current-limiting portion 1620 for the power-loss-inhibiting current-collector 1614 are not expected to result in undue experimentation.

With reference now to FIG. 18B, in accordance with embodiments of the present invention, an elevation view 1800B of a second example of a power-loss-inhibiting current-collector 1614 is shown. FIG. 18B shows the physical structure of the trace 520, including an electrically conductive core 520A and at least one overlying layer 520B, and the PTCR structure in the current-limiting portion 1620 of the power-loss-inhibiting current-collector 1614, including the low-conductivity matrix portion 1620a and the plurality of high-conductivity portions 1620b dispersed in the low-conductivity matrix portion 1620a. In one embodiment of the present invention, the layer 520B overlying the electrically conductive core 520A may include nickel. In another embodiment of the present invention, the layer 520B overlying the electrically conductive core 520A may be oxidized, prior to disposing a PTCR structure of the current-limiting portion 1620, as a coating, on the trace 520. The PTCR structure in the current-limiting portion 1620 may include a layer of PTCR material disposed coating at least a portion of the trace 520. Other details of the embodiment of the present invention shown in FIG. 18B have been discussed above in the description of FIGS. 16 and 17. Moreover, it is noted that certain embodiments of the present invention described with respect to FIGS. 16 and 17 may apply without limitation to embodiments of the present invention described in FIGS. 18A, 18C, 18D and 18E where the structure of the power-loss-inhibiting current-collector 1614 may differ from that shown in FIG. 18B, especially for embodiments of the present invention employing materials that may not have the specific PTCR structure as described above, but are nevertheless current-limiting materials.

With reference now to FIG. 18C, in accordance with embodiments of the present invention, a cross-sectional, elevation view 1800C of a third example of a power-loss-inhibiting current-collector 1614 is shown. FIG. 18C shows the physical structure of power-loss-inhibiting current-collector 1614 for a current-limiting portion of the power-loss-inhibiting current-collector integrated with the trace. In FIG. 18C, the current-limiting portion of the power-loss-inhibiting current-collector 1614 is not shown as a separate structure from the trace to emphasize that the current-limiting portion of the power-loss-inhibiting current-collector 1614 is integrated with the trace.

With reference now to FIG. 18D, in accordance with embodiments of the present invention, a cross-sectional, elevation view 1800D of a fourth example of a power-loss-inhibiting current-collector 1614 is shown. FIG. 18D shows the physical structure of the trace 520, including an electrically conductive core 520A, and the current-limiting portion 1620 of the power-loss-inhibiting current-collector 1614, including a material 1820 selected from the group of materials having current-limiting behavior. As described above, in the absence of a power-loss-inhibiting current-collector 1614, the approach of controlling the conductivities and thicknesses of the TCO layers 1616 works well, unless a current collector, current-collecting interconnect assembly, or integrated busbar-solar-cell-current collector, is located directly above the site of the shunt defect 1730. An embodiment of the present invention addresses this problem by utilizing a conductive layer, for example, the current-limiting portion 1620, between the trace 520 of a current collector, current-collecting interconnect assembly, or integrated busbar-solar-cell-current collector, that has a lower conductivity than the trace 520 which limits the shunt current at the site of the shunt defect 1730. Loss of efficiency in the solar cell 100A, the solar-cell module and the solar-cell array can be minimized because extra series resistance is added to the circuit only at the site of the shunt defect 1730 located at the contact between the current-limiting portion 1620 of the segment of the power-loss-inhibiting current-collector 1614 and the solar cell 100A. The primary path of current collection is not affected. In an embodiment of the present invention, the current-limiting portion 1620 includes an oxide coating that may be disposed on the trace 520 of the current collector, the current-collecting interconnect assembly, or the integrated busbar-solar-cell-current collector. The current-limiting portion 1620 may include the material 1820 selected from the group of current-limiting materials consisting of silver oxide, nickel oxide, indium tin oxide, zinc oxide, AZO, RAZO, a conductive carbon-containing material and a conductive nitrogen-containing material, which may not possess the PTCR structure as described above.

With reference now to FIG. 18E, in accordance with embodiments of the present invention, a cross-sectional, elevation view 1800E of a fifth example of a power-loss-inhibiting current-collector 1614 is shown. FIG. 18E shows the physical structure of the trace 520, including an electrically conductive core 520A and at least one overlying layer 520B, and the current-limiting portion 1620 of the power-loss-inhibiting current-collector 1614 including the material 1820 selected from the group of materials having current-limiting behavior. Similar to FIG. 18D, the current-limiting portion 1620 may include the material 1820 selected from the group of current-limiting materials consisting of silver oxide, nickel oxide, indium tin oxide, zinc oxide, AZO, RAZO, a conductive carbon-containing material and a conductive nitrogen-containing material, which may not possess the PTCR structure as described above.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments described herein were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A power-loss-inhibiting current-collector comprising:
a trace for collecting current from a solar cell; and
a current-limiting portion coupled with said trace, said current-limiting portion configured to regulate current flow through said power-loss-inhibiting current-collector.

2. The power-loss-inhibiting current-collector of claim 1, wherein said trace further comprises an electrically conductive core.

3. The power-loss-inhibiting current-collector of claim 1, wherein said trace further comprises nickel.

4. The power-loss-inhibiting current-collector of claim 1, wherein said trace further comprises an electrically conductive core and a layer overlying said electrically conductive core, said layer overlying said electrically conductive core comprising nickel.

5. The power-loss-inhibiting current-collector of claim 1, wherein said current-limiting portion comprises a layer of current-limiting material disposed coating at least a portion of said trace.

6. The power-loss-inhibiting current-collector of claim 1, wherein said current-limiting portion of a segment of said power-loss-inhibiting current-collector has a resistance that increases with occurrence of a shunt defect in said solar cell located in proximity to a contact between said current-limiting portion of said segment of said power-loss-inhibiting current-collector and said solar cell.

7. The power-loss-inhibiting current-collector of claim 1, wherein said current-limiting portion is integrated with said trace.

8. The power-loss-inhibiting current-collector of claim 1, wherein said current-limiting portion further comprises a positive-temperature-coefficient-of-electrical-resistance structure having a positive temperature coefficient of electrical resistance, said positive-temperature-coefficient-of-electrical-resistance structure comprising:
a low-conductivity matrix portion; and
a plurality of high-conductivity portions dispersed in said low-conductivity matrix portion.

9. The power-loss-inhibiting current-collector of claim 8, wherein said low-conductivity matrix portion of said positive-temperature-coefficient-of-electrical-resistance structure is selected from the group of materials consisting of a thermoplastic, an epoxy, an adhesive, an electrical varnish and a binder of an ink.

10. The power-loss-inhibiting current-collector of claim 8, wherein said plurality of high-conductivity portions dispersed in said low-conductivity matrix of said positive-temperature-coefficient-of-electrical-resistance structure is selected from the group of materials consisting of silver, tin, nickel, and carbon.

11. The power-loss-inhibiting current-collector of claim 1, wherein said current-limiting portion further comprises a material selected from the group of current-limiting materials consisting of silver oxide, nickel oxide, indium tin oxide, zinc oxide, aluminum zinc oxide, resistive aluminum zinc oxide, a conductive carbon-containing material and a conductive nitrogen-containing material.

12. A combined solar-cell, power-loss-inhibiting current-collector comprising:
a solar cell; and
a power-loss-inhibiting current-collector comprising:
a trace for collecting current from said solar cell; and
a current-limiting portion coupled with said trace, said current-limiting portion configured to regulate current flow through said power-loss-inhibiting current-collector.

13. The combined solar-cell, power-loss-inhibiting current-collector of claim 12, wherein said current-limiting portion comprises a layer of current-limiting material disposed coating at least a portion of said trace.

14. The combined solar-cell, power-loss-inhibiting current-collector of claim 12, wherein said current-limiting portion is integrated with said trace.

15. The combined solar-cell, power-loss-inhibiting current-collector of claim 12, wherein said current-limiting portion further comprises a positive-temperature-coefficient-of-electrical-resistance structure having a positive temperature coefficient of electrical resistance, said positive-temperature-coefficient-of-electrical-resistance structure comprising:
a low-conductivity matrix portion; and
a plurality of high-conductivity portions dispersed in said low-conductivity matrix portion.

16. The combined solar-cell, power-loss-inhibiting current-collector of claim 15, wherein said low-conductivity matrix portion of said positive-temperature-coefficient-of-electrical-resistance structure is selected from the group of materials consisting of a thermoplastic, an epoxy, an adhesive, an electrical varnish and a binder of an ink.

17. The combined solar-cell, power-loss-inhibiting current-collector of claim 15, wherein said plurality of high-conductivity portions dispersed in said low-conductivity matrix of said positive-temperature-coefficient-of-electrical-resistance structure is selected from the group of materials consisting of silver, tin, nickel, and carbon.

18. The combined solar-cell, power-loss-inhibiting current-collector of claim 12, wherein said current-limiting portion further comprises a material selected from the group of current-limiting materials consisting of silver oxide, nickel oxide, indium tin oxide, zinc oxide, aluminum zinc oxide, resistive aluminum zinc oxide, a conductive carbon-containing material and a conductive nitrogen-containing material.

19. A system for photovoltaic current-collection comprising:
an electrical-conduction means for collecting current from a photovoltaic-convertor means for converting radiant power into electrical power; and
a current-regulating means for limiting current to a portion of said system for photovoltaic current-collection coupled with said electrical-conduction means, said current-regulating means configured to regulate current flow through said system for photovoltaic current-collection.

20. The system for photovoltaic current-collection of claim 19, wherein said current-regulating means of a segment of said system for photovoltaic current-collection has a resistance that increases with occurrence of a shunt defect in said photovoltaic-convertor means located in proximity to a contact between said current-regulating means of said segment of said system for photovoltaic current-collection and said photovoltaic-convertor means.
